(19) United States
(12) Patent Application Publication
(10) Pub. No.: US 2016/0155759 A1
(43) Pub. Date: Jun. 2, 2016

(54) SEMICONDUCTOR DEVICE AND DISPLAY DEVICE INCLUDING THE SAME

(71) Applicant: Semiconductor Energy Laboratory Co., Ltd., Atsugi-shi (JP)

(72) Inventors: Shunpei YAMAZAKI, Tokyo (JP); Kenichi OKAZAKI, Tochigi (JP); Hiroshi KANEMURA, Tochigi (JP); Daisuke KUROSAKI, Tochigi (JP); Yukinori SHIMA, Tatebayashi (JP); Junichi KOEZUKA, Tochigi (JP); Hiroyuki MIYAKE, Atsugi (JP)

(21) Appl. No.: 14/946,985

(22) Filed: Nov. 20, 2015

(30) Foreign Application Priority Data
Nov. 28, 2014 (JP) 2014-242170
Dec. 18, 2014 (JP) 2014-255804
Mar. 9, 2015 (JP) 2015-046110
Mar. 24, 2015 (JP) 2015-061604

(51) Int. Cl. H01L 27/12; H01L 29/417; H01L 29/786

(52) U.S. Cl. CPC H01L 27/1225; H01L 29/78693; H01L 29/41733

(57) ABSTRACT

To provide a semiconductor device including a transistor which includes an oxide semiconductor film and has excellent electrical characteristics. A semiconductor device includes a transistor including a first electrode, a first insulating film over the first electrode, an oxide semiconductor film over the first insulating film, a second insulating film over the oxide semiconductor film, and a second electrode over the second insulating film. The oxide semiconductor film includes a first oxide semiconductor film and a second oxide semiconductor film. The difference between energy at a conduction band minimum of the first oxide semiconductor film and energy at a conduction band minimum of the second oxide semiconductor film is greater than or equal to 0.2 eV. A rate of change in drain current per unit channel width relative to a drain voltage of 1 V can be less than or equal to 2%.

### BACKGROUND OF THE INVENTION

1. Field of the Invention

One embodiment of the present invention relates to a semiconductor device including an oxide semiconductor film and a display device including the semiconductor device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a storage device, an imaging device, a method for driving any of them, and a method for manufacturing any of them.

In this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. An imaging device, a display device, a liquid crystal display device, a light-emitting device, an electro-optical device, a power generation device (including a thin film solar cell, an organic thin film solar cell, and the like), and an electronic device may each include a semiconductor device.

2. Description of the Related Art

Attention has been focused on a technique for forming a transistor (a thin film transistor (TFT) or a field-effect transistor (FET)) using a semiconductor thin film formed over a substrate. The transistor is applied to a wide range of electronic devices such as an integrated circuit (IC) or an image device (display device). As semiconductor thin films applicable to the transistors, silicon-based semiconductor materials have been widely used, but oxide semiconductors have been attracting attention as alternative materials.

In 1995, a transistor including an oxide semiconductor was invented, and its electrical characteristics were disclosed (see Patent Document 1).

In addition, a technique for improving carrier mobility by forming a stack of oxide semiconductor films has been disclosed (see Patent Documents 2 and 3).

### REFERENCES

### Patent Documents

[Patent Document 1] Japanese Translation of PCT International Application No. H11-505377

[Patent Document 2] Japanese Published Patent Application No. 2011-138934

[Patent Document 3] Japanese Published Patent Application No. 2011-124360

### SUMMARY OF THE INVENTION

In one embodiment of the present invention, one object is to provide a semiconductor device including a transistor having excellent electrical characteristics (e.g., on-state current, field-effect mobility, or frequency characteristics). Another object is to provide a semiconductor device including a transistor having excellent saturation characteristics. Another object is to provide a semiconductor device including a highly reliable transistor. Another object is to provide a novel semiconductor device. Another object is to provide a novel method for manufacturing a semiconductor device.

Note that the description of the above object does not disturb the existence of other objects. In one embodiment of the present invention, there is no need to achieve all the objects. Objects other than the above objects will be apparent from and can be derived from the description of the specification and the like.

One embodiment of the present invention is a semiconductor device including a transistor including a first electrode, a first insulating film over the first electrode, an oxide semiconductor film over the first insulating film, a second insulating film over the oxide semiconductor film, and a second electrode over the second insulating film. The oxide semiconductor film includes a first oxide semiconductor film and a second oxide semiconductor film. A difference between energy at a conduction band minimum of the first oxide semiconductor film and energy at a conduction band minimum of the second oxide semiconductor film is greater than or equal to 0.2 eV. In a region of the transistor, a rate of change in drain current per unit channel width relative to a drain voltage of 1 V is less than or equal to 2%.

Another embodiment of the present invention is a semiconductor device including a transistor including a first electrode, a first insulating film over the first electrode, an oxide semiconductor film over the first insulating film, a second insulating film over the oxide semiconductor film, and a second electrode over the second insulating film. The oxide semiconductor film includes a first oxide semiconductor film and a second oxide semiconductor film. A difference between energy at a conduction band minimum of the first oxide semiconductor film and energy at a conduction band minimum of the second oxide semiconductor film is greater than or equal to 0.2 eV. In a region of the transistor, an amount of change in drain current per unit channel width relative to a drain voltage of 1 V is less than or equal to 1×10⁻⁹ A/μm.

Another embodiment of the present invention is a semiconductor device including a transistor including a first electrode, a first insulating film over the first electrode, an oxide semiconductor film over the first insulating film, a second insulating film over the oxide semiconductor film, and a second electrode over the second insulating film. The oxide semiconductor film includes a first oxide semiconductor film and a second oxide semiconductor film. The first oxide semiconductor film includes In, Zn, and M. M is Ti, Ga, Y, Zr, Sn, La, Ce, Nd, or Hf. The first oxide semiconductor film includes a region where an amount of the In is larger than or equal to an amount of the M. At least one element of the first oxide semiconductor film is the same as at least one element of the second oxide semiconductor film. A difference between energy at a conduction band minimum of the first oxide semiconductor film and energy at a conduction band minimum of the second oxide semiconductor film is greater than or equal to 0.2 eV. In a region of the transistor, a rate of change in drain current per unit channel width relative to a drain voltage of 1 V is less than or equal to 2%.

Another embodiment of the present invention is a semiconductor device including a transistor including a first electrode, a first insulating film over the first electrode, an oxide semiconductor film over the first insulating film, a second insulating film over the oxide semiconductor film, and a second electrode over the second insulating film. The oxide semiconductor film includes a first oxide semiconductor film and a second oxide semiconductor film. The first oxide semiconductor film includes In, Zn, and M. M is Ti, Ga, Y, Zr, Sn, La, Ce, Nd, or Hf. The first oxide semiconductor film includes a region where an amount of the In is larger than or equal to an amount of the M. At least one element in the first oxide semiconductor film is the same as at least one element in the second oxide semiconductor film. A difference between energy at a conduction band minimum of the first oxide semiconductor film and energy at a conduction band minimum of the second oxide semiconductor film is greater than or equal to 0.2 eV. In a region of the transistor, an amount of change in drain current per unit channel width relative to a drain voltage of 1 V is less than or equal to 1×10⁻⁹ A/μm.

In each of the above-described embodiments, the second oxide semiconductor film includes In, Zn, and M (M is Ti, Ga, Y, Zr, Sn, La, Ce, Nd, or Hf), and, in a region of the second oxide semiconductor film, an amount of the M is larger than or equal to an amount of the In.

In the above-described embodiment, a region where an amount of the In in the first oxide semiconductor film is larger than or equal to an amount of the In in the second oxide semiconductor film is included.

In the above-described embodiments, a region where an amount of the M in the second oxide semiconductor film is larger than an amount of the M in the first oxide semiconductor film is included.

In each of the above embodiments, a thickness of a region of the first oxide semiconductor film is smaller than or equal to a thickness of the second oxide semiconductor film.

In each of the above embodiments, the oxide semiconductor film includes a crystal part, and the crystal part has c-axis alignment and includes a portion whose c-axis is parallel to a normal vector of a surface over which the oxide semiconductor film is formed.

In each of the above embodiments, oxygen molecules of more than or equal to 8.0×10¹⁴/cm² are detected from the second insulating film in the semiconductor device by thermal desorption spectroscopy.

Another embodiment of the present invention is a display device including the semiconductor device having any one of the above structures and a display element. Another embodiment of the present invention is a display module including the display device and a touch sensor. Another embodiment of the present invention is an electronic device including at least one of the semiconductor device having any one of the above structures, the display device having the above structure, and the display module having the above structure, and at least one of an operation key and a battery.

One embodiment of the present invention can provide a semiconductor device including a transistor having excellent electric characteristics (e.g., on-state current, field-effect mobility, frequency characteristics, and the like). A semiconductor device including a transistor having excellent saturation characteristics can be provided. A semiconductor device including a highly reliable transistor can be provided. An excellent semiconductor device can be provided. A novel method of manufacturing a semiconductor device can be provided.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIGS. 1A to 1C are a top view and cross-sectional views illustrating a semiconductor device of one embodiment of the present invention.

FIGS. 2A to 2C are a top view and cross-sectional views illustrating a semiconductor device of one embodiment of the present invention.

FIGS. 3A and 3B illustrate band structures of a semiconductor device of one embodiment of the present invention.

FIGS. 4A to 4C illustrate band structures of a semiconductor device of one embodiment of the present invention.

FIGS. 5A and 5B illustrate band structures of a semiconductor device of one embodiment of the present invention.

FIGS. 6A to 6C are a top view and cross-sectional views illustrating a semiconductor device of one embodiment of the present invention.

FIGS. 7A to 7C illustrate electrical characteristics of semiconductor elements of one embodiment of the present invention.

FIGS. 8A to 8D illustrate an example of a process of manufacturing a semiconductor device of one embodiment of the present invention.

FIGS. 9A to 9D illustrate an example of the process of manufacturing a semiconductor device of one embodiment of the present invention.

FIGS. 10A to 10C illustrate an example of the process of manufacturing a semiconductor device of one embodiment of the present invention.

FIGS. 11A to 11C illustrate an example of the process of manufacturing a semiconductor device of one embodiment of the present invention.

FIGS. 12A to 12C are a top view and cross-sectional views illustrating a semiconductor device of one embodiment of the present invention.

FIGS. 13A to 13C are a top view and cross-sectional views illustrating a semiconductor device of one embodiment of the present invention.

FIGS. 14A to 14C are a top view and cross-sectional views illustrating a semiconductor device of one embodiment of the present invention.

FIGS. 15A and 15B each show one embodiment of a thermal profile of heat treatment in a gas baking furnace.

FIGS. 16A and 16B each show one embodiment of a thermal profile of heat treatment in a gas baking furnace.

FIGS. 17A to 17D are Cs-corrected high-resolution TEM images of a cross section of a CAAC-OS and a cross-sectional schematic view of a CAAC-OS.

FIGS. 18A to 18D are Cs-corrected high-resolution TEM images of a plane of a CAAC-OS.

FIGS. 19A to 19C show structure analysis of a CAAC-OS and a single crystal oxide semiconductor by XRD.

FIGS. 20A and 20B show electron diffraction patterns of a CAAC-OS.

FIG. 21 shows a change in crystal part of an In—Ga—Zn oxide induced by electron irradiation.

FIGS. 22A to 22D illustrate a deposition method of a CAAC-OS.

FIG. 23 illustrates a crystal structure of InMZnO₄.

FIGS. 24A to 24E illustrate a deposition method of a CAAC-OS.

FIGS. 25A to 25C illustrate a deposition method of a CAAC-OS.

FIG. 26 illustrates a deposition method of an nc-OS.

FIGS. 27A to 27C are a block diagram and circuit diagrams illustrating a display device.

FIGS. 28A and 28B are perspective views illustrating an example of a touch panel.

FIGS. 29A and 29B are cross-sectional views illustrating examples of a display device.

FIG. 30 is a cross-sectional view illustrating an example of a touch sensor.

FIGS. 31A and 31B are cross-sectional views illustrating examples of a touch panel.

FIGS. 32A and 32B are a block diagram and a timing chart of a touch sensor.

FIG. 33 is a circuit diagram of a touch sensor.

FIG. 34 illustrates a display module.

FIGS. 35A to 35G illustrate electronic devices.

FIG. 36 illustrates a circuit structure in a semiconductor device.

FIG. 37A is a diagram showing a configuration of a pixel circuit, and FIG. 37B is a timing chart illustrating the operation of the pixel circuit.

FIG. 38 illustrates a structure of a deposition apparatus.

FIGS. 39A and 39B show XRD spectra in an example.

FIGS. 40A and 40B are cross-sectional TEM images of oxide semiconductor films in an example.

FIGS. 41A to 41C are a top view and cross-sectional views of a transistor in an example.

FIGS. 42A and 42B each illustrate electrical characteristics of transistors in an example.

FIGS. 43A and 43B each show I_{d}-V_{g} characteristics of transistors before and after a reliability test in an example.

FIGS. 44A and 44B each show I_{d}-V_{g} characteristics of transistors before and after a reliability test in an example.

FIGS. 45A and 45B show results of reliability tests performed on transistors in an example.

FIGS. 46A to 46C show I_{d}-V_{g} characteristics of transistors in an example.

FIGS. 47A and 47B each show electrical characteristics of transistors in an example.

FIGS. 48A and 48B each show I_{d}-V_{g} characteristics of transistors in an example.

FIGS. 49A and 49B each show I_{d}-V_{d} characteristics of transistors in an example.

FIGS. 50A and 50B each show the results of a constant-current stress test performed on transistors in an example.

FIG. 51 shows a display example of a display device in an example.

### DETAILED DESCRIPTION OF THE INVENTION

Embodiments of the present invention will be explained below with reference to the drawings. However, the present invention is not limited to description to be given below, and it is to be easily understood that modes and details thereof can be variously modified without departing from the purpose and the scope of the present invention. Accordingly, the present invention should not be interpreted as being limited to the content of the embodiments below.

Note that the position, the size, the range, or the like of each structure illustrated in drawings and the like is not accurately represented in some cases for simplification. Therefore, the disclosed invention is not necessarily limited to the position, the size, the range, or the like disclosed in the drawings and the like.

Note that the ordinal numbers such as “first”, “second”, and the like in this specification and the like are used for convenience and do not denote the order of steps or the stacking order of layers. Therefore, for example, description can be made even when “first” is replaced with “second” or “third”, as appropriate. In addition, the ordinal numbers in this specification and the like are not necessarily the same as those which specify one embodiment of the present invention.

Note that in this specification, terms for describing arrangement, such as “over” “above”, “under”, and “below”, are used for convenience in describing a positional relation between components with reference to drawings. Further, the positional relation between components is changed as appropriate in accordance with a direction in which each component is described. Thus, there is no limitation on terms used in this specification, and description can be made appropriately depending on the situation.

In describing structures of the invention with reference to the drawings in this specification and the like, common reference numerals are used for the same portions in different drawings.

In this specification and the like, a transistor is an element having at least three terminals of a gate, a drain, and a source. In addition, the transistor has a channel region between a drain (a drain terminal, a drain region, or a drain electrode) and a source (a source terminal, a source region, or a source electrode), and current can flow through the drain region, the channel region, and the source region. Note that in this specification and the like, a channel region refers to a region through which current mainly flows.

Further, functions of a source and a drain might be switched when transistors having different polarities are employed or a direction of current flow is changed in circuit operation, for example. Therefore, the terms “source” and “drain” can be switched in this specification and the like.

Note that in this specification and the like, the expression “electrically connected” includes the case where components are connected through an “object having any electric function”. There is no particular limitation on an “object having any electric function” as long as electric signals can be transmitted and received between components that are connected through the object. Examples of an “object having any electric function” are a switching element such as a transistor, a resistor, an inductor, a capacitor, and elements with a variety of functions as well as an electrode and a wiring.

Note that in this specification and the like, a silicon oxynitride film refers to a film in which the proportion of oxygen is higher than that of nitrogen. The silicon oxynitride film preferably contains oxygen, nitrogen, silicon, and hydrogen in the ranges of 55 atomic % to 65 atomic %, 1 atomic % to 20 atomic %, 25 atomic % to 35 atomic %, and 0.1 atomic % to 10 atomic %, respectively. A silicon nitride oxide film refers to a film in which the proportion of nitrogen is higher than that of oxygen. The silicon nitride oxide film preferably contains nitrogen, oxygen, silicon, and hydrogen in the ranges of 55 atomic % to 65 atomic %, 1 atomic % to 20 atomic %, 25 atomic % to 35 atomic %, and 0.1 atomic % to 10 atomic %, respectively.

In this specification and the like, the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

In this specification, the term “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. In addition, the term “perpendicular” indicates that the angle formed between two straight lines is greater than or equal to 80° and less than or equal to 100°, and accordingly also includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

### Embodiment 1

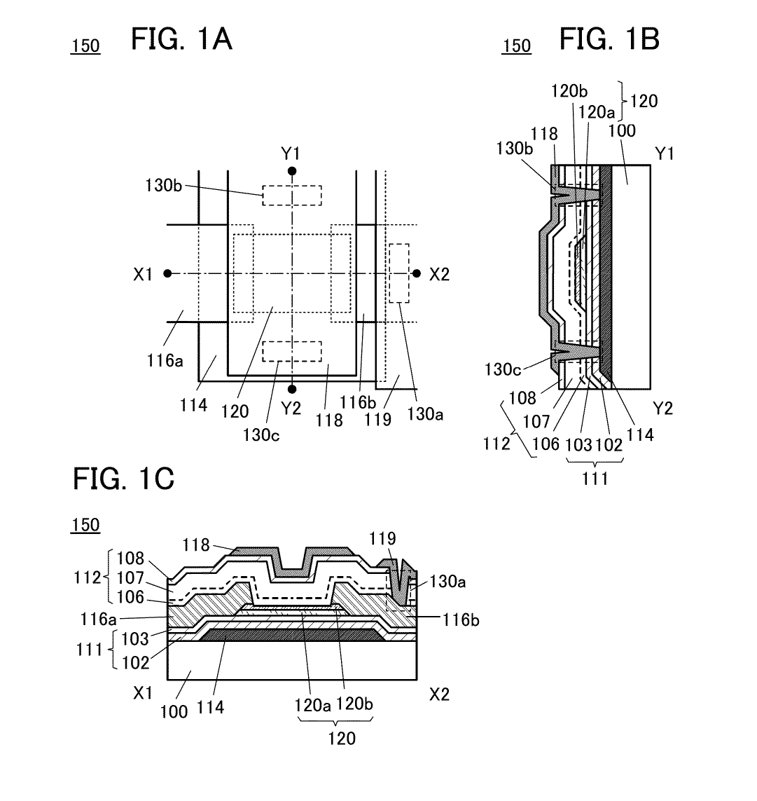

In this embodiment, semiconductor devices of one embodiment of the present invention will be described below with reference to FIGS. 1A to 1C, FIGS. 2A to 2C, FIGS. 3A and 3B, FIGS. 4A to 4C, FIGS. 5A and 5B, FIGS. 6A to 6C, FIGS. 7A to 7C, FIGS. 8A to 8D, FIGS. 9A to 9D, FIGS. 10A to 10C, FIGS. 11A to 11C, FIGS. 12A to 12C, FIGS. 13A to 13C, FIGS. 14A to 14C, FIGS. 15A and 15B, and FIGS. 16A and 16B.

### <Example of Structure of Semiconductor Device>

FIG. 1A is a top view of a transistor 150 that is a semiconductor device of one embodiment of the present invention. FIG. 1B is a cross-sectional view taken along the dashed-dotted line Y1-Y2 shown in FIG. 1A, and FIG. 1C is a cross-sectional view taken along the dashed-dotted line X1-X2 shown in FIG. 1A. Note that some components (e.g., a substrate 100 and an insulating film) of the transistor 150 are not illustrated in FIG. 1A for simplicity.

In some cases, the direction of the dashed-dotted line X1-X2 in FIG. 1A is referred to as a channel length direction of the transistor 150 and the direction of the dashed-dotted line Y1-Y2 in FIG. 1A is referred to as a channel width direction of the transistor 150.

The transistor 150 includes a gate electrode 114, a gate insulating film 111, a gate insulating film 112, an oxide semiconductor film 120, a pair of electrodes 116a and 116b, a gate electrode 118, and an electrode 119 over the substrate 100. The gate insulating film 111 includes an insulating film 102 and an insulating film 103. The gate insulating film 112 includes an insulating film 106, an insulating film 107, and an insulating film 108. The insulating film 102 is formed over the gate electrode 114 and the substrate 100. The insulating film 103 is formed over the insulating film 102. The oxide semiconductor film 120 is formed over the insulating film 103. The pair of electrodes 116a and 116b is formed in contact with the oxide semiconductor film 120. The insulating film 106 and the insulating film 107 are formed over the insulating film 103, the oxide semiconductor film 120, and the pair of electrodes 116a and 116b. The insulating film 108 is formed over the insulating film 107. The gate electrode 118 and the electrode 119 are formed over the insulating film 108. The oxide semiconductor film 120 includes an oxide semiconductor film 120a and an oxide semiconductor film 120b. The gate electrode 118 is connected to the gate electrode 114 through opening portions 130b and 130c provided in the gate insulating film 111 and the gate insulating film 112. The electrode 119 is connected to the one of the electrodes 116a and 116b (in FIG. 1C, the electrode 116b) through the opening portion 130a provided in the gate insulating film 112. Note that the pair of electrodes 116a and 116b functions as a source electrode and a drain electrode, and the electrode 119 functions as a pixel electrode.

The gate insulating film 111 functions as a gate insulating film of the transistor 150. The gate insulating film 112 functions as a gate insulating film of the transistor 150. The gate insulating film 112 has a function of supplying oxygen to the oxide semiconductor film 120. That is, the insulating film 106 contains oxide, and the insulating film 107 contains oxide. The insulating film 108 contains nitride.

<s-channel Structure>

The oxide semiconductor film 120 is provided between the gate electrode 114 and the gate electrode 118 with the gate insulating film 111 positioned between the oxide semiconductor film 120 and the gate electrode 114 and with the gate insulating film 112 positioned between the oxide semiconductor film 120 and the gate electrode 118. The lengths in the channel length direction and the channel width direction of the gate electrode 118 are longer than those in the channel length direction and the channel width direction of the oxide semiconductor film 120. The whole oxide semiconductor film 120 is covered with the gate electrode 118 with the gate insulating films 111 and 112 positioned therebetween. Since the gate electrode 114 and the gate electrode 118 are connected to each other through the opening portions 130b and 130c provided in the gate insulating films 111 and 112, a side surface of the oxide semiconductor film 120 in the channel width direction faces the gate electrode 118 with the gate insulating films 111 and 112 positioned therebetween.

In other words, in the channel width direction of the transistor 150, the gate electrode 114 and the gate electrode 118 are connected to each other through the opening portions 130b and 130c provided in the gate insulating films 111 and 112 functioning as gate insulating films; and the gate electrode 114 and the gate electrode 118 surround the oxide semiconductor film 120 with the gate insulating films 111 and 112 functioning as gate insulating films positioned therebetween.

Thus, the same potential can be applied to the gate electrode 114 and the gate electrode 118, so that the oxide semiconductor film 120 included in the transistor 150 can be electrically surrounded by electric fields of the gate electrode 114 and the gate electrode 118. A device structure of a transistor, like that of the transistor 150, in which electric fields of the gate electrode 114 and the gate electrode 118 electrically surround an oxide semiconductor film where a channel region is formed can be referred to as a surrounded channel (s-channel) structure.

Since the transistor 150 has the s-channel structure, an electric field for inducing a channel can be effectively applied to the oxide semiconductor film 120 by the gate electrode 114. Accordingly, the current drive capability of the transistor 150 is increased, so that high on-state current can be obtained. Since the on-state current can be increased, it is possible to reduce the size of the transistor 150. Furthermore, since the transistor 150 has a structure in which the oxide semiconductor film 120 is surrounded by the gate electrode 114 and the gate electrode 118, the mechanical strength of the transistor 150 can be increased.

In such a structure, the area where carriers flow in the oxide semiconductor film 120 is increased. That is, carriers flow at the interface between the gate insulating film 111 and the oxide semiconductor film 120, at the interface between the gate insulating film 112 and the oxide semiconductor film 120, and in the oxide semiconductor film 120. Therefore, the amount of carrier movement in the transistor 150 is increased. As a result, the on-state current of the transistor 150 is increased, and the field-effect mobility is increased. Typically, the field-effect mobility is greater than or equal to 10 cm²/V·s. Note that here, the field-effect mobility is not an approximate value of the mobility as the physical property of the oxide semiconductor film but is an index of current drive capability and the apparent field-effect mobility of a saturation region of the transistor.

Note that in gate voltage-drain current characteristics (hereinafter, also referred to as V_{d}-I_{d} characteristics), which are the electrical characteristics of a transistor, drain current (I_{d}) is saturated when voltage between a pair of electrodes (a source electrode and a drain electrode) is higher than gate voltage, more properly, when drain voltage is higher than voltage obtained by substituting threshold voltage from gate voltage (V_{d}>V_{g}−Vₜₕ). A region where drain current (I_{d}) is saturated is called a saturation region.

In a transistor in which a gate electrode is provided over or below an oxide semiconductor film, such as a transistor with a structure including one gate electrode (also referred to as a single-gate structure), the charge density of a region in the oxide semiconductor film and in the vicinity of a drain electrode is increased because of high drain voltage. However, the transistor 150 of one embodiment of the present invention has the structure including the gate electrode 114 and the gate electrode 118 (also referred to as a dual-gate structure) with the oxide semiconductor film 120 positioned between the gate electrode 114 and the gate electrode 118. The gate insulating film 111 is provided between the gate electrode 114 and the oxide semiconductor film 120, and the gate insulating film 112 is provided between the gate electrode 118 and the oxide semiconductor film 120. Since the same potential is applied to the gate electrode 114 and the gate electrode 118, high controllability by the gate electrode can be achieved, so that an increase in the charge density of the region in the oxide semiconductor film and in the vicinity of the drain electrode (the electrode 116a or 116b) can be suppressed. As a result, drain current (I_{d}) in a saturation region is saturated more easily in the transistor 150 employing the above-described driving method (also referred to as dual-gate driving) than in the transistor having a single-gate structure. This means that drain current (I_{d}) in the saturation region does not greatly fluctuate even when drain voltage (V_{d}) fluctuates.

Defects are formed at the side surfaces and their vicinity of the oxide semiconductor film 120, which is processed by etching or the like, because of damage due to the processing, and the side surfaces and their vicinity are polluted by attachment of impurities or the like. For this reason, in the case where a transistor has a single-gate structure in which only one of the gate electrode 114 and the gate electrode 118 is formed, even when the oxide semiconductor film 120 is intrinsic or substantially intrinsic as described later, the side surfaces and their vicinity of the oxide semiconductor film 120 are easily activated to be low-resistance regions (n-type regions) by application of stress such as an electric field. In the case where the n-type side surfaces and their vicinity overlap with regions between the pair of electrodes 116a and 116b, the n-type regions serve as carrier paths, resulting in formation of a parasitic channel. As a result, the value of the drain current (I_{d}) is increased at or around the threshold voltage, and the threshold voltage shifts in the negative direction.

However, the transistor 150 of one embodiment of the present invention includes the gate electrode 114 and the gate electrode 118 which have the same potential, and, in the channel width direction, the side surfaces of the oxide semiconductor film 120 are provided between one part of the gate electrode 118 and another part thereof with the gate insulating film 111 and the gate insulating film 112 positioned therebetween. Therefore, the side surface of the oxide semiconductor film 120 is influenced by an electric field of the gate electrode 118. Thus, formation of a parasitic channel at the side surface and its vicinity of the oxide semiconductor film 120 can be suppressed. As a result, the transistor 150 has excellent electrical characteristics.

### <Example of Structure of Oxide Semiconductor Film>

The oxide semiconductor film 120 contains In, Zn, and M (M is titanium (Ti), gallium (Ga), yttrium (Y), zirconium (Zr), tin (Sn), lanthanum (La), cerium (Ce), neodymium (Nd), or hafnium (Hf)). Typically, In—Ga oxide, In—Zn oxide, or In-M-Zn oxide can be used for the oxide semiconductor film 120. It is particularly preferable to use an In-M—Zn oxide as the oxide semiconductor film 120.

In the case where the oxide semiconductor film 120 is In-M—Zn oxide, it is preferable that the atomic ratio of metal elements of a sputtering target used for forming a film of the In-M—Zn oxide satisfy In >M (In is greater than or equal to M) and Zn M (Zn is greater than or equal to M). As the atomic ratio of metal elements of such a sputtering target, In:M:Zn=1:1:1, In:M:Zn=1:1:1.2, In:M:Zn=2:1:3, In:M:Zn=3:1:2, and In:M:Zn=4:2:4.1 are preferable.

For example, it is preferable to use a sputtering target with an atomic ratio of In:Ga:Zn=4:2:4.1 to form the In-M—Zn oxide as the oxide semiconductor film 120, in which case the transistor can have high field-effect mobility. The transistor having high field-effect mobility is preferably used in a pixel circuit or a driver circuit (or a driver) in a high-resolution display device typified by 4 k×2 k pixels (3840 pixels in the horizontal direction and 2160 pixels in the perpendicular direction) or 8 k×4 k pixels (7680 pixels in the horizontal direction and 4320 pixels in the perpendicular direction).

Note that the atomic ratio of metal elements in the oxide semiconductor film 120 vary from that in the above-described sputtering target, within a range of ±40% as an error. For example, when a sputtering target with an atomic ratio of In:Ga:Zn=4:2:4.1 is used, an atomic ratio of In:Ga:Zn in the oxide semiconductor film 120 may be 4:2:3 to 4:2:4.1 and its vicinity. For example, when a sputtering target with an atomic ratio of In:Ga:Zn=1:1:1.2 is used, the atomic ratio of In:Ga:Zn in the oxide semiconductor film 120 may be 1:1:1 to 1:1:1.2 and its vicinity.

The oxide semiconductor film 120 contains metal oxide having an energy gap of 2.0 eV or more, preferably 2.5 eV or more, more preferably 3.0 eV or more. The use of metal oxide having such a wide energy gap as the oxide semiconductor film 120 can reduce the off-state current of the transistor 150.

The thickness of the oxide semiconductor film 120 is preferably greater than or equal to 3 nm and less than or equal to 200 nm, more preferably greater than or equal to 3 nm and less than or equal to 100 nm, still more preferably greater than or equal to 3 nm and less than or equal to 50 nm.

When an oxide semiconductor film with a low impurity concentration and a low density of defect states is used as the oxide semiconductor film 120, the transistor can have more excellent electrical characteristics, which is preferable. Here, the state in which impurity concentration is low and density of defect states is low (the amount of oxygen vacancy is small) is referred to as “highly purified intrinsic” or “substantially highly purified intrinsic”. A highly purified intrinsic or substantially highly purified intrinsic oxide semiconductor has few carrier generation sources, and thus has a low carrier density in some cases.

That is, a highly purified intrinsic or substantially highly purified intrinsic oxide semiconductor film is preferably used as the oxide semiconductor film 120. The term “substantially intrinsic” refers to the state where an oxide semiconductor film has a carrier density lower than 8×10¹¹/cm³, preferably lower than 1×10¹¹/cm³, more preferably lower than 1×10¹⁰/cm³, and is higher than or equal to 1×10⁻⁹/cm³. A highly purified intrinsic or substantially highly purified intrinsic oxide semiconductor film has few carrier generation sources, and thus can have a low carrier density. The highly purified intrinsic or substantially highly purified intrinsic oxide semiconductor film has a low density of defect states and accordingly can have a low density of trap states.

A transistor in which a channel is formed in a highly purified intrinsic or substantially highly purified intrinsic oxide semiconductor film is likely to have positive threshold voltage (normally-off characteristics). A highly purified intrinsic or substantially highly purified intrinsic oxide semiconductor film has a low density of defect states and accordingly has a low density of trap states in some cases.

Furthermore, a transistor including a highly purified intrinsic or substantially highly purified intrinsic oxide semiconductor film has an extremely low off-state current; even when a semiconductor element has a channel width of 1×10⁶ μm and a channel length (L) of 10 μm, the off-state current can be less than or equal to the measurement limit of a semiconductor parameter analyzer, i.e., less than or equal to 1×10⁻¹³ A, at a voltage (drain voltage) between a source electrode and a drain electrode of from 1 V to 10 V. Thus, the transistor whose channel region is formed in the oxide semiconductor film has a small variation in electrical characteristics and high reliability.

Charges trapped by the trap states in the oxide semiconductor film take a long time to be released and may behave like fixed charges. Thus, the transistor whose channel region is formed in the oxide semiconductor film having a high density of trap states has unstable electrical characteristics in some cases. Examples of impurities are hydrogen, nitrogen, alkali metal, and alkaline earth metal.

Hydrogen contained in the oxide semiconductor film reacts with oxygen bonded to a metal atom to form water, and also causes oxygen vacancies in a lattice from which oxygen is released (or a portion from which oxygen is released). Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor including an oxide semiconductor film that contains hydrogen is likely to have negative threshold voltage (normally-on characteristics).

Thus, hydrogen in the oxide semiconductor film where a channel of the transistor is formed is preferably reduced as much as possible. Specifically, in the oxide semiconductor film 120, the concentration of hydrogen which is measured by secondary ion mass spectrometry (SIMS) is lower than or equal to 2×10²⁰ atoms/cm³, preferably lower than or equal to 5×10¹⁹ atoms/cm³, more preferably lower than or equal to 1×10¹⁹ atoms/cm³, lower than 5×10¹⁸ atoms/cm³, preferably lower than or equal to 1×10¹⁸ atoms/cm³, more preferably lower than or equal to 5×10¹⁷ atoms/cm³, still more preferably lower than or equal to 1×10¹⁶ atoms/cm³. As a result, the transistor has positive threshold voltage (normally-off characteristics).

When silicon or carbon that is one of elements belonging to Group 14 is contained in the oxide semiconductor film 120, oxygen vacancies are increased in the oxide semiconductor film 120, and the oxide semiconductor film 120 becomes an n-type film. Thus, the concentration of silicon or carbon (the concentration is measured by SIMS) of the oxide semiconductor film 120 is lower than or equal to 2×10¹⁸ atoms/cm³, preferably lower than or equal to 2×10¹⁷ atoms/cm³. As a result, the transistor 150 has positive threshold voltage (normally-off characteristics).

Further, the concentration of alkali metal or alkaline earth metal of the oxide semiconductor film 120, which is measured by SIMS, is lower than or equal to 1×10¹⁸ atoms/cm³, preferably lower than or equal to 2×10¹⁶ atoms/cm³. An alkali metal and an alkaline earth metal might generate carriers when bonded to an oxide semiconductor, in which case the off-state current of the transistor might be increased. Therefore, it is preferable to reduce the concentration of alkali metal or alkaline earth metal in the oxide semiconductor film 120. As a result, the transistor 150 has positive threshold voltage (normally-off characteristics).

When the oxide semiconductor film 120 contains nitrogen, the oxide semiconductor film 120 easily become n-type by generation of electrons serving as carriers and an increase of carrier density. A transistor including an oxide semiconductor film that contains nitrogen is likely to have negative threshold voltage (normally-on characteristics). For this reason, the concentration of nitrogen that is measured by SIMS is preferably set to be, for example, lower than or equal to 5×10¹⁸ atoms/cm³.

It is preferable to perform heat treatment after the oxide semiconductor film used for the channel region of the transistor is formed. The heat treatment is preferably performed at a temperature of higher than or equal to 250° C. and lower than or equal to 650° C., preferably higher than or equal to 300° C. and lower than or equal to 400° C., more preferably higher than or equal to 320° C. and lower than or equal to 370° C., in an inert gas atmosphere, an atmosphere containing an oxidizing gas at 10 ppm or more, or a reduced pressure atmosphere. Alternatively, the heat treatment may be performed in such a manner that heat treatment is performed in an inert gas atmosphere, and then another heat treatment is performed in an atmosphere containing an oxidizing gas at 10 ppm or more in order to compensate released oxygen. The heat treatment here allows impurities such as hydrogen and water to be removed from the oxide semiconductor film. Note that the above-described heat treatment may be performed before the oxide semiconductor film is processed into an island shape.

Note that, without limitation to those described above, a material with an appropriate composition may be used for the oxide semiconductor film depending on required semiconductor characteristics and electrical characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of the oxide semiconductor film be set to appropriate values.

In addition, the oxide semiconductor film 120 preferably includes a c-axis-aligned crystalline oxide semiconductor (CAAC-OS) described later. The CAAC-OS structure has lower density of defect states than a polycrystalline structure, a microcrystalline structure described later, and an amorphous structure.

Note that the oxide semiconductor film 120 may be a mixed film including two or more of the following: a region having a microcrystalline structure, a region having a polycrystalline structure, a CAAC-OS region, and a region having a single-crystal structure. The mixed film has a single-layer structure including, for example, two or more of a region having an amorphous structure, a region having a polycrystalline structure, a CAAC-OS region, and a region having a single-crystal structure in some cases. Further, the mixed film has a stacked-layer structure of two or more of a region having an amorphous structure, a region having a polycrystalline structure, a CAAC-OS region, and a region having a single-crystal structure in some cases.

### <Channel-Etched Transistor>

Here, a channel-etched transistor and a channel protective transistor are compared.

In a channel protective transistor including two gate electrodes (a first gate electrode and a second gate electrode) with an oxide semiconductor film positioned therebetween, a first insulating film is formed over a first gate electrode, and the oxide semiconductor film is formed over the first insulating film in the transistor. A channel protective film is formed over the oxide semiconductor film, and a pair of electrodes in contact with the oxide semiconductor film is formed over the channel protective film. A second insulating film is formed over the channel protective film and the pair of electrodes, and a second gate electrode is formed over the second insulating film.

The channel protective film is damaged by exposure to plasma in an etching process for forming the pair of electrodes. Thus, defects are easily formed in the channel protective film.

Furthermore, in the channel protective transistor, the pair of electrodes blocks an electric field applied from the second gate electrode to regions in the oxide semiconductor film which overlap with the pair of electrodes, so that the electric field from the second gate electrode does not evenly affect the oxide semiconductor film. As a result, the amount of carriers that flow in the oxide semiconductor film when induced by the electric field from the second gate electrode is reduced.

However, in the transistor 150 described in this embodiment is a channel-etched transistor, and therefore, a region in the gate insulating film 112 between the oxide semiconductor film 120 and the gate electrode 118 is not exposed to an etching atmosphere. Thus, the transistor 150 has few defects in the gate insulating film 112 and thus has high reliability.

In addition, in the transistor 150 described in this embodiment, the electric field from the gate electrode 118 evenly affects a back channel of the oxide semiconductor film 120. Furthermore, the electric field from the gate electrode 118 also affects the side surface of the oxide semiconductor film 120. As a result, carriers flow in a wide region in the oxide semiconductor film 120, so that the field-effect mobility and the on-state current of the transistor are increased.

Furthermore, in the channel protective transistor, one end portion of each of the pair of electrodes is positioned over the channel protective film to make a connection between the oxide semiconductor film and each of the pair of electrodes. The one end portion of each of the pair of electrodes is positioned on an inner side of a connection region of the oxide semiconductor film and each of the pair of electrodes. For this reason, in consideration of misalignment of a photomask, the distance between the connection regions of the oxide semiconductor film and the pair of electrodes needs to be designed to be long.

In contrast, in the channel-etched transistor 150, the oxide semiconductor film 120 is directly in contact with one end portion of each of a pair of electrodes 116a and 116b. Thus, the distance between the pair of electrodes in the channel-etched transistor 150 can be made small easily in comparison with the channel protective transistor.

Each of the gate electrode 114 and the gate electrode 118 in the channel-etched transistor 150 has a function of blocking an external electric field. Thus, fixed charges between the substrate 100 and the gate electrode 114 and over the gate electrode 118 do not affect the oxide semiconductor film 120. Thus, degradation due to a stress test (e.g., a negative gate bias temperature (−GBT) stress test in which a negative potential is applied to a gate electrode) can be reduced, and changes in the rising voltages of on-state current at different drain voltages can be suppressed.

The BT stress test is one kind of accelerated test and can evaluate, in a short time, change in characteristics (i.e., a change over time) of transistors, which is caused by long-term use. In particular, the amount of change in the threshold voltage of the transistor between before and after the BT stress test is an important indicator when examining the reliability of the transistor. As the amount of change in the threshold voltage between before and after the BT stress test is small, the transistor has higher reliability.

On the other hand, the channel-etched transistor changes in characteristics in some cases due to damage or impurity contamination in a region of the oxide semiconductor film 120 in contact with the gate insulating film 112 in a process such as a film formation step or an etching step of the pair of electrodes 116a and 116b.

Furthermore, a transistor including an oxide semiconductor is operated by the accumulation of electrons that are major carriers. Thus, there is a bulk current in the oxide semiconductor film 120 in addition to the accumulation current on the gate insulating film 111 side of the oxide semiconductor film. Because of this, when a trap state due to damage or impurity contamination during processing is present on the gate insulating film 112 side of the oxide semiconductor film 120, a carrier is easily trapped by the trap state.

### <Buried Channel Structure>

The oxide semiconductor film 120 in the transistor 150 of one embodiment of the present invention includes the oxide semiconductor film 120a and the oxide semiconductor film 120b. That is, the oxide semiconductor film 120 has a two-layer structure of oxides differing in composition. Part of the oxide semiconductor film 120a functions as a channel region of the transistor 150.

At least one element in the oxide semiconductor film 120a is the same as at least one element in the oxide semiconductor film 120b. Thus, interface scattering is unlikely to occur at the interface between the oxide semiconductor films 120a and 120b. Thus, the transistor can have high field-effect mobility because the movement of carriers is not hindered at the interface.

The oxide semiconductor film 120a contains metal oxide, and the metal oxide contains at least In or Zn. The oxide semiconductor film 120a typically contains In—Ga oxide, In—Zn oxide, or In-M—Zn oxide (M is Ti, Ga, Y, Zr, Sn, La, Ce, Nd, or Hf).

Note that in the case where the oxide semiconductor film 120a contains In-M—Zn oxide, the proportion of In and the proportion of M, not taking Zn and oxygen into consideration, are preferably greater than 25 atomic % and less than 75 atomic %, respectively, more preferably greater than 34 atomic % and less than 66 atomic %, respectively.

The oxide semiconductor film 120b contains metal oxide, and the metal oxide contains at least In or Zn. The oxide semiconductor film 120b typically contains In—Ga oxide, In—Zn oxide, or In-M—Zn oxide (M is Ti, Ga, Y, Zr, Sn, La, Ce, Nd, or Hf).

The energy at the conduction band minimum of the oxide semiconductor film 120b is closer to the vacuum level than that of the oxide semiconductor film 120a is; typically, an energy difference between the conduction band minimum of the oxide semiconductor film 120a and the conduction band minimum of the oxide semiconductor film 120b is greater than or equal to 0.1 eV and less than or equal to 2 eV, preferably greater than or equal to 0.2 eV and less than or equal to 0.5 eV. That is, the difference between the electron affinity of the oxide semiconductor film 120a and the electron affinity of the oxide semiconductor film 120b is greater than or equal to 0.1 eV and less than or equal to 2 eV, preferably greater than or equal to 0.2 eV and less than or equal to 0.5 eV.

Note that in the case where the oxide semiconductor film 120b contains In-M—Zn oxide, the proportion of In and the proportion of M, not taking Zn and O into consideration, are less than 75 atomic % and greater than 25 atomic %, respectively, preferably less than 66 atomic % and greater than 34 atomic %, respectively.

In the case where the oxide semiconductor film 120b contains In-M oxide containing a larger amount of the element M than the amount of In in an atomic ratio, any of the following effects may be obtained: (1) the energy gap of the oxide semiconductor film 120b is widened; (2) the electron affinity of the oxide semiconductor film 120b is reduced; (3) an impurity from the outside is blocked; and (4) an insulating property increases. Further, oxygen vacancies are less likely to be generated in the oxide semiconductor film containing a larger amount of the element M in an atomic ratio than the amount of In in an atomic ratio because M is a metal element which is strongly bonded to oxygen.

In the case where the oxide semiconductor film 120a and the oxide semiconductor film 120b contain In-M—Zn oxide (M is Ti, Ga, Y, Zr, Sn, La, Ce, Nd, or Hf), the amount of the element M in the atomic ratio of the oxide semiconductor film 120b is larger than the amount of the element M in an atomic ratio of the oxide semiconductor film 120a. Typically, the amount of the element M in the atomic ratio of the oxide semiconductor film 120b is preferably 1.5 or more times, more preferably two or more times as large as the amount of the element M in the atomic ratio of the oxide semiconductor film 120a.

In the case where the oxide semiconductor film 120a and the oxide semiconductor film 120b contain In-M—Zn oxide (M is Ti, Ga, Y, Zr, Sn, La, Ce, Nd, or Hf), the amount of In in the atomic ratio of the oxide semiconductor film 120a is larger than or equal to the amount of In in the atomic ratio of the oxide semiconductor film 120b. Typically, the amount of In in the atomic ratio of the oxide semiconductor film 120b is preferably 1.5 or more times, more preferably two or more times as large as the amount of In in the atomic ratio of the oxide semiconductor film 120a. The transistor including the oxide semiconductor film 120a having such an atomic ratio can be expected to have high on-state current and high field-effect mobility. Note that the transistor with high field-effect mobility has negative threshold voltage (normally-on characteristics) in some cases. This is because electric charges are generated owing to oxygen vacancies in the oxide semiconductor film in the transistor and the resistance is thus reduced. The transistor having normally-on characteristics causes various problems in that malfunction is likely to be caused when in operation and that power consumption is increased when not in operation, for example. Thus, it is preferable to use, as the oxide semiconductor film 120a, CAAC-OS which is described later and includes few impurities or defects (e.g., oxygen vacancies).

In the case where the oxide semiconductor film 120a and the oxide semiconductor film 120b contain In-M—Zn oxide (M is Ti, Ga, Y, Zr, Sn, La, Ce, Nd, or Hf), when the oxide semiconductor film 120a has an atomic ratio of In:M:Zn=xₐ:yₐ:zₐ and the oxide semiconductor film 120b has an atomic ratio of In:M:Zn=x_{b}:y_{b}:z_{b}, y_{b}/x_{b} is larger than yₐ/xₐ, preferably y_{b}/x_{b} is 1.5 or more times as large as yₐ/xₐ, more preferably, y_{b}/x_{b} is two or more times as large as yₐ/xₐ. In this case, it is preferable that in the oxide semiconductor film 120b, y_{b} be higher than or equal to x_{b} because a transistor including the oxide semiconductor film can have stable electrical characteristics.

In the case where the oxide semiconductor film 120a contains In-M—Zn oxide (M is Ti, Ga, Y, Zr, Sn, La, Ce, Nd, or Hf), it is preferable that the atomic ratio of metal elements of a sputtering target used for forming a film of the oxide semiconductor film 120a satisfy In M and Zn M. When the sputtering target has the atomic ratio of metal elements of In:M:Zn=xₐ:yₐ:zₐ, xₐ/yₐ is preferably greater than or equal to ⅓ and less than or equal to 6, more preferably greater than or equal to 1 and less than or equal to 6, and zₐ/yₐ is preferably greater than or equal to ⅓ and less than or equal to 6, more preferably greater than or equal to 1 and less than or equal to 6. Note that when zₐ/yₐ is greater than or equal to 1 and less than or equal to 6, a c-axis-aligned crystalline oxide semiconductor (CAAC-OS) film described later as the oxide semiconductor film 120a is easily formed. Typical examples of the atomic ratio of the metal elements of the target are In:M:Zn=1:1:1, In:M:Zn=1:1:1.2, In:M:Zn=3:1:2, In:M:Zn=4:2:4.1.

In the case where the oxide semiconductor film 120b contains In-M—Zn oxide (M is Ti, Ga, Y, Zr, Sn, La, Ce, Nd, or Hf), it is preferable that the atomic ratio of metal elements of a sputtering target used for forming the oxide semiconductor film 120b satisfy M≧In. When the sputtering target has the atomic ratio of metal elements of In:M:Zn=x_{b}:y_{b}:z_{b}, x_{b}/y_{b} is preferably less than xₐ/yₐ, and z_{b}/y_{b} is preferably greater than or equal to ⅓ and less than or equal to 6, more preferably greater than or equal to 1 and less than or equal to 6. Note that when z_{b}/y_{b} is greater than or equal to 1 and less than or equal to 6, a CAAC-OS film described later is easily formed as the oxide semiconductor film 120b. Typical examples of the atomic ratio of the metal elements of the target are In:M:Zn=1:1:1, In:M:Zn=1:1:1.2, In:M:Zn=1:3:2, In:M:Zn=1:3:4, In:M:Zn=1:3:6, and In:M:Zn=1:3:8.

Note that a proportion of each atom in the atomic ratio of each of the oxide semiconductor films 120a and 120b varies within a range of ±40% of the above atomic ratio as an error.

The oxide semiconductor film 120b has a function of relieving damage to the oxide semiconductor film 120a when the insulating film 107 is formed. For that reason, the insulating film 107 may be formed over the oxide semiconductor film 120b without forming the insulating film 106.

The transistor 150 includes the oxide semiconductor film 120b between the oxide semiconductor film 120a and the insulating film 106. Hence, if carrier traps are formed between the oxide semiconductor film 120b and the insulating film 106 owing to impurities or defects, electrons flowing in the oxide semiconductor film 120a are less likely to be captured by the carrier traps because there is a distance between the carrier traps and the oxide semiconductor film 120a. Accordingly, the amount of on-state current of the transistor 150 can be increased, or the field-effect mobility of the transistor 150 can be increased. When electrons are captured by the carrier traps, the electrons behave as negative fixed charges, resulting in a change of the threshold voltage of the transistor. However, by the distance between the region where the carrier traps are formed and the oxide semiconductor film 120a, the influence of capture of the electrons by the carrier traps in the transistor 150 can be reduced, or change in the threshold voltage of the transistor 150 can be reduced.

The oxide semiconductor film 120b preferably has a function of blocking external impurity, and accordingly, the amount of impurities which move from the outside to the oxide semiconductor film 120a can be reduced. Furthermore, an oxygen vacancy is less likely to be formed in the oxide semiconductor film 120b. Consequently, the impurity concentration and oxygen vacancies in the oxide semiconductor film 120a can be reduced.

Note that the oxide semiconductor films 120a and 120b are not formed by simply stacking each film, but are formed to form a continuous junction (here, in particular, a structure in which the conduction band minimum is changed continuously between each film). In other words, a stacked-layer structure in which there exist no impurity which forms a defect level such as a trap center or a recombination center at each interface is provided.

If a continuous junction is not formed and an impurity exists between the oxide semiconductor films 120a and 120b that are stacked, a continuity of the energy band is damaged, and the carrier is trapped or recombined at the interface and then disappears.

Specifically, to make the continuous junction, the films are preferably stacked in succession without exposure to the air using a deposition apparatus (sputtering apparatus) of a multi chamber type with a load lock chamber. Each chamber in the sputtering apparatus is preferably evacuated to be a high vacuum state (to a degree of about 5×10⁻⁷ Pa to 1×10⁻⁴ Pa) with an adsorption vacuum pump such as a cryopump in order to remove water or the like, which serves as an impurity against the oxide semiconductor film, as much as possible. Alternatively, a turbo molecular pump and a cold trap are preferably combined so as to prevent a backflow of a gas, especially a gas containing carbon or hydrogen from an exhaust system to the inside of the chamber.

### Modification Example 1

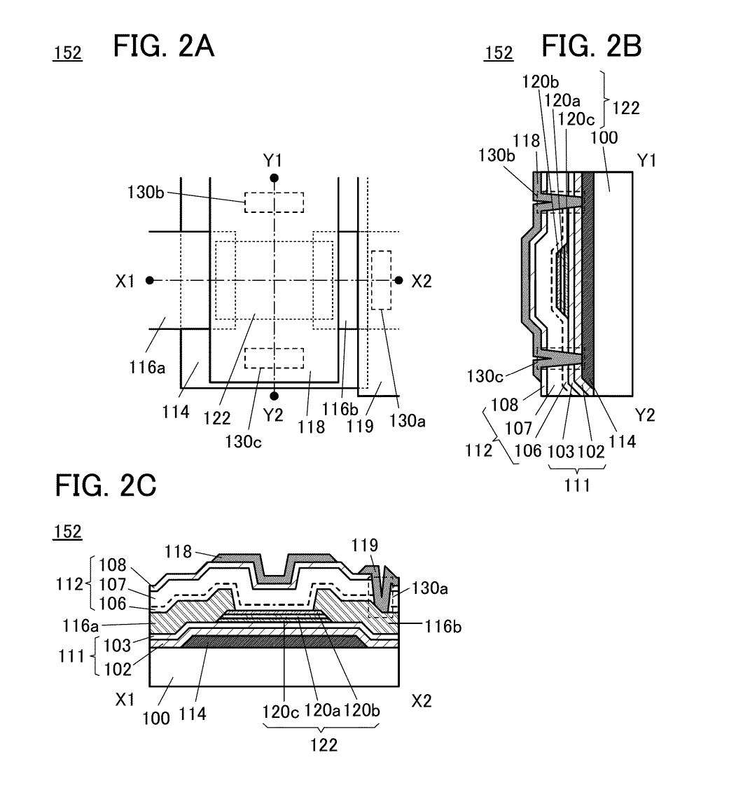

As in a transistor 152 shown in FIGS. 2A to 2C, an oxide semiconductor film 122 may include the oxide semiconductor film 120a, the oxide semiconductor film 120b, and an oxide semiconductor film 120c. That is, the oxide semiconductor film 122 has a three-layer structure. Part of the oxide semiconductor film 120a functions as a channel region of the transistor 152.

The oxide semiconductor film 120c is in contact with the gate insulating film 111. That is, the oxide semiconductor film 120c in the oxide semiconductor film 122 is provided between the gate insulating film 111 and the oxide semiconductor film 120a. The oxide semiconductor film 120b is in contact with the gate insulating film 112. That is, the oxide semiconductor film 120b in the oxide semiconductor film 122 is provided between the gate insulating film 112 and the oxide semiconductor film 120a.

The oxide semiconductor film 120c can be formed using a material and a formation method similar to those of the oxide semiconductor film 120b.

It is preferable that the thickness of the oxide semiconductor film 120c be smaller than that of the oxide semiconductor film 120a. When the thickness of the oxide semiconductor film 120c is greater than or equal to 1 nm and less than or equal to 5 nm, preferably greater than or equal to 1 nm and less than or equal to 3 nm, the amount of change in the threshold voltage of the transistor 152 can be reduced.

As in the transistor 150, the oxide semiconductor film 120b of the transistor 152 has a function of relieving damage to the oxide semiconductor film 120a when the insulating film 107 is formed. For that reason, the insulating film 107 may be formed over the oxide semiconductor film 120b without forming the insulating film 106.

The transistor 152 includes the oxide semiconductor film 120b between the oxide semiconductor film 120a and the insulating film 106. Hence, if carrier traps are formed between the oxide semiconductor film 120b and the insulating film 106 owing to impurities or defects, electrons flowing in the oxide semiconductor film 120a are less likely to be captured by the carrier traps because there is a distance between the carrier traps and the oxide semiconductor film 120a. Accordingly, the amount of on-state current of the transistor 152 can be increased, or the field-effect mobility of the transistor 152 can be increased. When electrons are captured by the carrier traps, the electrons behave as negative fixed charges, resulting in a change of the threshold voltage of the transistor. However, by the distance between the region where the carrier traps are formed and the oxide semiconductor film 120a, the influence of capture of the electrons by the carrier traps in the transistor 152 can be reduced, or change in the threshold voltage of the transistor 152 can be reduced.

The oxide semiconductor film 120b preferably has a function of blocking external impurity, and accordingly, the amount of impurities which move from the outside to the oxide semiconductor film 120a can be reduced. Furthermore, an oxygen vacancy is less likely to be formed in the oxide semiconductor film 120b. Consequently, the impurity concentration and oxygen vacancies in the oxide semiconductor film 120a can be reduced.

In the transistor 152, the oxide semiconductor film 120c is provided between the gate insulating film 111 and the oxide semiconductor film 120a, and the oxide semiconductor film 120b is provided between the oxide semiconductor film 120a and the gate insulating film 112. Thus, it is possible to reduce the concentration of silicon or carbon in the vicinity of the interface between the oxide semiconductor film 120c and the oxide semiconductor film 120a, the concentration of silicon or carbon in the oxide semiconductor film 120a, or the concentration of silicon or carbon in the vicinity of the interface between the oxide semiconductor film 120b and the oxide semiconductor film 120a.

The transistor 152 having such a structure includes very few defects in the oxide semiconductor film 122 including the oxide semiconductor film 120a; thus, the electrical characteristics are improved. Typically, the on-state current and field-effect mobility of the transistor 152 can be increased. Further, in a BT stress test and a BT photostress test which are examples of a stress test, the amount of change in the threshold voltage of the transistor 152 is small, and thus, reliability is high.

### <Band Structure in Transistor>

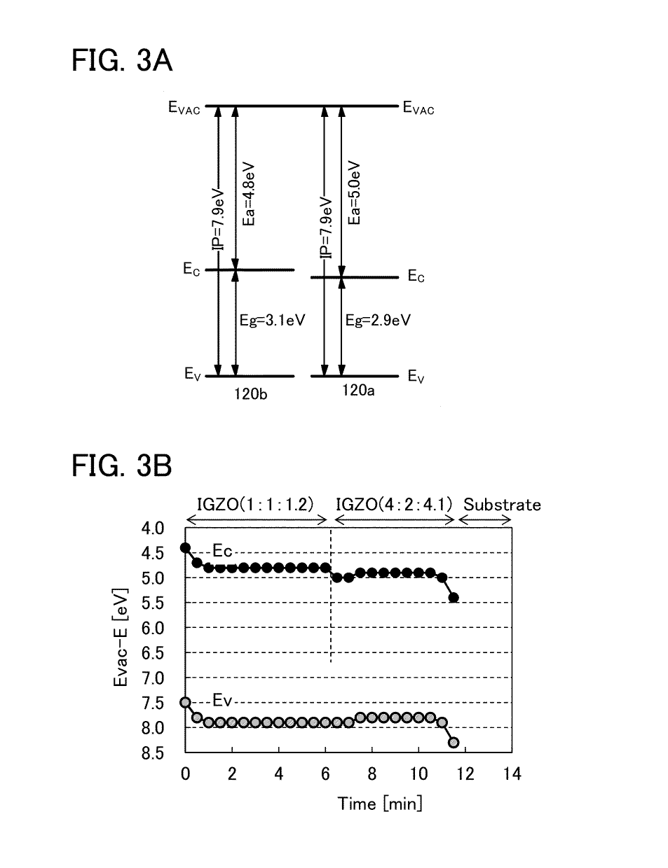

Next, band structures of the oxide semiconductor films in the transistor 150 shown in FIGS. 1A to 1C and the transistor 152 shown in FIGS. 2A to 2C will be described with reference to FIGS. 3A and 3B, FIGS. 4A to 4C, and FIGS. 5A and 5B.

FIGS. 3A and 3B show, as examples, measurement results of band structures in the case of using In—Ga—Zn oxide with an atomic ratio of In:Ga:Zn=4:2:4.1 as a sputtering target for forming the oxide semiconductor film 120a and the case of using In—Ga—Zn oxide with an atomic ratio of In:Ga:Zn=1:1:1.2 as a sputtering target for forming the oxide semiconductor film 120b. In the measurement results, the energy gap of the oxide semiconductor film 120a is 2.9 eV, and the energy gap of the oxide semiconductor film 120b is 3.1 eV. The energy gaps were measured using a spectroscopic ellipsometer (UT-300 manufactured by HORIBA JOBIN YVON S.A.S.).

The energy difference between the vacuum level and the valence band maximum (also referred to as ionization potential) of the oxide semiconductor film 120a and the energy difference between the vacuum level and the valence band maximum of the oxide semiconductor film 120b are each 7.9 eV. Note that the energy difference between the vacuum level and the valence band maximum was measured using an ultraviolet photoelectron spectroscopy (UPS) device (VersaProbe manufactured by ULVAC-PHI, Inc.).

Thus, the energy difference between the vacuum level and the conduction band minimum (also referred to as electron affinity) of the oxide semiconductor film 120a and the energy difference between the vacuum level and the conduction band minimum of the oxide semiconductor film 120b are 5.0 eV and 4.8 eV, respectively. That is, a band diagram in the oxide semiconductor film 120a and the oxide semiconductor film 120b as shown in FIG. 3A is obtained. In FIGS. 3A and 3B, EVAC denotes the energy of vacuum level, E_{C} denotes the energy of the conduction band minimum, E_{V} denotes the energy of the valence band maximum, Eg denotes the energy gap, IP denotes the ionization potential, and Ea denotes the electron affinity.

The difference between the energy of the conduction band minimum of the oxide semiconductor film 120a and the energy of the conduction band minimum of the oxide semiconductor film 120b is 0.2 eV.

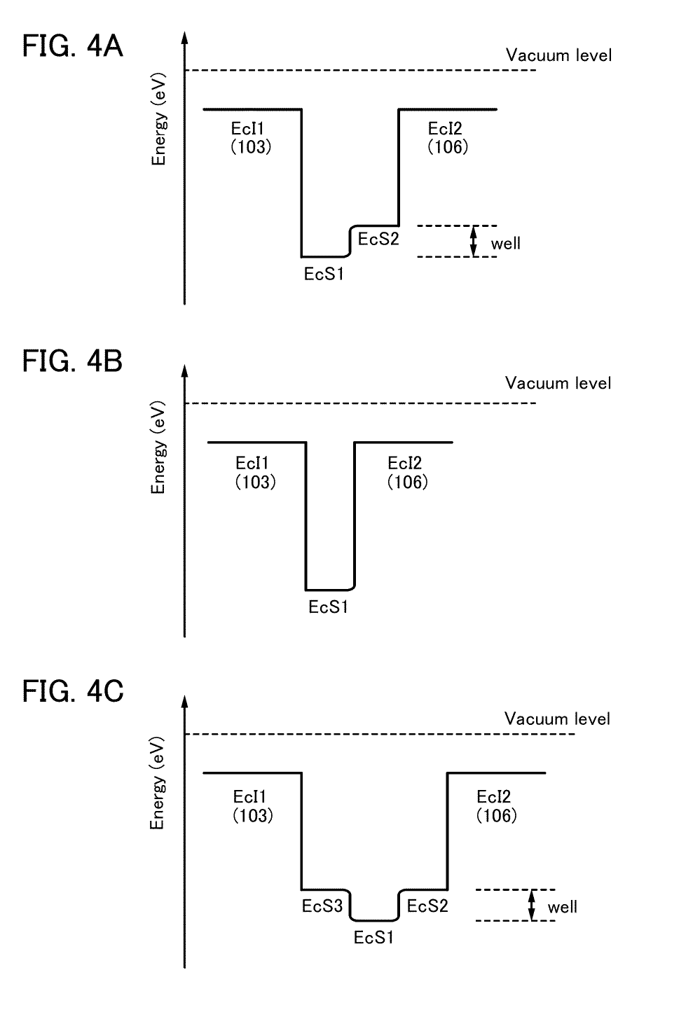

FIG. 4A schematically shows part of the band structure in the transistor 150. In FIGS. 4A and 4B, the insulating films 103 and 106 are silicon oxide films provided in contact with the oxide semiconductor film 120.

In FIGS. 4A to 4C, EcI1 denotes the energy of the conduction band minimum in the silicon oxide film; EcS1 denotes the energy of the conduction band minimum in the oxide semiconductor film 120a; and EcI2 denotes the energy of the conduction band minimum in the silicon oxide film. EcS2 in FIGS. 4A and 4C denotes the energy of the conduction band minimum in the oxide semiconductor film 120b. EcI1 denotes the energy of the conduction band minimum of the insulating films 103 of the transistor 150, and EcI2 denotes the energy of the conduction band minimum of the insulating films 106 of the transistor 150.

As shown in FIG. 4A, there is no energy barrier between the oxide semiconductor films 120a and 120b, and the energy of the conduction band minimums thereof smoothly vary. In other words, the energy level of the conduction band minimum is continuously changed. This is because the oxide semiconductor film 120a contains an element contained in the oxide semiconductor film 120b and oxygen is transferred between the oxide semiconductor film 120a and the oxide semiconductor film 120b, so that a mixed layer is formed.

It is shown from FIG. 4A that the oxide semiconductor film 120a serves as a well and a channel region is formed in the oxide semiconductor film 120a in the transistor 150 including the oxide semiconductor film 120a and the oxide semiconductor film 120b. Note that since the energy of the conduction band minimum of the oxide semiconductor film 120 is continuously changed, it can be said that the oxide semiconductor film 120a and the oxide semiconductor film 120b have a continuous junction. Therefore, such an energy band structure is also referred to as a buried channel structure.

Although trap states due to impurities or defects might be generated in the vicinity of the interface between the oxide semiconductor film 120b and the insulating film 106 as shown in FIG. 4A, the oxide semiconductor film 120a can be distanced from the region where the trap states are generated owing to the existence of the oxide semiconductor film 120b. However, when the energy difference between EcS1 and EcS2 is small, electrons in the oxide semiconductor film 120a might reach the trap level across the energy difference. When the electron is trapped by the trap state, a negative fixed electric charge is generated at the interface with the insulating film 106, so that the threshold voltage of the transistor is shifted in the positive direction. Thus, it is preferable that the energy difference between EcS1 and EcS2 be greater than or equal to 0.1 eV and less than or equal to 2 eV, preferably greater than or equal to 0.2 eV and less than or equal to 0.5 eV, because a change in the threshold voltage of the transistor 150 is reduced and stable electrical characteristics are obtained.

To prevent the oxide semiconductor film 120b from functioning as part of a channel region, a material having lower conductivity than the oxide semiconductor film 120a is used for the oxide semiconductor film 120b. Alternatively, a material which has a smaller electron affinity (a difference in energy level between the vacuum level and the conduction band minimum) than the oxide semiconductor film 120a and has a difference in the energy level of the conduction band minimum from the oxide semiconductor film 120a (band offset) is used for the oxide semiconductor film 120b. Furthermore, to inhibit generation of a difference between threshold voltages due to the value of the drain voltage, it is preferable to form the oxide semiconductor film 120b using a material in which the energy level of the conduction band minimum is closer to the vacuum level than the energy level of the conduction band minimum of the oxide semiconductor film 120a is by more than 0.1 eV, preferably 0.2 eV or more.

It is preferable that the oxide semiconductor film 120b not have a spinel crystal structure. If the oxide semiconductor film 120b has a spinel crystal structure, constituent elements of the pair of electrodes 116a and 116b might be diffused into the oxide semiconductor film 120a at the interface between the spinel structure and another region. Note that the oxide semiconductor film 120b is preferably a CAAC-OS described later, in which case a higher blocking property against constituent elements of the pair of electrodes 116a and 116b, e.g., a copper element, is obtained.

The thickness of the oxide semiconductor film 120b is greater than or equal to a thickness that is capable of inhibiting diffusion of the constituent element of the pair of electrodes 116a and 116b into the oxide semiconductor film 120a, and less than a thickness which inhibits supply of oxygen from the insulating film 106 to the oxide semiconductor film 120a. For example, when the thickness of the oxide semiconductor film 120b is greater than or equal to 10 nm, the constituent element of the pair of electrodes 116a and 116b can be prevented from diffusing into the oxide semiconductor film 120a. When the thickness of the oxide semiconductor film 120b is less than or equal to 100 nm, oxygen can be effectively supplied from the insulating films 106 and 107 to the oxide semiconductor film 120a. That is, the thickness of the oxide semiconductor film 120b preferably ranges from 10 nm to 100 nm.

FIG. 4B schematically shows part of a band structure of the transistor 150, which is a modification example of the band structure shown in FIG. 4A.

In the transistor of FIG. 4B, an upper portion of the oxide semiconductor film 120, i.e., the oxide semiconductor film 120b might be etched in formation of the pair of electrodes 116a and 116b. Furthermore, a mixed film of the oxide semiconductor films 120a and 120b is likely to be formed on the top surface of the oxide semiconductor film 120a in formation of the oxide semiconductor film 120b.

For example, Ga content in the oxide semiconductor film 120b is higher than that in the oxide semiconductor film 120a in the case where the oxide semiconductor film 120a is an oxide semiconductor film formed with use of, as a sputtering target, In—Ga—Zn oxide whose atomic ratio of In to Ga and Zn is 4:2:4.1 and the oxide semiconductor film 120b is an oxide semiconductor film formed with use of, as a sputtering target, In—Ga—Zn oxide whose atomic ratio of In to Ga and Zn is 1:1:1.2. Thus, a GaOx layer or a mixed layer whose Ga content is higher than that in the oxide semiconductor film 120a can be formed on the top surface of the oxide semiconductor film 120a.

For that reason, even in the case where the oxide semiconductor film 120b is etched, the energy of the conduction band minimum of EcS1 on the EcI2 side is increased and the band structure shown in FIG. 4B can be obtained in some cases.

As in the band structure shown in FIG. 4B, in observation of a cross section of a channel region, only the oxide semiconductor film 120a in the oxide semiconductor film 120 is apparently observed in some cases. However, a mixed layer that contains Ga more than the oxide semiconductor film 120a is formed over the oxide semiconductor film 120a in fact, and thus the mixed layer can be regarded as a 1.5-th layer. Note that the mixed layer can be confirmed by analyzing a composition in the upper portion of the oxide semiconductor film 120a, when the elements contained in the oxide semiconductor film 120 are measured by an EDX analysis, for example. The mixed layer can be confirmed, for example, in such a manner that the Ga content in the composition in the upper portion of the oxide semiconductor film 120a is larger than the Ga content in the oxide semiconductor film 120a.

FIG. 4C schematically shows part of a band structure of the transistor 152. In FIG. 4C, the insulating films 103 and 106 are silicon oxide films in contact with the oxide semiconductor film 122. EcS3 denotes the energy of the conduction band minimum in the oxide semiconductor film 120c.

As shown in FIG. 4C, there is no energy barrier between the oxide semiconductor films 120a, 120b, and 120c, and the conduction band minimums thereof smoothly vary. In other words, the energy level of the conduction band minimum is continuously changed. This is because the oxide semiconductor films 120a, 120b, and 120c contain a common element and oxygen is transferred between the oxide semiconductor film 120a and the oxide semiconductor film 120c and between the oxide semiconductor film 120a and the oxide semiconductor film 120b.

It is shown from FIG. 4C that the oxide semiconductor film 120a serves as a well and a channel region is formed in the oxide semiconductor film 120a in the transistor 152 including the oxide semiconductor film 120a, the oxide semiconductor film 120b, and the oxide semiconductor film 120c. Note that since the energy of the conduction band minimum of the oxide semiconductor film 122 is continuously changed, it can be said that the oxide semiconductor films 120a, 120b, and 120c have a continuous junction.

Although trap states due to impurities or defects might be generated in the vicinity of the interface between the oxide semiconductor film 120b and the insulating film 106 and in the vicinity of the interface between the oxide semiconductor film 120c and the insulating film 103 as shown in FIG. 4C, the oxide semiconductor film 120a can be distanced from the region where the trap states are generated owing to the existence of the oxide semiconductor films 120b and 120c. However, when the energy difference between EcS1 and EcS2 and the energy difference between EcS1 and EcS3 are small, electrons in the oxide semiconductor film 120a might reach the trap level across the energy difference. When the electron is trapped by the trap state, a negative fixed electric charge is generated on the insulating film, so that the threshold voltage of the transistor is shifted in the positive direction. Thus, it is preferable that the energy difference between EcS1 and EcS2 and the energy difference between EcS1 and EcS3 be greater than or equal to 0.1 eV, preferably greater than or equal to 0.2 eV, because a change in the threshold voltage of the transistor 152 is reduced and stable electrical characteristics are obtained.

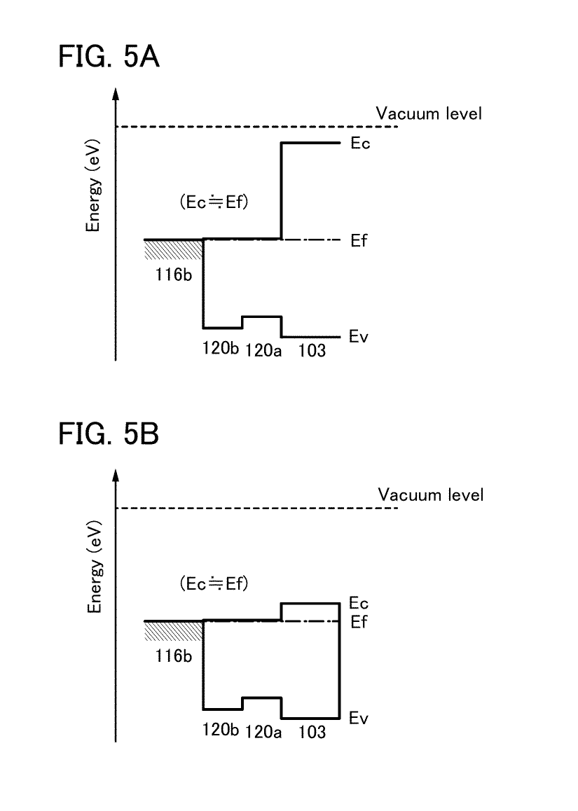

FIG. 5A shows a band structure of a region including a source region or a drain region of the transistor 150. Note that the oxide semiconductor films 120a and 120b are assumed to be in a degenerate state, and the energy (Ec) of the conduction band minimum is assumed to be approximately the same as the Fermi level (Ef).

When the pair of electrodes 116a and 116b is formed over the oxide semiconductor film 120, an oxygen vacancy is formed at the interface between the oxide semiconductor films 120a and 120b and hydrogen is bonded to the oxygen vacancy. Thus, the oxide semiconductor films 120a and 120b become n-type oxide semiconductor films 120a and 120b, so that low-resistance regions can be formed.

In this case, an ohmic contact is made between one of the electrodes 116a and 116b (here, the electrode 116b) functioning as source and drain electrodes and the oxide semiconductor films 120a and 120b because an energy barrier is sufficiently low. Thus, electrons are smoothly accepted and donated between one of the electrodes 116a and 116b and the oxide semiconductor films 120a and 120b.

In a transistor including an intrinsic or substantially intrinsic oxide semiconductor film, when the distance between the pair of electrodes is sufficiently short, the conduction band minimum is low because of the electric fields of the pair of electrodes, so that the energy of the conduction band minimum is close to the Fermi level (see FIG. 5B). This phenomenon is called a conduction band lowering (CBL) effect. Owing to the CBL effect, a drain current starts to flow at a low voltage that is close to 0 V in the V_{g}-I_{d} characteristics, so that the driving voltage of the transistor may be reduced.

Note that description similar to that of FIGS. 5A and 5B can be made also on a region where the other of the pair of electrodes 116a and 116b (here, the electrode 116a) of the transistor 150 is in contact with the oxide semiconductor films 120a and 120b.

### <Electrical Characteristics of Transistor>

The transistor 150, which has the s-channel structure and two oxide semiconductor layers as described above, is preferably used in a display device including an organic electroluminescent element (also referred to as an organic EL element) as a light-emitting element.

An organic EL element is a current-driving-type element. For a transistor controlling the organic EL element, field-effect mobility and on-state current in a saturation region (a voltage region where a drain voltage is higher than a voltage obtained by subtracting a threshold voltage from a gate voltage, i.e., V_{d}>V_{g}−Vₜₕ) of the transistor are particularly important among electrical characteristics. Owing to the s-channel structure, the on-state current and field-effect mobility of the transistor 150 can be increased.

The channel width of the transistor with high field-effect mobility can be made short. When such a transistor is used in a gate driver of a display device, a small-sized gate driver can be obtained. Moreover, the display device can have a narrow bezel, the display device can have high resolution, or the power consumption of the display device can be reduced because the gate voltage can be reduced. Note that the details of the gate driver will be described later.

Here, the electrical characteristics of the transistor of one embodiment of the present invention are described.

### <Structure of Transistor>

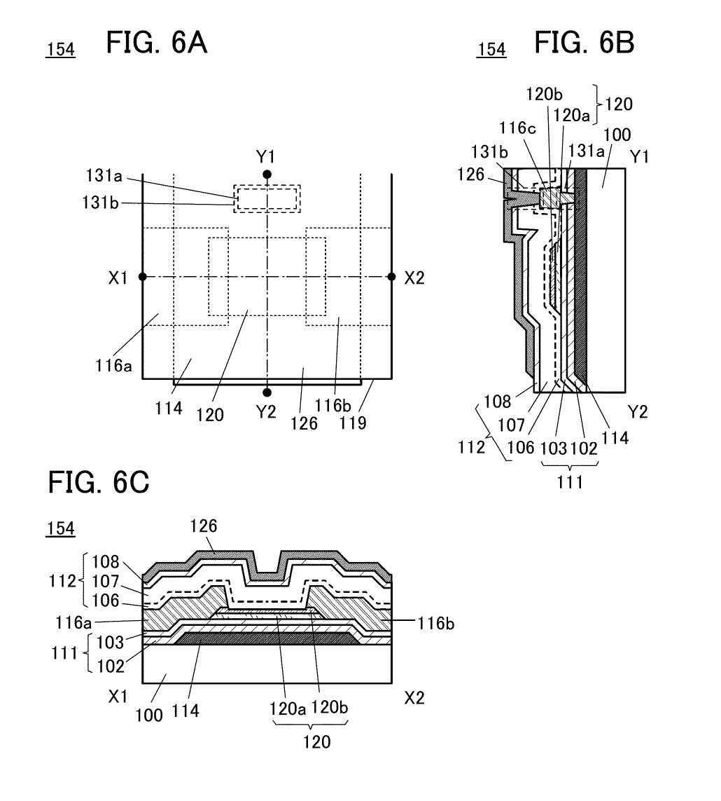

First, a transistor 154 shown in FIGS. 6A to 6C is described. FIG. 6A is a top view of the transistor 154. FIG. 6B is a cross-sectional view taken along the dashed dotted line Y1-Y2 in FIG. 6A, and FIG. 6C is a cross-sectional view taken along the dashed dotted line X1-X2 in FIG. 6A.

The transistor 154 includes the gate electrode 114 functioning as a first gate electrode over the substrate 100, the insulating film 102 over the substrate 100 and the gate electrode 114, the insulating film 103 over the insulating film 102, the oxide semiconductor film 120 over the insulating film 103, and the pair of electrodes 116a and 116b functioning as source and drain electrodes electrically connected to the oxide semiconductor film 120.

Over the transistor 154, specifically, over the pair of electrodes 116a and 116b and the oxide semiconductor film 120, the insulating films 106, 107, and 108 are provided. A gate electrode 126 is provided over the insulating film 108. An opening portion 131a reaching the gate electrode 114 is provided in the insulating films 102 and 103, and a conductive film 116c is formed to cover the opening portion 131a. An opening portion 131b reaching the conductive film 116c is provided in the insulating films 106, 107, and 108. The gate electrode 126 is connected to the conductive film 116c through the opening portion 131b. That is, the gate electrode 114 and the gate electrode 126 are electrically connected to each other. A planarization insulating film is provided over the gate electrode 126. Note that the gate electrode 126 functions as a second gate electrode (also referred to as a back gate electrode) of the transistor 154. The oxide semiconductor film 120 includes the oxide semiconductor film 120a and the oxide semiconductor film 120b.

In this embodiment, a semiconductor element 1 corresponding to the transistor 154 shown in FIGS. 6A to 6C was formed and evaluated. Note that the semiconductor element 1 was a transistor having the s-channel structure and two oxide semiconductor layers. For comparison, a semiconductor element 2 having two oxide semiconductor layers and not having the gate electrode 126 was formed. The semiconductor elements 1 and 2 each had a channel length L of 6 μm and a channel width W of 3 μm.

### <Manufacturing Process of Semiconductor Element>

First, the gate electrode 114 was formed over the substrate 100. A glass substrate was used as the substrate 100. As the gate electrode 114, a 100-nm-thick tungsten film was formed with a sputtering apparatus.

The insulating films 102 and 103 were formed over the substrate 100 and the gate electrode 114. As the insulating film 102, a 400-nm-thick silicon nitride film was formed with a PECVD apparatus. As the insulating film 103, a 50-nm-thick silicon oxynitride film was formed with a PECVD apparatus.

The oxide semiconductor films 120a and 120b were formed over the insulating film 103. As the oxide semiconductor film 120a, a 10-nm-thick IGZO film was formed with a sputtering apparatus. As the oxide semiconductor film 120b, a 15-nm-thick IGZO film was formed over the oxide semiconductor film 120a with a sputtering apparatus. Note that the oxide semiconductor film 120a was deposited under the conditions where the substrate temperature was 170° C., an argon gas at a flow rate of 140 sccm and an oxygen gas at a flow rate of 60 sccm were introduced into a chamber, the pressure was 0.6 Pa, and an AC power of 2500 W was applied to a metal oxide sputtering target (having an atomic ratio of In:Ga:Zn=4:2:4.1). Note that the oxide semiconductor film 120b was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a metal oxide sputtering target (having an atomic ratio of In:Ga:Zn=1:1:1.2). Note that the oxide semiconductor film 120a and the oxide semiconductor film 120b were successively formed in a vacuum.

Then, first heat treatment was performed. As the first heat treatment, heat treatment was performed at 450° C. for 1 hour in a nitrogen atmosphere and then heat treatment was performed at 450° C. for 1 hour in a mixed atmosphere of nitrogen and oxygen.

Next, a resist mask was formed over the insulating film 103 and the oxide semiconductor film 120, and a desired region was etched to form the opening portion 131a reaching the gate electrode 114. The opening portion 131a was formed with a dry etching apparatus. Note that the resist mask was removed after the formation of the opening portion 131a.

Next, a conductive film was formed over the insulating film 103, the oxide semiconductor film 120, and the opening portion 131a. A resist mask was formed over the conductive film, and a desired region was etched to form the pair of electrodes 116a and 116b and the conductive film 116c. As the pair of electrodes 116a and 116b and the conductive film 116c, a 50-nm-thick tungsten film, a 400-nm-thick aluminum film, and a 100-nm-thick titanium film were successively formed in a vacuum with a sputtering apparatus. The resist mask was removed after the formation of the pair of electrodes 116a and 116b and the conductive film 116c.

Next, a phosphoric acid solution (a solution obtained by diluting an 85% phosphoric acid solution with pure water by 100 times) was applied from above the insulating film 103, the oxide semiconductor film 120, the pair of electrodes 116a and 116b, and the conductive film 116c. Thus, part of the surface of the oxide semiconductor film 120 which is not covered with the pair of electrodes 116a and 116b was removed.

Next, the insulating films 106 and 107 were formed over the insulating film 103, the oxide semiconductor film 120, the pair of electrodes 116a and 116b, and the conductive film 116c. As the insulating film 106, a 50-nm-thick silicon oxynitride film was formed with a PECVD apparatus. As the insulating film 107, a 400-nm-thick silicon oxynitride film was formed with a PECVD apparatus. Note that the insulating film 106 and the insulating film 107 were formed successively in a vacuum with a PECVD apparatus.

The insulating film 106 was deposited under the conditions where the substrate temperature was 220° C., a silane gas at a flow rate of 50 sccm and a dinitrogen monoxide gas at a flow rate of 2000 sccm were introduced into a chamber, the pressure was 20 Pa, and an RF power of 100 W was supplied between parallel-plate electrodes provided in a PECVD apparatus. The insulating film 107 was deposited under the conditions where the substrate temperature was 220° C., a silane gas at a flow rate of 160 sccm and a dinitrogen monoxide gas at a flow rate of 4000 sccm were introduced into a chamber, the pressure was 200 Pa, and an RF power of 1500 W was supplied between parallel-plate electrodes provided in a PECVD apparatus.

Then, second heat treatment was performed. The second heat treatment was performed at 350° C. in an atmosphere containing nitrogen for 1 hour.

Next, oxygen addition treatment was performed on the insulating films 106 and 107 with an ashing apparatus under the conditions where the substrate temperature was 40° C., an oxygen gas at a flow rate of 250 sccm was introduced into a chamber, the pressure was 15 Pa, and an RF power of 4500 W was supplied between parallel-plate electrodes provided in the ashing apparatus so that a bias would be applied to the substrate side.

Next, the insulating film 108 was formed over the insulating film 107. As the insulating film 108, a 100-nm-thick silicon nitride film was formed with a PECVD apparatus. The insulating film 108 was deposited under the conditions where the substrate temperature was 350° C.; a silane gas at a flow rate of 50 sccm, a nitrogen gas at a flow rate of 5000 sccm, and an ammonia gas at a flow rate of 100 sccm were introduced into a chamber; the pressure was 100 Pa; and an RF power of 1000 W was supplied between parallel-plate electrodes provided in a PECVD apparatus.

The comparative semiconductor element 2 was formed through the above-described process. Then, the following process was performed to obtain the semiconductor element 1, which is a transistor of one embodiment of the present invention.

A resist mask was formed over the insulating film 108, and a desired region was etched to form the opening portion 131b reaching the conductive film 116c. The opening portion 131b was formed with a dry etching apparatus. Note that the resist mask was removed after the formation of the opening portion 131b.

Next, a conductive film was formed over the insulating film 108 to cover the opening portion 131b, and the conductive film was processed to form the gate electrode 126. As the gate electrode 126, a 100-nm-thick ITSO film was formed with a sputtering apparatus. The ITSO film was deposited under the conditions where the substrate temperature was room temperature, an argon gas at a flow rate of 72 sccm and an oxygen gas at a flow rate of 5 sccm were introduced into a chamber, the pressure was 0.15 Pa, and a DC power of 3200 W was supplied to a metal oxide target provided in a sputtering apparatus. Note that the composition of the metal oxide target used for forming the ITSO film was In₂O₃:SnO₂:SiO₂=85:10:5 [wt %].

Then, third heat treatment was performed. The third heat treatment was performed at 250° C. for 1 hour in a nitrogen atmosphere.

The semiconductor element 1 corresponding to the transistor 154 was formed through the above-described process.

### <Evaluation of Electrical Characteristics>

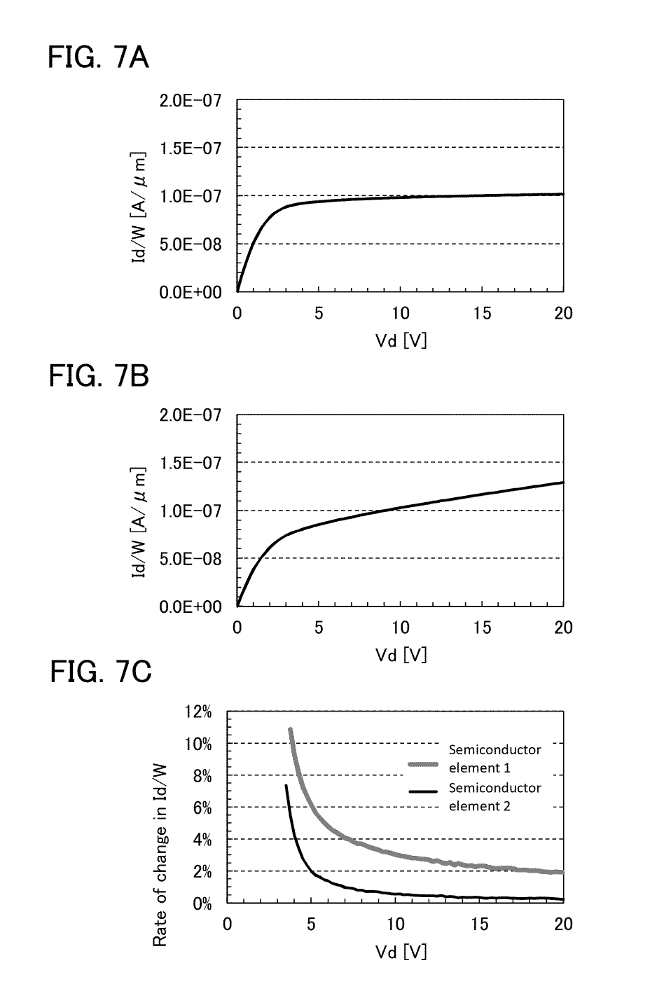

Electrical characteristics of the semiconductor element 1 and the semiconductor element 2 were evaluated. FIGS. 7A and 7B show results of electrical characteristics of the semiconductor element 1 and the semiconductor element 2, respectively.

In FIGS. 7A and 7B, voltages (V_{g}) of the gate electrodes in the semiconductor element 1 and the semiconductor element 2 were set to 3.4 V and 3.7 V, respectively, and voltage (V_{d}) between the source electrode and the drain electrode was applied from 0 V to 20 V at intervals of 0.25 V. In FIGS. 7A and 7B, the vertical axis shows I_{d}/W, drain current per unit channel width (1 μm), and the horizontal axis shows V_{d}, gate voltage.

It is shown from the evaluation results of electrical characteristics that the semiconductor element 1 exhibits more favorable saturation characteristics in V_{d}-I_{d} characteristics than the semiconductor element 2.

FIG. 7C shows the rate of change in I_{d}/W relative to a drain voltage of 1 V in a saturation region (a voltage region where a drain voltage is higher than a voltage obtained by subtracting a threshold voltage from a gate voltage, i.e., V_{d}>V_{g}−Vₜₕ).

For the semiconductor element 1, in a given range of the drain voltage, the rate of change in I_{d}/W relative to a drain voltage of 1 V is less than or equal to 2%, and favorable saturation characteristics are exhibited. In the semiconductor element 2, the rate of change in I_{d}/W relative to a drain voltage of 1 V is greater than 2%.

The semiconductor element 1 has a region where the amount of change in I_{d}/W relative to a drain voltage of 1 V is less than or equal to 1×10⁻⁹ A/μm. In the semiconductor element 2, the amount of change in I_{d}/W relative to a drain voltage of 1 V is greater than or equal to 2×10⁻⁹ A/μm.

Thus, the use of one embodiment of the present invention can provide a transistor exhibiting favorable electrical characteristics in a saturation region. The use of the transistor of one embodiment of the present invention can provide a display device with favorable display quality in which display unevenness is suppressed, or a reliable display device in which display quality hardly deteriorates.

Since a transistor having the s-channel structure and two oxide semiconductor layers like the semiconductor element 1 includes very few defects in the oxide semiconductor film, the electrical characteristics are improved. Typically, the on-state current and field-effect mobility of the transistor can be increased. Furthermore, the oxide semiconductor film containing a large amount of In can increase the field-effect mobility of the transistor, which is preferable.

The channel width of the transistor of one embodiment of the present invention can be made short. When such a transistor is used in a gate driver of a display device, a small-sized gate driver can be obtained. Furthermore, the display device can have a narrow bezel, the display device can have high resolution, or the power consumption of the display device can be reduced because the gate voltage can be reduced.

### <Structural Example of Transistor>

Up to this point, the structure of the oxide semiconductor film 120 is described in detail. Described below are the details of other components of the transistor 150.

### <Substrate>

There is no particular limitation on the property of a material and the like of the substrate 100 as long as the material has heat resistance high enough to withstand at least heat treatment to be performed later. For example, a glass substrate, a ceramic substrate, a quartz substrate, a sapphire substrate, or the like may be used as the substrate 100. Alternatively, a single crystal semiconductor substrate or a polycrystalline semiconductor substrate made of silicon, silicon carbide, or the like, a compound semiconductor substrate made of silicon germanium or the like, an SOI (silicon on insulator) substrate, or the like may be used as the substrate 100.

In the case where a glass substrate is used as the substrate 100, a glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm) Thus, a large-sized display device can be manufactured.

Alternatively, a flexible substrate may be used as the substrate 100, and the transistor 150 may be provided directly on the flexible substrate. Alternatively, a separation layer may be provided between the substrate 100 and the transistor 150. The separation layer can be used when part or the whole of a semiconductor device formed over the separation layer is separated from the substrate 100 and transferred onto another substrate. In such a case, the transistor 150 can be transferred to a substrate having low heat resistance or a flexible substrate as well.

### <Gate Electrode>

The gate electrode 114 can be formed using a metal element selected from aluminum, chromium, copper, tantalum, titanium, molybdenum, and tungsten; an alloy containing any of these metal elements as a component; an alloy containing any of these metal elements in combination; or the like. Further, one or more metal elements selected from manganese and zirconium may be used. Further, the gate electrode 114 may have a single-layer structure or a stacked-layer structure of two or more layers. For example, a single-layer structure of an aluminum film containing silicon, a two-layer structure in which an aluminum film is stacked over a titanium film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a two-layer structure in which a copper film is stacked over a titanium film, a three-layer structure in which a titanium film, an aluminum film, and a titanium film are stacked in this order, and the like can be given. Alternatively, an alloy film or a nitride film in which aluminum and one or more elements selected from titanium, tantalum, tungsten, molybdenum, chromium, neodymium, and scandium are combined may be used.

The gate electrode 114 can be formed using a light-transmitting conductive material such as indium tin oxide (ITO), indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a layered structure formed using the above light-transmitting conductive material and the above metal element.

A Cu—X alloy film (X is Mn, Ni, Cr, Fe, Co, Mo, Ta, or Ti) may be used for the gate electrode 114. The use of a Cu—X alloy film enables the manufacturing cost to be reduced because wet etching process can be used in the processing.

For each of the gate electrode 118 and the electrode 119, a light-transmitting conductive film is used. The light-transmitting conductive film is formed using an indium tin oxide, an indium zinc oxide, an indium oxide containing tungsten oxide, an indium zinc oxide containing tungsten oxide, an indium oxide containing titanium oxide, an indium tin oxide containing titanium oxide, an indium tin oxide containing silicon oxide, or the like.

### <Pair of Electrodes>

Each of the pair of electrodes 116a and 116b is formed to have a single-layer structure or a stacked-layer structure using any of metals such as aluminum, titanium, chromium, nickel, copper, yttrium, zirconium, molybdenum, silver, tantalum, and tungsten, or an alloy containing any of these metals as a main component. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be given. Note that a transparent conductive material containing indium oxide, tin oxide, or zinc oxide may be used.

### <Gate Insulating Film>

The insulating film 102 and the insulating film 103 in the gate insulating film 111 are each formed with a stacked-layer structure or a single-layer structure using, for example, silicon oxide, silicon oxynitride, silicon nitride oxide, aluminum oxide, hafnium oxide, gallium oxide, Ga—Zn-based metal oxide, silicon nitride, or the like by a plasma-enhanced chemical vapor deposition (PECVD) method, a sputtering method, or the like.

Further, the insulating film 102 and the insulating film 103 are preferably formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), hafnium oxide, or yttrium oxide. The material containing hafnium or yttrium has higher dielectric constant than silicon oxide and silicon oxynitride. Therefore, the thicknesses of the insulating film 102 and the insulating film 103 can be made large as compared with the case where silicon oxide is used; as a result, a leakage current due to a tunnel current can be low. That is, it is possible to provide a transistor with a low off-state current. Moreover, hafnium oxide with a crystalline structure has higher dielectric constant than hafnium oxide with an amorphous structure. Therefore, it is preferable to use hafnium oxide with a crystalline structure in order to provide a transistor with a low off-state current. Examples of the crystalline structure include a monoclinic crystal structure and a cubic crystal structure. Note that one embodiment of the present invention is not limited to the above examples.

In this embodiment, a silicon nitride film is formed as the insulating film 102, and a silicon oxide film is formed as the insulating film 103. A silicon nitride film has a higher dielectric constant than a silicon oxide film and needs a larger thickness for an equivalent capacitance. Therefore, when the gate insulating film 111 of the transistor 150 includes a silicon nitride film, the physical thickness of the gate insulating film 111 can be increased. This makes it possible to reduce a decrease in the withstand voltage of the transistor 150 and furthermore increase the withstand voltage, thereby preventing electrostatic breakdown of the transistor 150.

The thickness of the gate insulating film 111 is preferably greater than or equal to 5 nm and less than or equal to 400 nm, more preferably greater than or equal to 10 nm and less than or equal to 300 nm, still more preferably greater than or equal to 50 nm and less than or equal to 250 nm.

### <Protective Insulating Film>

The gate insulating film 112 includes the insulating film 106 in contact with the oxide semiconductor film 120, the insulating film 107 in contact with the insulating film 106, and the insulating film 108 in contact with the insulating film 107. The gate insulating film 112 preferably includes at least an oxide insulating film containing a higher proportion of oxygen than that of oxygen in the stoichiometric composition. Here, as the insulating film 106, an oxide insulating film through which oxygen passes is formed. As the insulating film 107, an oxide insulating film containing a higher proportion of oxygen than that of oxygen in the stoichiometric composition is formed. As the insulating film 108, a nitride insulating film that blocks hydrogen and oxygen is formed. Although the gate insulating film 112 has a three-layer structure here, the gate insulating film 112 can have a single-layer structure, a two-layer structure, or a stacked-layer structure including four or more layers as appropriate. Note that in these cases, at least an oxide insulating film containing oxygen at higher proportion than the stoichiometric composition is preferably included.

The oxide insulating film 106 is an oxide insulating film through which oxygen passes. Thus, oxygen released from the insulating film 107 provided over the insulating film 106 can be moved to the oxide semiconductor film 120 through the insulating film 106. Moreover, the insulating film 106 also serves as a film which relieves damage to the oxide semiconductor film 120 at the time of forming the insulating film 107 later.

The insulating film 106 has a thickness greater than or equal to 5 nm and less than or equal to 150 nm, preferably greater than or equal to 5 nm and less than or equal to 50 nm. As the insulating film 106, for example, silicon oxide, silicon oxynitride, or the like can be used.

It is preferable that the amount of defects in the insulating film 106 be small. Typically, the spin density of a signal that appears at g=2.001 due to a dangling bond of silicon is preferably lower than or equal to 3×10¹⁷ spins/cm³ by ESR measurement. This is because if the density of defects in the insulating film 106 is high, oxygen is bonded to the defects and the amount of oxygen that passes through the insulating film 106 is decreased.

Further, it is preferable that the amount of defects at the interface between the insulating film 106 and the oxide semiconductor film 120 be small. Typically, the spin density of a signal that appears at g=1.93 due to an oxygen vacancy in the oxide semiconductor film 120 is preferably lower than or equal to 1×10¹⁷ spins/cm³, more preferably lower than or equal to the lower limit of detection by ESR measurement.

Note that all oxygen entering the insulating film 106 from the outside moves to the outside of the insulating film 106. Alternatively, some oxygen having entered the insulating film 106 from the outside remains in the insulating film 106 in some cases. Furthermore, movement of oxygen occurs in the insulating film 106 in some cases in such a manner that oxygen enters the insulating film 106 from the outside and oxygen contained in the insulating film 106 moves to the outside of the insulating film 106. When an oxide insulating film which can transmit oxygen is formed as the insulating film 106, oxygen released from the insulating film 107 provided over the insulating film 106 can be moved to the oxide semiconductor film 120 through the insulating film 106.

The insulating film 106 can be formed using an oxide insulating film having a low density of states due to nitrogen oxide. Note that the density of states due to nitrogen oxide can be formed between the energy of the valence band maximum (Eᵥ_{_}ₒₛ) and the energy of the conduction band minimum (E_{c}_{_}ₒₛ) of the oxide semiconductor film. A silicon oxynitride film that releases less nitrogen oxide, an aluminum oxynitride film that releases less nitrogen oxide, and the like can be used as the above oxide insulating film.

Note that a silicon oxynitride film that releases a small amount of nitrogen oxide is a film of which the amount of released ammonia is larger than the amount of released nitrogen oxide in thermal desorption spectroscopy analysis; the amount of released ammonia is typically greater than or equal to 1×10¹⁸/cm³ and less than or equal to 5×10¹⁹/cm³. Note that the amount of released ammonia is the amount of ammonia released by heat treatment with which the surface temperature of the film becomes a temperature higher than or equal to 50° C. and lower than or equal to 650° C., or preferably higher than or equal to 50° C. and lower than or equal to 550° C.

Nitrogen oxide (NOₓ; x is greater than or equal to 0 and less than or equal to 2, preferably greater than or equal to 1 and less than or equal to 2), typically NO₂ or NO, forms levels in the insulating film 106, for example. The level is positioned in the energy gap of the oxide semiconductor film 120. Therefore, when nitrogen oxide is diffused to the vicinity of the interface between the insulating film 106 and the oxide semiconductor film 120, an electron is in some cases trapped by the level on the insulating film 106 side. As a result, the trapped electron remains in the vicinity of the interface between the insulating film 106 and the oxide semiconductor film 120; thus, the threshold voltage of the transistor is shifted in the positive direction.

Nitrogen oxide reacts with ammonia and oxygen in heat treatment. Since nitrogen oxide contained in the insulating film 106 reacts with ammonia contained in the insulating film 107 in heat treatment, nitrogen oxide contained in the insulating film 106 is reduced. Therefore, an electron is hardly trapped at the vicinity of the interface between the insulating film 106 and the oxide semiconductor film 120.

By using such an oxide insulating film, the insulating film 106 can reduce the shift in the threshold voltage of the transistor, which leads to a smaller change in the electrical characteristics of the transistor.

Note that in an ESR spectrum at 100 K or lower of the insulating film 106, by heat treatment of a manufacturing process of the transistor, typically heat treatment at a temperature higher than or equal to 300° C. and lower than the strain point of the substrate, a first signal that appears at a g-factor of greater than or equal to 2.037 and less than or equal to 2.039, a second signal that appears at a g-factor of greater than or equal to 2.001 and less than or equal to 2.003, and a third signal that appears at a g-factor of greater than or equal to 1.964 and less than or equal to 1.966 are observed. The split width of the first and second signals and the split width of the second and third signals that are obtained by ESR measurement using an X-band are each approximately 5 mT. The sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is lower than 1×10¹⁸ spins/cm³, typically higher than or equal to 1×10¹⁷ spins/cm³ and lower than 1×10¹⁸ spins/cm³.

In the ESR spectrum at 100 K or lower, the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 correspond to signals attributed to nitrogen oxide (NOₓ; x is greater than or equal to 0 and less than or equal to 2, preferably greater than or equal to 1 and less than or equal to 2). Typical examples of nitrogen oxide include nitrogen monoxide and nitrogen dioxide. In other words, the lower the total spin density of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is, the smaller amount of nitrogen oxide the oxide insulating film contains.

The concentration of nitrogen of the above oxide insulating film measured by SIMS is lower than or equal to 6×10²⁰ atoms/cm³.

The above oxide insulating film is formed by a PECVD method at a substrate temperature higher than or equal to 220° C., higher than or equal to 280° C., or higher than or equal to 350° C. using silane and dinitrogen monoxide, whereby a dense and hard film can be formed.

The insulating film 107 is formed in contact with the insulating film 106. The insulating film 107 is formed using an oxide insulating film that contains oxygen at a higher proportion than oxygen in the stoichiometric composition. Part of oxygen is released by heating from the oxide insulating film that contains oxygen at a higher proportion than oxygen in the stoichiometric composition. The oxide insulating film that contains oxygen at a higher proportion than oxygen in the stoichiometric composition is an oxide insulating film of which the amount of released oxygen converted into oxygen atoms is greater than or equal to 1.0×10¹⁸ atoms/cm³, preferably greater than or equal to 3.0×10²⁰ atoms/cm³ in TDS analysis. Note that the temperature of the film surface in the TDS analysis is preferably higher than or equal to 100° C. and lower than or equal to 700° C., or higher than or equal to 100° C. and lower than or equal to 500° C.

In the case where the insulating film 107 includes the oxide insulating film containing oxygen at higher proportion than the stoichiometric composition, part of oxygen contained in the insulating film 107 can be transferred to the oxide semiconductor film 120 through the insulating film 106 to reduce oxygen vacancies in the oxide semiconductor film 120.

In a transistor formed using an oxide semiconductor film including oxygen vacancies, the threshold voltage is likely to shift in the negative direction, and such a transistor tends to have negative threshold voltage (normally-on characteristics). This is because charges are generated because of oxygen vacancies in the oxide semiconductor film and the resistance of the oxide semiconductor film is thus reduced. The transistor having normally-on characteristics causes various problems in that malfunction is likely to be caused when in operation and that power consumption is increased when not in operation. Furthermore, there is a problem in that the amount of change in electrical characteristics, typified by threshold voltage, of the transistor is increased with passage of time or by a stress test.

However, in the transistor 150 described in this embodiment, an oxide insulating film containing oxygen at higher proportion than the stoichiometric composition is included in the insulating film 107 provided over the oxide semiconductor film 120; thus, oxygen contained in the insulating film 107 can be transferred to the oxide semiconductor film 120 through the insulating film 106 to reduce oxygen vacancies in the oxide semiconductor film 120. In addition, because the gate insulating film 112 is not exposed to an etching atmosphere, the gate insulating film 112 has few defects. As a result, the transistor has positive threshold voltage (normally-off characteristics). Further, the amount of change in electrical characteristics, typified by threshold voltage with respect to operation time, of the transistors with passage of time or due to a stress test can be reduced. Furthermore, a change in the threshold voltage can be reduced even when a stress test is repeatedly performed.

Oxygen can be introduced by a method in which acceleration energy is applied to a gas under reduced pressure, specifically, an ion implantation method, an ion doping method, a plasma immersion ion implantation method, plasma treatment, or the like. When oxygen is introduced, a substrate is preferably heated because a larger amount of oxygen can be introduced. The substrate temperature at the time when oxygen is introduced is preferably higher than room temperature and lower than 350° C., for example. For the above plasma treatment, an apparatus with which an oxygen gas is made to be plasma by high-frequency power (also referred to as a plasma etching apparatus or a plasma ashing apparatus) is preferably used.

The insulating film 107 preferably has a thickness greater than or equal to 30 nm and less than or equal to 500 nm, more preferably greater than or equal to 50 nm and less than or equal to 400 nm. As the insulating film 107, for example, silicon oxide, silicon oxynitride, or the like can be used.

It is preferable that the amount of defects in the insulating film 107 be small. Typically, the spin density corresponding to a signal that appears at g=2.001 due to a dangling bond of silicon is preferably lower than 6×10¹⁷ spins/cm³, more preferably lower than 3×10¹⁷ spins/cm³, still more preferably lower than 1.5×10¹⁷ spins/cm³ by ESR measurement. Note that the insulating film 107 is provided more apart from the oxide semiconductor film 120 than the insulating film 106 is; thus, the insulating film 107 may have higher defect density than the insulating film 106.

The amount of released oxygen can be found by measuring an insulating film by thermal desorption spectroscopy (TDS). For example, the amount of released oxygen molecules from the insulating films 106 and 107 is larger than or equal to 8.0×10¹⁴/cm², preferably larger than or equal to 1.0×10¹⁵/cm², still more preferably larger than or equal to 1.5×10¹⁵/cm² by TDS. Note that the surface temperature of the films in TDS is higher than or equal to 100° C. and lower than or equal to 700° C., preferably higher than or equal to 100° C. and lower than or equal to 500° C.

In one embodiment of the present invention, a protective film having a function of inhibiting release of oxygen (also simply referred to as a protective film) is formed over the insulating film 107 and oxygen is introduced into the insulating films 106 and 107 through the protective film, so that the oxygen excess region is formed in the insulating films 106 and 107.

For the protective film having a function of inhibiting release of oxygen, for example, indium (In) and a material including one of zinc (Zn), tin (Sn), tungsten (W), titanium (Ti), and silicon (Si) can be used. In particular, a conductive film containing indium or a semiconductor film containing indium is preferably used as the protective film. The protective film may be removed after oxygen introduction. For the conductive film containing indium, a light-transmitting conductive material such as indium oxide containing tungsten oxide, indium zinc oxide containing tungsten oxide, indium oxide containing titanium oxide, indium tin oxide containing titanium oxide, indium tin oxide (ITO), indium zinc oxide, or indium tin oxide containing silicon oxide (abbreviation: ITSO) can be used. Among the above-described materials, ITSO is particularly preferably used as the film having a function of inhibiting release of oxygen because it can be deposited over an insulating film having roughness or the like with favorable coverage.

The insulating film 108 has an effect of blocking at least hydrogen and oxygen. Preferably, the insulating film 108 has an effect of blocking oxygen, hydrogen, water, an alkali metal, an alkaline earth metal, or the like. It is possible to prevent outward diffusion of oxygen from the oxide semiconductor film 120 and entry of hydrogen, water, or the like into the oxide semiconductor film 120 from the outside by including the insulating film 108 in the gate insulating film 112.

The insulating film 108 has a thickness greater than or equal to 50 nm and less than or equal to 300 nm, preferably greater than or equal to 100 nm and less than or equal to 200 nm. As the insulating film 108, a silicon nitride film, a silicon nitride oxide film, an aluminum nitride film, an aluminum nitride oxide film, or the like can be formed.

Note that instead of the insulating film 108, an oxide insulating film having a blocking effect against oxygen, hydrogen, water, and the like may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given.

Note that the above-described various films such as the electrodes, the insulating films, and the oxide semiconductor film can be formed by a sputtering method, a chemical vapor deposition (CVD) method, a vacuum evaporation method, a pulsed laser deposition (PLD) method, or the like. Alternatively, the above-described various films such as the electrodes, the insulating films, and the oxide semiconductor film can be formed by a plasma enhanced chemical vapor deposition (PECVD) method, a thermal CVD method, or an atomic layer deposition (ALD) method. As an example of a thermal CVD method, a metal organic chemical vapor deposition (MOCVD) method can be given. Further alternatively, the above-described various films such as the electrodes, the insulating films, and the oxide semiconductor film can be formed by a coating method or a printing method.

A thermal CVD method has an advantage that no defect due to plasma damage is generated since it does not utilize plasma for forming a film.

Deposition by a thermal CVD method may be performed in such a manner that a source gas and an oxidizer are supplied at a time to the chamber, in which the pressure is set to an atmospheric pressure or a reduced pressure, and react with each other in the vicinity of the substrate or over the substrate.

Deposition by an ALD method may be performed in such a manner that source gases for reaction are sequentially introduced into the chamber, in which the pressure is set to an atmospheric pressure or a reduced pressure, and then the sequence of the gas introduction is repeated. For example, two or more kinds of source gases are sequentially supplied to the chamber by switching respective switching valves (also referred to as high-speed valves). For example, a first source gas is introduced, an inert gas (e.g., argon or nitrogen) or the like is introduced at the same time as or after the introduction of the first gas so that the source gases are not mixed, and then a second source gas is introduced. Note that in the case where the first source gas and the inert gas are introduced at a time, the inert gas serves as a carrier gas, and the inert gas may also be introduced at the same time as the introduction of the second source gas. Alternatively, the first source gas may be exhausted by vacuum evacuation instead of the introduction of the inert gas, and then the second source gas may be introduced. The first source gas is adsorbed on the surface of the substrate to form a first layer; then the second source gas is introduced to react with the first layer; as a result, a second layer is stacked over the first layer, so that a thin film is formed. The sequence of the gas introduction is repeated plural times until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and thus is suitable for manufacturing a minute FET.

The above-described variety of films such as the conductive film, the insulating film, the oxide semiconductor film, and the metal oxide film in this embodiment can be formed by an ALD method or a thermal CVD method such as an MOCVD method. For example, in the case where an In—Ga—Zn—O film is formed, trimethylindium, trimethylgallium, and dimethylzinc are used. Note that the chemical formula of trimethylindium is In(CH₃)₃. The chemical formula of trimethylgallium is Ga (CH₃)₃. The chemical formula of dimethylzinc is Zn(CH₃)₂. Without limitation to the above combination, triethylgallium (chemical formula: Ga(C₂H₅)₃) can be used instead of trimethylgallium, and diethylzinc (chemical formula: Zn(C₂H₅)₂) can be used instead of dimethylzinc.

For example, in the case where a hafnium oxide film is formed with a deposition apparatus employing ALD, two kinds of gases, i.e., ozone (O₃) as an oxidizer and a source gas which is obtained by vaporizing liquid containing a solvent and a hafnium precursor compound (hafnium alkoxide or hafnium amide such as tetrakis(dimethylamide)hafnium (TDMAH)) are used. The chemical formula of tetrakis(dimethylamide)hafnium is Hf[N(CH₃)₂]₄. Examples of another material liquid include tetrakis(ethylmethylamide)hafnium.

For example, in the case where an aluminum oxide film is formed by a deposition apparatus using an ALD method, two kinds of gases, e.g., H₂O as an oxidizer and a source gas which is obtained by vaporizing liquid containing a solvent and an aluminum precursor compound (e.g., trimethylaluminum (TMA)) are used. The chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

For example, in the case where a silicon oxide film is formed by a deposition apparatus using an ALD method, hexachlorodisilane is adsorbed on a surface where a film is to be formed, chlorine contained in the adsorbate is removed, and radicals of an oxidizing gas (e.g., O₂ or dinitrogen monoxide) are supplied to react with the adsorbate.

For example, in the case where a tungsten film is formed using a deposition apparatus employing ALD, a WF₆ gas and a B₂H₆ gas are sequentially introduced a plurality of times to form an initial tungsten film, and then a WF₆ gas and an H₂ gas are alternately introduced at a time, so that a tungsten film is formed. Note that an SiH₄ gas may be used instead of a B₂H₆ gas.

For example, in the case where an oxide semiconductor film, e.g., an In—Ga—Zn—O film is formed with a deposition apparatus using an ALD method, an In(CH₃)₃ gas and an O₃ gas are sequentially introduced plural times to form an In—O layer, a Ga(CH₃)₃ gas and an O₃ gas are sequentially introduced plural times to form a GaO layer, and then a Zn(CH₃)₂ gas and an O₃ gas are sequentially introduced plural times to form a ZnO layer. Note that the order of these layers is not limited to this example. A mixed compound layer such as an In—Ga—O layer, an In—Zn—O layer, or a Ga—Zn—O layer may be formed by using these gases. Note that although an H₂O gas which is obtained by bubbling with an inert gas such as Ar may be used instead of an O₃ gas, it is preferable to use an O₃ gas, which does not contain H. Further, instead of an In(CH₃)₃ gas, an In(C₂H₅)₃ gas may be used. Instead of a Ga(CH₃)₃ gas, a Ga(C₂H₅)₃ gas may be used. Furthermore, a Zn(CH₃)₂ gas may be used.

### <Method 1 for Manufacturing Transistor>

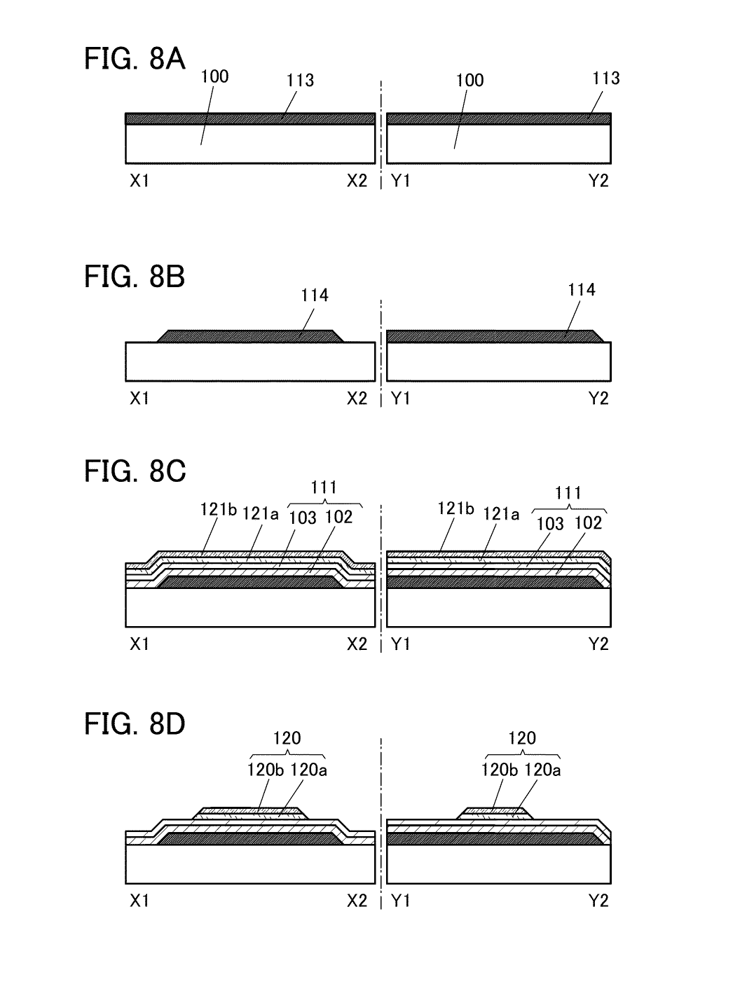

Next, a method for manufacturing the transistor 150 shown in FIGS. 1A to 1C will be described with reference to FIGS. 8A to 8D, FIGS. 9A to 9D, FIGS. 10A to 10C, and FIGS. 11A and 11C. In each of FIGS. 8A to 8D, FIGS. 9A to 9D, FIGS. 10A to 10C, and FIGS. 11A and 11C, a cross-sectional view in the channel length direction along line X1-X2 and a cross-sectional view in the channel width direction along line Y1-Y2 are used for describing a method for manufacturing the transistor 150.

### <Formation Step of Gate Electrode>

As illustrated in FIG. 8A, a conductive film 113 to be the gate electrode 114 is formed over the substrate 100. In this case, a glass substrate is used as the substrate 100. The conductive film 113 can be formed by a sputtering method, a CVD method, an evaporation method, or the like. In this case, as the conductive film 113, a 100-nm-thick tungsten film is formed by a sputtering method.

Then, a mask is formed over the conductive film 113 by a photolithography process using a first photomask. Next, the conductive film 113 is partly etched using the mask to form the gate electrode 114. After that, the mask is removed (see FIG. 8B).

The conductive film 113 can be partly etched by one or both of wet etching and dry etching. Here, the conductive film 113 is dry-etched by a dry etching method to form the gate electrode 114.

Note that the gate electrode 114 may be formed by an electrolytic plating method, a printing method, an ink-jet method, or the like instead of the above formation method.

### <Formation Step of Gate Insulating Film>

Next, as illustrated in FIG. 8C, the insulating film 102 and the insulating film 103 to be the gate insulating film 111 is formed over the substrate 100 and the gate electrode 114.

The insulating films 102 and 103 can be formed by a sputtering method, a CVD method, an evaporation method, or the like. In the case where a silicon oxide film, a silicon oxynitride film, or a silicon nitride oxide film is formed as the insulating films 102 and 103, a deposition gas containing silicon and an oxidizing gas are preferred to be used as a source gas. Typical examples of the deposition gas containing silicon include silane, disilane, trisilane, and silane fluoride. As the oxidizing gas, oxygen, ozone, dinitrogen monoxide, nitrogen dioxide, and the like can be given as examples. Moreover, in the case of forming a gallium oxide film as the insulating films 102 and 103, a metal organic chemical vapor deposition (MOCVD) method can be employed. Here, a 400-nm-thick silicon nitride film as the insulating film 102 and a 50-nm-thick silicon oxynitride film as the insulating film 103 are formed by a PECVD method.

The insulating film 102 has a stacked-layer structure of silicon nitride films. Specifically, the insulating film 102 can have a three-layer stacked-layer structure of a first silicon nitride film, a second silicon nitride film, and a third silicon nitride film. An example of the three-layer stacked-layer structure can be formed as follows.

For example, the first silicon nitride film can be formed to have a thickness of 50 nm under the conditions where silane at a flow rate of 200 sccm, nitrogen at a flow rate of 2000 sccm, and an ammonia gas at a flow rate of 100 sccm are supplied as a source gas to a reaction chamber of a PECVD apparatus, the pressure in the reaction chamber is controlled to 100 Pa, and a power of 2000 W is supplied using a 27.12 MHz high-frequency power source.

The second silicon nitride film can be formed to have a thickness of 300 nm under the condition where silane at a flow rate of 200 sccm, nitrogen at a flow rate of 2000 sccm, and an ammonia gas at a flow rate of 2000 sccm are supplied as a source gas to the reaction chamber of the PECVD apparatus; the pressure in the reaction chamber is controlled to 100 Pa, and a power of 2000 W is supplied using a 27.12 MHz high-frequency power source.

The third silicon nitride film can be formed to have a thickness of 50 nm under the condition where silane at a flow rate of 200 sccm, nitrogen at a flow rate of 2000 sccm, and an ammonia gas at a flow rate of 100 sccm are supplied as a source gas to the reaction chamber of the PECVD apparatus; the pressure in the reaction chamber is controlled to 100 Pa, and a power of 2000 W is supplied using a 27.12 MHz high-frequency power source.

Note that the first silicon nitride film, the second silicon nitride film, and the third silicon nitride film can be each formed at a substrate temperature of 350° C.

When the insulating film 102 has the three-layer stacked-layer structure of silicon nitride films, for example, in the case where a conductive film containing copper (Cu) is used as the gate electrode 114, the following effect can be obtained.

The first silicon nitride film can inhibit diffusion of a copper (Cu) element from the gate electrode 114. The second silicon nitride film has a function of releasing hydrogen and can improve withstand voltage of the insulating film functioning as a gate insulating film. The third silicon nitride film releases a small amount of hydrogen and can inhibit diffusion of hydrogen released from the second silicon nitride film.

The insulating film 103 is preferably an insulating film containing oxygen to improve characteristics of an interface with the oxide semiconductor film 120a formed later.

### <Formation Step of Oxide Semiconductor Film>

Oxide semiconductor films 121a and 121b to be the oxide semiconductor films 120a and 120b are formed over the insulating film 103 (see FIG. 8C). The oxide semiconductor films 121a and 121b can be formed by a sputtering method, a coating method, a pulsed laser deposition method, a laser ablation method, or the like.

As a power supply device for generating plasma in the case of forming the oxide semiconductor films 121a and 121b by a sputtering method, an RF power supply device, an AC power supply device, a DC power supply device, or the like can be used as appropriate. As a sputtering gas, a rare gas (typically argon), an oxygen gas, or a mixed gas of a rare gas and oxygen is used as appropriate. In the case of using the mixed gas of a rare gas and oxygen, the proportion of oxygen is preferably higher than that of a rare gas. Further, a target may be appropriately selected in accordance with the composition of the oxide semiconductor films 121a and 121b to be formed.

Specifically, to make the continuous junction, the oxide semiconductor films 121a and 121b are preferably stacked in succession without exposure to the air using a deposition apparatus (sputtering apparatus) of a multi chamber type with a load lock chamber. Each chamber in the sputtering apparatus is preferably evacuated to be a high vacuum state (to a degree of about 5×10⁻⁷ Pa to 1×10⁻⁴ Pa) with an adsorption vacuum pump such as a cryopump in order to remove water or the like, which serves as an impurity against the oxide semiconductor film, as much as possible. Alternatively, a turbo molecular pump and a cold trap are preferably combined so as to prevent a backflow of a gas, especially a gas containing carbon or hydrogen from an exhaust system to the inside of the chamber.

To make the oxide semiconductor films 121a and 121b intrinsic or substantially intrinsic, besides the high vacuum evacuation of the chamber, a highly purification of a sputtering gas is also needed. As an oxygen gas or an argon gas used for a sputtering gas, a gas which is highly purified to have a dew point of −60° C. or lower, preferably −100° C. or lower is used, whereby entry of moisture or the like into the oxide semiconductor films 121a and 121b can be prevented as much as possible.

Here, a 10-nm-thick In—Ga—Zn oxide film is formed as the oxide semiconductor film 121a by a sputtering method using an In—Ga—Zn oxide target (In:Ga:Zn=4:2:4.1). In addition, a 15-nm-thick In—Ga—Zn oxide film is formed as the oxide semiconductor film 121b by a sputtering method using an In—Ga—Zn oxide target (In:Ga:Zn=1:1:1.2).

Then, after a mask is formed over the oxide semiconductor film 121b by a photolithography process using a second photomask, the oxide semiconductor films 121a and 121b are partly etched using the mask. Thus, the oxide semiconductor film 120 including the oxide semiconductor film 120a and 120b subjected to element isolation is formed. After that, the mask is removed (see FIG. 8D).

The oxide semiconductor films 121a and 121b can be partly etched by one or both of wet etching and dry etching. Here, the oxide semiconductor films 121a and 121b are wet-etched to form the oxide semiconductor film 120 including the oxide semiconductor films 120a and 120b.

After that, heat treatment may be performed at higher than or equal to 150° C. and lower than the strain point of the substrate, preferably higher than or equal to 200° C. and lower than or equal to 450° C., more preferably higher than or equal to 300° C. and lower than or equal to 450° C. This heat treatment can reduce hydrogen, water, and the like contained in the oxide semiconductor films 120a and 120b, which results in a reduction in impurities contained in the oxide semiconductor films 120a and 120b. Note that the heat treatment for reducing hydrogen, water, or the like may be performed on the oxide semiconductor films 121a and 121b before the island-shaped oxide semiconductor films 120a and 120b are formed by processing.

A gas baking furnace, an electric furnace, a rapid thermal annealing (RTA) apparatus, or the like can be used for the heat treatment to which the oxide semiconductor film 120 is subjected. With the use of an RTA apparatus, the heat treatment can be performed at a temperature higher than or equal to the strain point of the substrate if the heating time is short. Therefore, the heat treatment time can be shortened.

The heat treatment to which the oxide semiconductor film 120 is subjected may be performed in an atmosphere of nitrogen gas, oxygen gas, clean dry air (also referred to as CDA, which is an air with a water content of 20 ppm or less, preferably 1 ppm or less, further preferably 10 ppb or less), or rare gas (e.g., argon or helium). The atmosphere of nitrogen gas, oxygen gas, CDA, or rare gas preferably does not contain hydrogen, water, and the like.

The purity of the nitrogen gas, the oxygen gas, or CDA is preferably increased, for example. Specifically, the purity of the nitrogen gas, the oxygen gas, or CDA is preferably 6N (99.9999%) or 7N (99.99999%). When a gas which is highly purified to have a dew point of −60° C. or lower, preferably −100° C. or lower, is used as the nitrogen gas, the oxygen gas, or CDA, entry of moisture and the like into the oxide semiconductor film 120 can be minimized.

Further, the oxide semiconductor film 120 may be subjected to another heat treatment in an oxygen atmosphere or a CDA atmosphere after the heat treatment in a nitrogen atmosphere or a rare gas atmosphere. As a result, hydrogen, water, and the like can be released from the oxide semiconductor film 120 and oxygen can be supplied to the oxide semiconductor film 120 at the same time. Consequently, the amount of oxygen vacancies in the oxide semiconductor film 120 can be reduced.

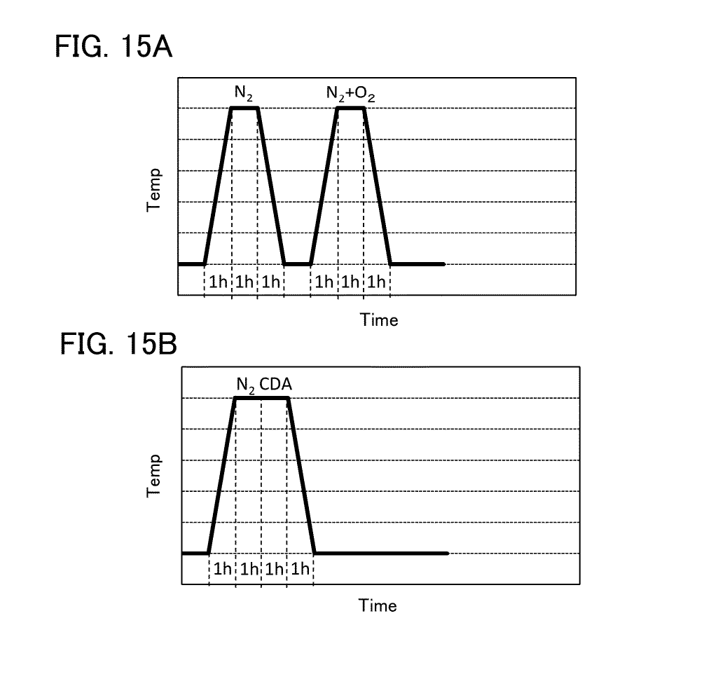

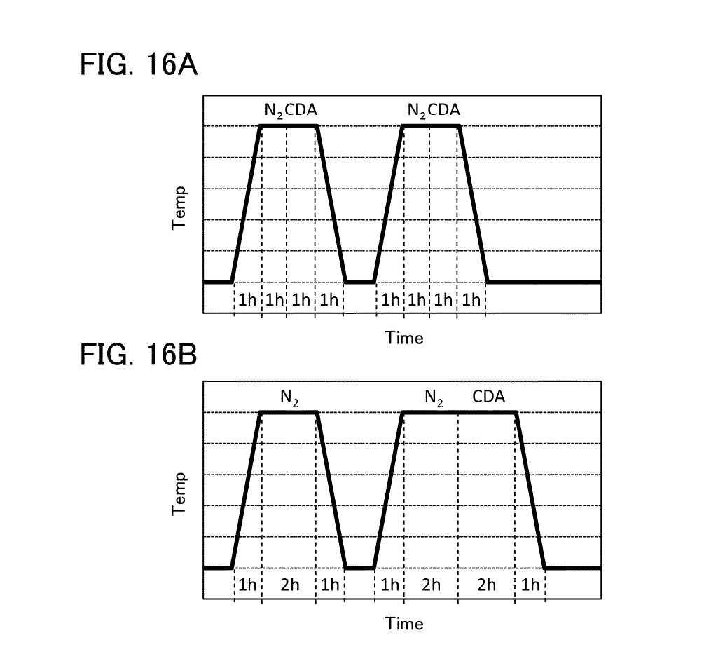

Here, thermal profiles of heat treatment performed on the oxide semiconductor film 120 in a gas baking furnace will be described with reference to FIGS. 15A and 15B and FIGS. 16A and 16B. FIGS. 15A and 15B and FIGS. 16A and 16B each show a thermal profile of heat treatment in a gas baking furnace.

Note that each of FIGS. 15A and 15B and FIGS. 16A and 16B is a thermal profile showing the temperature raised to a predetermined temperature (here, 450° C.; hereinafter referred to as a first temperature) and dropped to a predetermined temperature (here, higher than or equal to room temperature and lower than or equal to 150° C.; hereinafter referred to as a second temperature).

When the oxide semiconductor film 120 is subjected to heat treatment, the treatment can be divided into two steps using two kinds of gases as shown in FIG. 15A. For example, a nitrogen gas is introduced into a gas baking furnace in the first step. Then, the temperature is raised to the first temperature over one hour, and the heat treatment is performed at the first temperature for another one hour. After that, the temperature is dropped to the second temperature over the next one hour. In the second step, the nitrogen gas is replaced by a mixed gas of nitrogen and oxygen. Then, the time taken to raise the temperature to the first temperature is one hour, and the heat treatment is performed at the first temperature for another one hour. After that, the temperature is dropped to the second temperature over the next one hour.

Alternatively, when the oxide semiconductor film 120 is subjected to heat treatment, the treatment can be performed in one step using two kinds of gases as shown in FIG. 15B. For example, first, a nitrogen gas is introduced into a gas baking furnace. Then, the temperature is raised to the first temperature over one hour, and the heat treatment is performed at the first temperature for another one hour. After that, the gas is changed from the nitrogen gas to CDA. After the gas change, the heat treatment is performed for another one hour, and the temperature is dropped to the second temperature over the next one hour.

The thermal profile of the heat treatment in the gas baking furnace shown in FIG. 15B requires less processing time than the thermal profile of the heat treatment in the gas baking furnace shown in FIG. 15A; accordingly, semiconductor devices can be provided with higher productivity.

Alternatively, when the oxide semiconductor film 120 is subjected to heat treatment, the treatment can be performed in two steps using two kinds of gases as shown in FIG. 16A. For example, first, a nitrogen gas is introduced into a gas baking furnace in the first step. Then, the temperature is raised to the first temperature over one hour, and the heat treatment is performed at the first temperature for another one hour. After that, the gas is changed from the nitrogen gas to CDA. After the gas change, the heat treatment is performed for another one hour, and the temperature is dropped to the second temperature over the next one hour. In the second step, CDA is replaced by a nitrogen gas. Then, the temperature is raised to the first temperature over one hour, and the heat treatment is performed at the first temperature for another one hour. After that, the gas is changed from the nitrogen gas to CDA. After the gas change, the heat treatment is performed for another one hour, and the temperature is dropped to the second temperature over the next one hour.

Alternatively, when the oxide semiconductor film 120 is subjected to heat treatment, the treatment can be performed in two steps using two kinds of gases as shown in FIG. 16B. For example, first, a nitrogen gas is introduced into a gas baking furnace in the first step. Then, the temperature is raised to the first temperature over one hour, and the heat treatment is performed at the first temperature for two hours. After that, the temperature is dropped to the second temperature over the next one hour. In the second step, the temperature is raised to the first temperature over one hour, and the heat treatment is performed at the first temperature for two hours. After that, the gas is changed from the nitrogen gas to CDA. After the gas change, the heat treatment is performed for another two hours, and then the temperature is dropped to the second temperature over the next one hour.

As far as the thermal profiles of heat treatment performed on the oxide semiconductor film 120 in a gas baking furnace are concerned, it is preferable that the oxide semiconductor film 120 be first heated in a nitrogen gas as shown in FIGS. 15A and 15B and FIGS. 16A and 16B.

When the oxide semiconductor film 120 is first heated in a nitrogen gas, oxygen, which is one of the principal components of the oxide semiconductor film 120, and hydrogen in the oxide semiconductor film 120 react with each other to form an OH group. Then, the OH group is released from the surface of the oxide semiconductor film 120 as H₂O. In other words, owing to the first nitrogen gas, hydrogen in the oxide semiconductor film 120 can be captured.

However, heating the oxide semiconductor film 120 with only a nitrogen gas makes oxygen be released from the oxide semiconductor film 120 as H₂O, whereby oxygen vacancies are formed in the oxide semiconductor film 120.

Thus, the nitrogen gas is replaced by either a mixed gas of nitrogen and oxygen or CDA as shown in FIGS. 15A and 15B and FIGS. 16A and 16B, in which case oxygen contained in the gas can fill the oxygen vacancies in the oxide semiconductor film 120.

Note that although the heat treatment is performed for one or two consecutive hours after the temperature becomes stable at the predetermined temperature in FIGS. 15A and 15B and FIGS. 16A and 16B, one embodiment of the present invention is not limited thereto. For example, the processing time of heat treatment in the nitrogen gas in the first step in FIG. 16B may be one to 10 hours inclusive. As the processing time of the first step in FIG. 16B is increased, a larger amount of hydrogen can be released from the oxide semiconductor film 120, which is preferable.

In addition, time for baking with the use of either a mixed gas of nitrogen and oxygen or CDA may be set longer (e.g., one to 10 hours inclusive) as necessary. Increasing the heating time in an oxygen-containing atmosphere makes it possible to favorably fill the oxygen vacancies formed in the oxide semiconductor film 120.

### <Formation Step of Source Electrode and Drain Electrode>

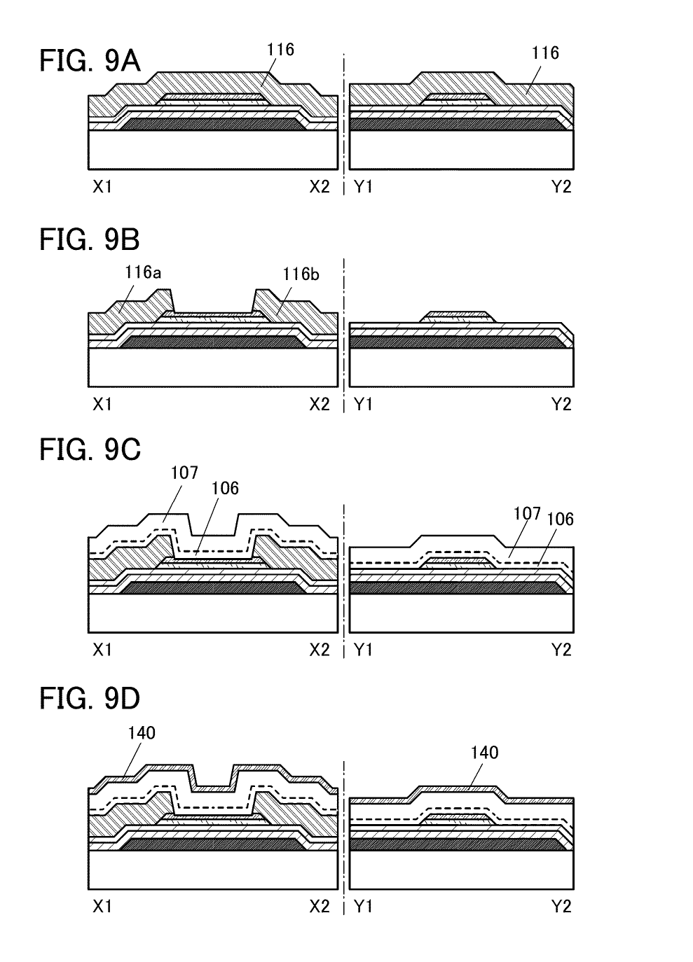

Next, as illustrated in FIG. 9A, a conductive film 116 to be the pair of electrodes 116a and 116b functioning as a source electrode and a drain electrode is formed.

The conductive film 116 is formed by a sputtering method, a CVD method, an evaporation method, or the like. Here, a 50-nm-thick tungsten (W) film, a 400-nm-thick aluminum (Al) film, and a 100-nm-thick Ti film are sequentially stacked by a sputtering method to form the conductive film 116. Although the conductive film 116 has a three-layer structure in this embodiment, one embodiment of the present invention is not limited thereto. For example, the conductive film 116 may have a two-layer structure of a 50-nm-thick W film and a 400-nm-thick Al film.

Then, a mask is formed over the conductive film 116 by a photolithography process using a third photomask. Next, the conductive film 116 is partly etched using the mask to form the pair of electrodes 116a and 116b. After that, the mask is removed (see FIG. 9B).

The conductive film 116 can be partly etched by one or both of wet etching and dry etching.

After the pair of electrodes 116a and 116b is formed, a surface of the oxide semiconductor film 120b (on a back channel side) may be cleaned. The cleaning may be performed, for example, using a chemical solution such as phosphoric acid. The cleaning using a chemical solution such as a phosphoric acid can remove impurities (e.g., an element contained in the pair of electrodes 116a and 116b) attached to the surface of the oxide semiconductor film 120b.

Note that a recessed portion might be formed in part of the oxide semiconductor film 120b in the step of forming the pair of electrodes 116a and 116b and/or the cleaning step.

### <Formation Step 1 of Protective Insulating Film>

Next, as illustrated in FIG. 9C, the insulating film 106 and the insulating film 107 are formed over the oxide semiconductor film 120 and the pair of electrodes 116a and 116b.

Note that after the insulating film 106 is formed, the insulating film 107 is preferably formed in succession without exposure to the air. After the insulating film 106 is formed, the insulating film 107 is formed in succession by adjusting at least one of the flow rate of a source gas, pressure, a high-frequency power, and a substrate temperature without exposure to the air, whereby the impurity concentration attributed to the atmospheric component at the interface between the insulating film 106 and the insulating film 107 can be reduced and oxygen in the insulating film 107 can be moved to the oxide semiconductor film 120; accordingly, the amount of oxygen vacancies in the oxide semiconductor film 120 can be reduced.

As the insulating film 106, a silicon oxynitride film can be formed by a PECVD method, for example. In this case, a deposition gas containing silicon and an oxidizing gas are preferably used as a source gas of the insulating film 106. Typical examples of the deposition gas containing silicon include silane, disilane, trisilane, and silane fluoride. Examples of the oxidizing gas include oxygen, ozone, dinitrogen monoxide and nitrogen dioxide. An insulating film containing nitrogen and having a small number of defects can be formed as the insulating film 106 by a PECVD method under the conditions where the ratio of the oxidizing gas to the deposition gas is higher than 20 times and lower than 100 times, preferably higher than or equal to 40 times and lower than or equal to 80 times and the pressure in a treatment chamber is lower than 100 Pa, preferably lower than or equal to 50 Pa.

Alternatively, a silicon oxide film or a silicon oxynitride film can be formed under the following conditions: the substrate placed in a treatment chamber of the PECVD apparatus that is vacuum-evacuated is held at a temperature higher than or equal to 180° C. and lower than or equal to 280° C., preferably higher than or equal to 200° C. and lower than or equal to 240° C.; the pressure is greater than or equal to 100 Pa and less than or equal to 250 Pa, preferably greater than or equal to 100 Pa and less than or equal to 200 Pa with introduction of a source gas into the treatment chamber; and a high-frequency power of greater than or equal to 0.17 W/cm² and less than or equal to 0.5 W/cm², preferably greater than or equal to 0.25 W/cm² and less than or equal to 0.35 W/cm² is supplied to an electrode provided in the treatment chamber.

With the use of the above conditions, an oxide insulating film which transmits oxygen can be formed as the insulating film 106. Further, by providing the insulating film 106, damage to the oxide semiconductor film 120 can be reduced in a step of forming the insulating film 107 which is formed later.

Under the above film formation conditions, the bonding strength of silicon and oxygen becomes strong in the above substrate temperature range. Thus, as the insulating film 106, a dense and hard oxide insulating film which transmits oxygen, as a typical example, a silicon oxide film or a silicon oxynitride film having an etching rate lower than or equal to 10 nm/min, preferably lower than or equal to 8 nm/min when etching is performed at 25° C. with 0.5 weight % using hydrofluoric acid can be formed.

In the case where hydrogen, water, and the like are contained in the oxide semiconductor film 120, the hydrogen, water, and the like can be removed in this step because the insulating film 106 is formed while heating is performed. Hydrogen contained in the oxide semiconductor film 120 is bonded to an oxygen radical formed in plasma to form water. Since the substrate is heated in the step of forming the insulating film 106, water formed by bonding of oxygen and hydrogen is released from the oxide semiconductor film 120. That is, when the insulating film 106 is formed by a PECVD method, the amount of water and hydrogen contained in the oxide semiconductor film 120 can be reduced.

Further, time for heating in a state where the oxide semiconductor film 120 is exposed can be shortened because heating is performed in a step of forming the insulating film 106. Thus, the amount of oxygen released from the oxide semiconductor film by heat treatment can be reduced. That is, oxygen vacancies in the oxide semiconductor film 120 can be reduced.

Note that by setting the pressure in the treatment chamber to be greater than or equal to 100 Pa and less than or equal to 250 Pa, the amount of water contained in the insulating film 106 is reduced; thus, variation in electrical characteristics of the transistor 150 can be reduced and change in threshold voltage can be inhibited.

Furthermore, by setting the pressure in the treatment chamber to be greater than or equal to 100 Pa and less than or equal to 250 Pa, damage to the oxide semiconductor film 120 can be reduced when the insulating film 106 is formed, so that oxygen vacancies contained in the oxide semiconductor film 120 can be reduced. In particular, when the film formation temperature of the insulating film 106 or the insulating film 107 which is formed later is set to be high, typified by a temperature higher than 220° C., part of oxygen contained in the oxide semiconductor film 120 is released and oxygen vacancies are easily formed. In addition, when the film formation conditions for reducing the amount of defects in the insulating film 107 which is formed later are used to increase reliability of the transistor, the amount of released oxygen is easily reduced. Thus, it is difficult to reduce oxygen vacancies in the oxide semiconductor film 120 in some cases. However, by setting the pressure in the treatment chamber to be greater than or equal to 100 Pa and less than or equal to 250 Pa to reduce damage to the oxide semiconductor film 120 at the time of forming the insulating film 106, oxygen vacancies in the oxide semiconductor film 120 can be reduced even when the amount of oxygen released from the insulating film 107 is small.

Note that when the ratio of the amount of the oxidizing gas to the amount of the deposition gas containing silicon is 200 or higher, the hydrogen content in the insulating film 106 can be reduced. Consequently, the amount of hydrogen entering the oxide semiconductor film 120 can be reduced; thus, the negative shift in the threshold voltage of the transistor can be inhibited.

Here, as the insulating film 106, a 50-nm-thick silicon oxynitride film is formed by a PECVD method in which silane at a flow rate of 50 sccm and dinitrogen monoxide at a flow rate of 2000 sccm are used as a source gas, the pressure in the treatment chamber is 20 Pa, the substrate temperature is 220° C., and a high-frequency power of 100 W is supplied to parallel-plate electrodes with the use of a 27.12 MHz high-frequency power source. Under the above conditions, a silicon oxynitride film which transmits oxygen can be formed.

As the insulating film 107, a silicon oxide film or a silicon oxynitride film is formed under the following conditions: the substrate placed in a treatment chamber of the PECVD apparatus that is vacuum-evacuated is held at a temperature higher than or equal to 180° C. and lower than or equal to 280° C., preferably higher than or equal to 200° C. and lower than or equal to 240° C., the pressure is greater than or equal to 100 Pa and less than or equal to 250 Pa, preferably greater than or equal to 100 Pa and less than or equal to 200 Pa with introduction of a source gas into the treatment chamber, and a high-frequency power greater than or equal to 0.17 W/cm² and less than or equal to 0.5 W/cm², preferably greater than or equal to 0.25 W/cm² and less than or equal to 0.35 W/cm² is supplied to an electrode provided in the treatment chamber.

A deposition gas containing silicon and an oxidizing gas are preferably used as the source gas of the insulating film 107. Typical examples of the deposition gas containing silicon include silane, disilane, trisilane, and silane fluoride. As the oxidizing gas, oxygen, ozone, dinitrogen monoxide, nitrogen dioxide, and the like can be given as examples.

As the film formation conditions of the insulating film 107, the high-frequency power having the above power density is supplied to a reaction chamber having the above pressure, whereby the degradation efficiency of the source gas in plasma is increased, oxygen radicals are increased, and oxidation of the source gas is promoted; thus, the oxygen content in the insulating film 107 becomes higher than that in the stoichiometric composition. On the other hand, in the film formed at a substrate temperature within the above temperature range, the bond between silicon and oxygen is weak, and accordingly, part of oxygen in the film is released by heat treatment in the later step. Thus, it is possible to form an oxide insulating film which contains oxygen at a higher proportion than the stoichiometric composition and from which part of oxygen is released by heating.

Further, the insulating film 106 is provided over the oxide semiconductor film 120. Accordingly, in the step of forming the insulating film 107, the insulating film 106 serves as a protective film of the oxide semiconductor film 120. Consequently, the insulating film 107 can be formed using the high-frequency power having a high power density while damage to the oxide semiconductor film 120 is reduced.

Here, as the insulating film 107, a 400-nm-thick silicon oxynitride film is formed by a PECVD method in which silane at a flow rate of 160 sccm and dinitrogen monoxide at a flow rate of 4000 sccm are used as the source gas, the pressure in the reaction chamber is 200 Pa, the substrate temperature is 220° C., and high-frequency power of 1500 W is supplied to the parallel-plate electrodes with the use of a 27.12 MHz high-frequency power source.

Next, heat treatment is performed. The heat treatment is performed at, as a typical example, a temperature higher than or equal to 150° C. and lower than or equal to 400° C., preferably higher than or equal to 300° C. and lower than or equal to 400° C., further preferably higher than or equal to 320° C. and lower than or equal to 370° C.

An electric furnace, an RTA apparatus, or the like can be used for the heat treatment. With the use of an RTA apparatus, the heat treatment can be performed at a temperature higher than or equal to the strain point of the substrate if the heating time is short. Therefore, the heat treatment time can be shortened.

The heat treatment may be performed under an atmosphere of nitrogen, oxygen, ultra-dry air (air in which a water content is 20 ppm or less, preferably 1 ppm or less, further preferably 10 ppb or less), or a rare gas (argon, helium, or the like). The atmosphere of nitrogen, oxygen, ultra-dry air, or a rare gas preferably does not contain hydrogen, water, and the like.

By the heat treatment, part of oxygen contained in the insulating film 107 can be moved to the oxide semiconductor film 120, so that oxygen vacancies contained in the oxide semiconductor film 120 can be further reduced.

In the case where the insulating film 106 and the insulating film 107 contain water, hydrogen, or the like, water, hydrogen, or the like contained in the insulating film 106 and the insulating film 107 is moved to the oxide semiconductor film 120 by heat treatment performed after an insulating film 108 that blocks water, hydrogen, and the like is formed, so that defects are generated in the oxide semiconductor film 120. However, when the heat treatment is performed prior to formation of the insulating film 108, water, hydrogen, or the like contained in the insulating film 106 and the insulating film 108 can be released; thus, variation in electrical characteristics of the transistor 150 can be reduced, and change in threshold voltage can be inhibited.

Note that when the insulating film 107 is formed over the insulating film 106 while being heated, oxygen can be moved to the oxide semiconductor film 120 to reduce the oxygen vacancies in the oxide semiconductor film 120; thus, the heat treatment needs not to be performed.

Here, heat treatment is performed at 350° C. for one hour in an atmosphere of nitrogen and oxygen.

Furthermore, when the pair of electrodes 116a and 116b is formed, the oxide semiconductor film 120 is damaged by the etching of the conductive film, so that oxygen vacancies are generated on the back channel side (the side of the oxide semiconductor film 120 which is opposite to the side facing to the gate electrode 114) of the oxide semiconductor film 120. However, with the use of the oxide insulating film containing oxygen at a higher proportion than the stoichiometric composition as the insulating film 107, the oxygen vacancies generated on the back channel side can be reduced by heat treatment. As a result, the reliability of the transistor 150 can be improved.

### <Step of Adding Oxygen to Oxide Insulating Film>

Next, a protective film 140 that inhibits release of oxygen is formed over the insulating film 107 (see FIG. 9D).

The protective film 140 can be formed using a conductive film including indium or a semiconductor film including indium. In this embodiment, a 5-nm-thick ITSO film is formed using a sputtering apparatus as the protective film 140. Note that the thickness of the protective film 140 is preferably greater than or equal to 1 nm and less than or equal to 20 nm or greater than or equal to 2 nm and less than or equal to 10 nm, in which case oxygen is favorably transmitted and release of oxygen can be inhibited.

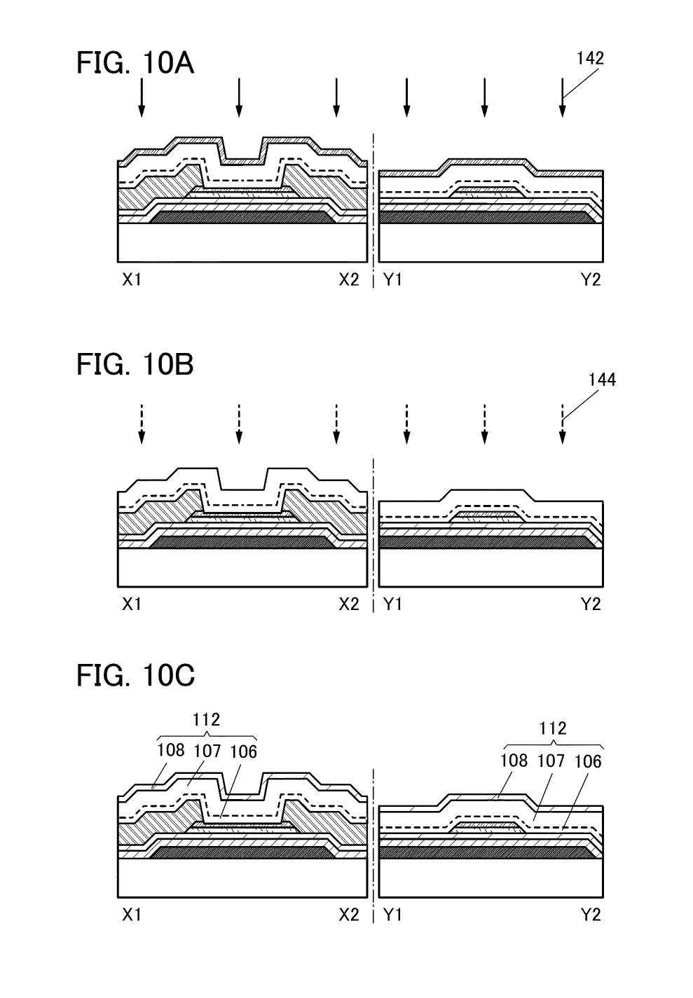

Next, oxygen 142 is added to the insulating films 106 and 107 through the protective film 140 (see FIG. 10A).

Examples of a method for adding the oxygen 142 to the insulating films 106 and 107 through the protective film 140 include an ion doping method, an ion implantation method (e.g., ion implantation, plasma-based ion implantation, plasma immersion ion implantation, and plasma source ion implantation), and a plasma treatment method. In the case of the plasma treatment method, high-density plasma may be generated by exciting a halogen element and oxygen with a microwave.

By application of a bias voltage to the substrate side when the oxygen 142 is added, the oxygen 142 can be effectively added to the insulating films 106 and 107. As the bias voltage, an ashing apparatus is used, for example, and the power density of the bias voltage applied to the substrate side of the ashing apparatus can be greater than or equal to 0.5 W/cm² and less than or equal to 5 W/cm². The substrate temperature during addition of the oxygen 142 is higher than or equal to room temperature and lower than or equal to 300° C., preferably higher than or equal to 100° C. and lower than or equal to 250° C., whereby the oxygen 142 can be added efficiently to the insulating films 106 and 107.

In this embodiment, an ashing apparatus is used. An oxygen gas is introduced into the ashing apparatus and a bias is applied to the substrate side, so that the oxygen 142 is added to the insulating films 106 and 107.

By adding the oxygen 142 after providing the protective film 140 over the insulating film 107, the protective film 140 functions as a protective film for inhibiting release of oxygen from the insulating film 107. Thus, a larger amount of oxygen can be added to the insulating films 106 and 107.

Next, the protective film 140 is removed using an etchant 144 (see FIG. 10B). As the etchant, a chemical solution or an etching gas is used to remove the protective film 140. In this embodiment, an oxalic acid solution containing an oxalic acid at a concentration of 5% is used as the etchant 144. As the etchant 144, after the oxalic acid solution containing an oxalic acid at a concentration of 5% is used, hydrofluoric acid at a concentration of 0.5% may be used. With the use of the hydrofluoric acid solution at a concentration of 0.5%, the protective film 140 that inhibits release of oxygen can be favorably removed.

### <Formation Step 2 of Protective Insulating Film>

Next, as illustrated in FIG. 10C, the insulating film 108 which is nitride is formed over the insulating film 107 by a sputtering method, a CVD method, or the like.

Note that in the case where the insulating film 108 is formed by a PECVD method, the substrate placed in the treatment chamber of the PECVD apparatus that is vacuum-evacuated is preferably set to be higher than or equal to 300° C. and lower than or equal to 400° C., more preferably, higher than or equal to 320° C. and lower than or equal to 370° C., so that a dense nitride insulating film can be formed.

In the case where a silicon nitride film is formed by the PECVD method as the insulating film 108, a deposition gas containing silicon, nitrogen, and ammonia are preferably used as a source gas. As the source gas, ammonia whose amount is smaller than the amount of nitrogen is used, whereby ammonia is dissociated in the plasma and activated species are generated. The activated species cut a bond between silicon and hydrogen which are contained in a deposition gas containing silicon and a triple bond between nitrogen molecules. As a result, a dense silicon nitride film having few defects, in which bonds between silicon and nitrogen are promoted and bonds between silicon and hydrogen is few, can be formed. On the other hand, when the amount of ammonia is larger than the amount of nitrogen in a source gas, decomposition of a deposition gas containing silicon and decomposition of nitrogen are not promoted, so that a sparse silicon nitride film in which bonds between silicon and hydrogen remain and defects are increased is formed. Thus, in a source gas, the flow ratio of the nitrogen to the ammonia is set to be preferably greater than or equal to 5 and less than or equal to 50, more preferably greater than or equal to 10 and less than or equal to 50.

Here, in the reaction chamber of a PECVD apparatus, a 100-nm-thick silicon nitride film is formed as the insulating film 108 by a PECVD method in which silane at a flow rate of 50 sccm, nitrogen at a flow rate of 5000 sccm, and ammonia at a flow rate of 100 sccm are used as the source gas, the pressure in the treatment chamber is 100 Pa, the substrate temperature is 350° C., and high-frequency power of 1000 W is supplied to parallel-plate electrodes with the use of a 27.12 MHz high-frequency power source.

Through the above-described steps, the insulating films 106 and 107 containing oxide and the insulating film 108 containing nitride, which function as the gate insulating film 112, can be formed.

Next, heat treatment may be performed after the insulating film 108 is formed. The heat treatment is performed at, as a typical example, a temperature higher than or equal to 150° C. and lower than or equal to 400° C., preferably higher than or equal to 300° C. and lower than or equal to 400° C., further preferably higher than or equal to 320° C. and lower than or equal to 370° C.

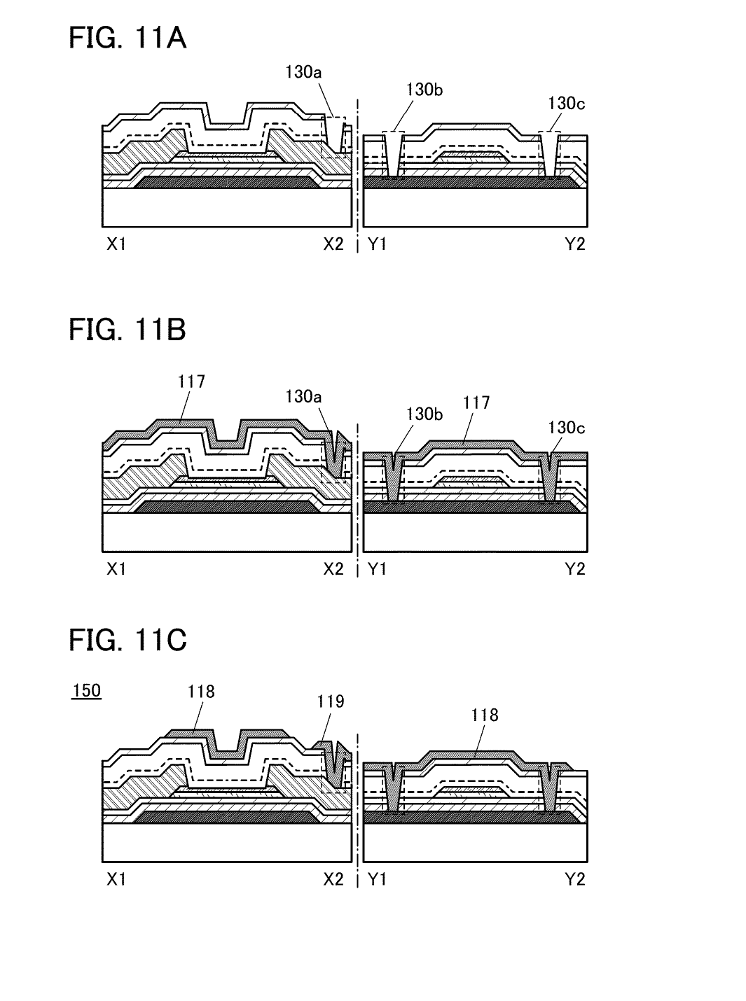

Next, a mask is formed over the insulating film 108 by a photolithography process using a fourth photomask, and then each of the insulating film 102, the insulating film 103, the insulating film 106, the insulating film 107, and the insulating film 108 is partly etched using the mask. As illustrated in the cross-sectional view along line X1-X2 in FIG. 11A, the opening portion 130a is provided in the gate insulating film 112. The opening portion 130a is formed to reach one of the pair of electrodes 116a and 116b (in FIG. 11A, the electrode 116b). As illustrated in the cross-sectional view along line Y1-Y2 in FIG. 11A, the opening portions 130b and 130c are provided in the gate insulating film 111 and the gate insulating film 112. The opening portions 130b and 130c are formed to reach the gate electrode 114.

Note that the opening portion 130a and the opening portions 130b and 130c may be formed in the same step or may be formed by different steps. In the case where the opening portion 130a and the opening portions 130b and 130c are formed in the same step, for example, a gray-tone mask or a half-tone mask can be used.

### <Formation Step of Gate Electrode and Pixel Electrode>

Then, as illustrated in FIG. 11B, a conductive film 117 to be the gate electrode 118 and the electrode 119 is formed.

The conductive film 117 is formed by a sputtering method, a CVD method, an evaporation method, or the like. Here, an ITSO film with a thickness of 100 nm is formed as the conductive film 117 by a sputtering method.

Then, a mask is formed over the conductive film 117 by a photolithography process using a fifth photomask. Next, the conductive film 117 is partly etched using the mask to form the gate electrode 118 and the electrode 119. After that, the mask is removed.

Note that as illustrated in FIG. 11C, in the channel width direction (Y1-Y2), the gate electrode 118 is formed so that the gate electrode 118 in the opening portions 130b and 130c and each of the side surfaces of the oxide semiconductor films 120a and 120b are provided so that the gate insulating film 112 is positioned therebetween.

Through the above process, the transistor 150 can be manufactured.

In the transistor 150 described in this embodiment, the opening portions 130b and 130c are provided in the gate insulating film 111 and the gate insulating film 112. In addition, in the channel width direction, the side surfaces of the oxide semiconductor film 120 are provided between two parts of the gate electrode 118, which is provided in the opening portions 130b and 130c, with the gate insulating film 112 positioned therebetween. Therefore, the side surface or its vicinity of the oxide semiconductor film 120 is influenced by an electric field of the gate electrode 118, and formation of a parasitic channel at the side surface or its vicinity of the oxide semiconductor film 120 is suppressed. As a result, the transistor 150 has excellent electrical characteristics. In addition, under the influence of the electric field of the gate electrode 118, carriers flow in a wide region in the oxide semiconductor film 120, so that the field-effect mobility and the on-state current of the transistor 150 are increased.

The oxide insulating film containing oxygen at higher proportion than the stoichiometric composition is formed to overlap with the oxide semiconductor film 120 that serves as a channel region, and thus, oxygen in the oxide insulating film can be transferred to the oxide semiconductor film 120. Consequently, oxygen vacancies contained in the oxide semiconductor film 120 can be reduced, so that the transistor 150 can have high reliability.

Through the above steps, a semiconductor device which includes the transistor 150 having the oxide semiconductor film 120 and has favorable electrical characteristics can be obtained. Furthermore, the semiconductor device including the transistor 150 having the oxide semiconductor film 120 can have high reliability.

### Modification Example 2

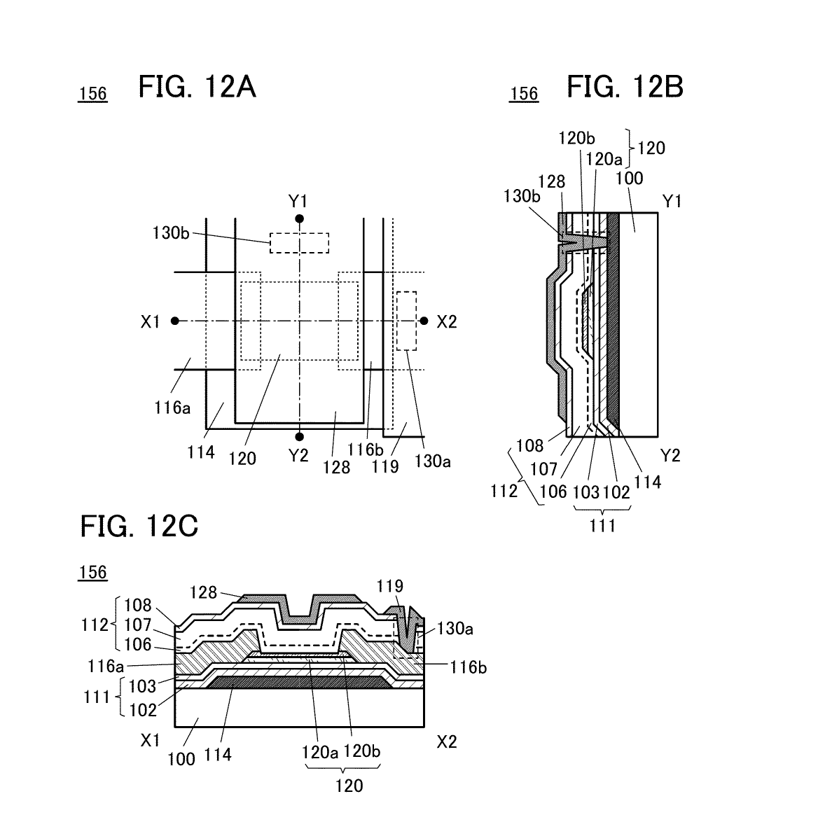

A transistor having a structure different from the structures shown in FIGS. 1A to 1C and FIGS. 2A to 2C will be described with reference to FIGS. 12A to 12C. Unlike the transistors 150 and 152, a transistor 156 illustrated in FIGS. 12A to 12C has a structure in which, in the channel width direction, the gate electrode 114 and a gate electrode 128 are connected to each other on an outer side of one side surface of the oxide semiconductor film 120, and the gate electrode 114 and the gate electrode 128 face each other on an outer side of the other side surface of the oxide semiconductor film 120, with the gate insulating film 111 and the gate insulating film 112 provided therebetween.

FIG. 12A is a top view of the transistor 156, FIG. 12B is a cross-sectional view taken along dashed-dotted line Y1-Y2 in FIG. 12A, and FIG. 12C is a cross-sectional view taken along dashed-dotted line X1-X2 in FIG. 12A. Note that in FIG. 12A, the substrate 100, insulating films, and the like are omitted for simplicity.

The transistor 156 shown in FIGS. 12A to 12C is a channel-etched transistor including the gate electrode 114, the gate insulating film 111, the gate insulating film 112, the oxide semiconductor film 120, the pair of electrodes 116a and 116b, a gate electrode 128, and the electrode 119 over the substrate 100. The gate insulating film 111 includes the insulating film 102 and the insulating film 103. The gate insulating film 112 includes the insulating film 106, the insulating film 107, and the insulating film 108. The insulating film 102 is formed over the gate electrode 114 and the substrate 100. The insulating film 103 is formed over the insulating film 102. The oxide semiconductor film 120 is formed over the insulating film 103. The pair of electrodes 116a and 116b is formed in contact with the oxide semiconductor film 120. The insulating film 106 and the insulating film 107 are formed over the insulating film 103, the oxide semiconductor film 120, and the pair of electrodes 116a and 116b. The insulating film 108 is formed over the insulating film 107. The gate electrode 128 and the electrode 119 are formed over the insulating film 108. The oxide semiconductor film 120 includes the oxide semiconductor film 120a and the oxide semiconductor film 120b. The gate electrode 128 is connected to the gate electrode 114 through the opening portion 130b provided in the gate insulating film 111 and the gate insulating film 112. The electrode 119 is connected to the one of the electrodes 116a and 116b (in FIG. 12C, the electrode 116b) through the opening portion 130a provided in the gate insulating film 112. Note that the pair of electrodes 116a and 116b functions as a source electrode and a drain electrode, and the electrode 119 functions as a pixel electrode.

The gate electrode 128 can be formed using a material and a formation method similar to those of the gate electrode 118 in the transistor 150, as appropriate. The gate electrode 128 and the electrode 119 can be formed at the same time.

In the transistor 156, the oxide semiconductor film 120 is provided between the gate electrode 114 and the gate electrode 128. In addition, as illustrated in FIG. 12A, the gate electrode 128 overlaps with the end portions of the oxide semiconductor film 120 with the gate insulating film 112 provided therebetween, when seen from the above.

Furthermore, a plurality of opening portions are provided in the gate insulating film 111 and the gate insulating film 112. As a typical example, as illustrated in FIG. 12C, the opening portion 130a that reaches one of the pair of electrodes 116a and 116b is provided. In addition, as illustrated in FIG. 12B, the opening portion 130b is provided in the gate insulating film 111 and the gate insulating film 112 on an outer side of one side surface of the oxide semiconductor film 120. The gate electrode 128 and the gate electrode 114 are connected to each other through the opening portion 130b. The gate electrode 128 in the opening portion 130b and the side surface of the oxide semiconductor film 120 are provided so that the gate insulating film 112 is positioned therebetween. The gate electrode 128 and the gate electrode 114 are not connected to each other on an outer side of the other side surface of the oxide semiconductor film 120. End portions of the gate electrode 128 are positioned on the outer sides of the side surfaces of the oxide semiconductor film 120. The gate electrode 128 extends to the outer side of the side surface of the oxide semiconductor film 120 (on the side in which the opening portion 130b is not provided). Thus, the side surface or its vicinity of the oxide semiconductor film 120 is influence by the electric field of the gate electrode 128, so that generation of a parasitic channel at the side surface and its vicinity of the oxide semiconductor film 120 can be suppressed. Moreover, since the opening portion is provided only in the vicinity of one of the side surfaces of the oxide semiconductor film 120, the area of the transistor can be made small.

### <Manufacturing Process 2 of Transistor>

Next, a manufacturing process of the transistor 156 will be described.

Through steps of FIGS. 8A to 8D, FIGS. 9A to 9D, and FIGS. 10A to 10C, the gate electrode 114, the insulating film 102, the insulating film 103, the oxide semiconductor film 120a, the oxide semiconductor film 120b, the pair of electrodes 116a and 116b, the insulating film 106, the insulating film 107, and the insulating film 108 are formed over the substrate 100. In the steps, a photolithography process is performed using the first to third photomasks.

Next, after a mask is formed over the insulating film 108 by a photolithography process using a fourth photomask, the insulating film 102, the insulating film 103, the insulating film 106, the insulating film 107, and the insulating film 108 are partly etched to form the opening portions 130a and 130b illustrated in FIGS. 12A to 12C.

Subsequently, the conductive film 117 is formed as in the step of FIG. 11B. Then, after a mask is formed over the conductive film 117 by a photolithography process using a fifth photomask, the conductive film 117 is partly etched to form the gate electrode 128 and the electrode 119 illustrated in FIGS. 12A to 12C.

Through the above process, the transistor 156 can be manufactured.

### Modification Example 3

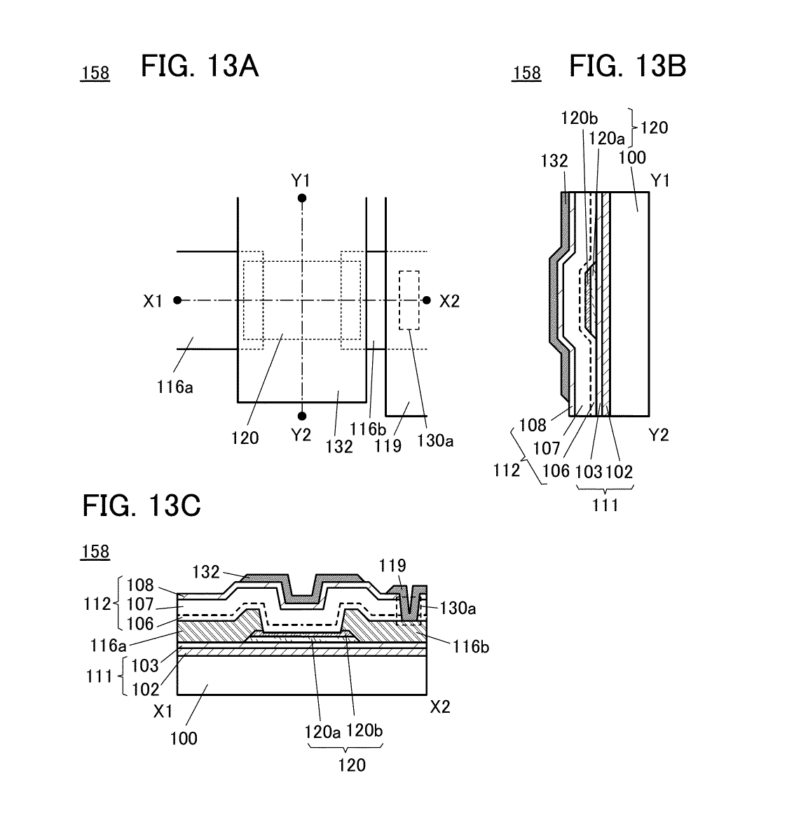

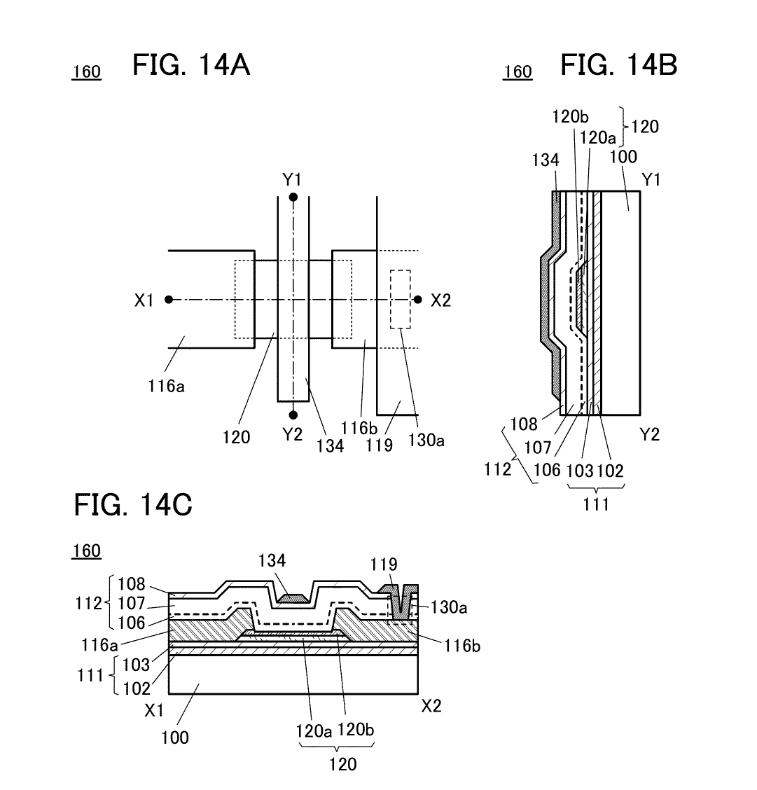

Transistors having structures different from those shown in FIGS. 1A to 1C, FIGS. 2A to 2C, and FIGS. 12A to 12C will be described with reference to FIGS. 13A to 13C and FIGS. 14A to 14C. A transistor 158 shown in FIGS. 13A to 13C includes a gate electrode 132 but does not include the gate electrode 114, unlike the transistors 150, 152, and 156. A transistor 160 shown in FIGS. 14A to 14C includes a gate electrode 134 but does not include the gate electrode 114, unlike the transistors 150, 152, and 156.

FIG. 13A is a top view of the transistor 158, FIG. 13B is a cross-sectional view taken along dashed-dotted line Y1-Y2 in FIG. 13A, and FIG. 13C is a cross-sectional view taken along dashed-dotted line X1-X2 in FIG. 13A. Note that in FIG. 13A, the substrate 100, insulating films, and the like are omitted for simplicity.

FIG. 14A is a top view of the transistor 160, FIG. 14B is a cross-sectional view taken along the dashed-dotted line Y1-Y2 in FIG. 14A, and FIG. 14C is a cross-sectional view taken along the dashed-dotted line X1-X2 in FIG. 14A. Note that in FIG. 14A, the substrate 100, insulating films, and the like are omitted for simplicity.

The transistors 158 and 160 shown in FIGS. 13A to 13C and FIGS. 14A to 14C are channel-etched transistors each including the gate insulating film 111, the gate insulating film 112, the oxide semiconductor film 120, the pair of electrodes 116a and 116b, and the electrode 119 over the substrate 100. The gate insulating film 111 includes the insulating film 102 and the insulating film 103. The gate insulating film 112 includes the insulating film 106, the insulating film 107, and the insulating film 108. The insulating film 102 is formed over the substrate 100. The insulating film 103 is formed over the insulating film 102. The oxide semiconductor film 120 is formed over the insulating film 103. The pair of electrodes 116a and 116b is formed in contact with the oxide semiconductor film 120. The insulating film 106 and the insulating film 107 are formed over the insulating film 103, the oxide semiconductor film 120, and the pair of electrodes 116a and 116b. The insulating film 108 is formed over the insulating film 107. The electrode 119 are formed over the insulating film 108. The oxide semiconductor film 120 includes the oxide semiconductor film 120a and the oxide semiconductor film 120b. The electrode 119 is connected to the one of the electrodes 116a and 116b (in FIGS. 13C and 14C, the electrode 116b) through the opening portion 130a provided in the gate insulating film 112. Note that the pair of electrodes 116a and 116b functions as a source electrode and a drain electrode, and the electrode 119 functions as a pixel electrode.

The transistor 158 includes the gate electrode 132 over the insulating film 108. The transistor 160 includes the gate electrode 134 over the insulating film 108.

The gate electrodes 132 and 134 can be formed using a material and a formation method similar to those of the gate electrode 118 in the transistor 150, as appropriate. The gate electrodes 132 and 134 and the electrode 119 can be formed at the same time.

As shown in FIG. 13A, the gate electrode 132 of the transistor 158 overlaps with end portions of the oxide semiconductor film 120 with the gate insulating film 112 provided therebetween, when seen from the above. This enables an electric field of the gate electrode 132 to affect the oxide semiconductor film 120 adequately. Moreover, since the gate electrode 114 is not included, the area of the transistor can be reduced.

As shown in FIG. 14A, the gate electrode 134 does not overlap with end portions of the oxide semiconductor film 120 and the pair of electrodes 116a and 116b with the gate insulating film 112 positioned therebetween in the transistor 160, when seen from the above. In addition, the area of the transistor can be reduced because the gate electrode 114 is not included.

One embodiment of the present invention has been described. Note that one embodiment of the present invention is not limited to the above. In other words, various embodiments of the invention are described in this embodiment and the other embodiments, and one embodiment of the present invention is not limited to a particular embodiment. Although the example where the oxide semiconductor film is included in the channel region, the source region, the drain region, and the like of the transistor is described as one embodiment of the present invention, one embodiment of the present invention is not limited to this example. Depending on cases or conditions, silicon, germanium, silicon germanium, silicon carbide, gallium arsenide, aluminum gallium arsenide, indium phosphide, gallium nitride, an organic semiconductor, or the like may be used in various transistors, a channel formation region of a transistor, a source region or a drain region of a transistor, or the like of one embodiment of the present invention. Alternatively, depending on cases or conditions, an oxide semiconductor film is not necessarily included in various transistors, a channel formation region of a transistor, a source region or a drain region of a transistor, or the like of one embodiment of the present invention, for example. Alternatively, an example in which an oxide semiconductor film having a two-layer structure is included in a channel region is described in this embodiment; however, one embodiment of the present invention is not limited to this example. Depending on cases or conditions, in one embodiment of the present invention, the oxide semiconductor film does not necessarily include two oxide semiconductor layers. In the structure described in this embodiment, the opening portion is provided to connect the two gate electrodes. However, one embodiment of the present invention is not limited to this structure. Depending on cases or conditions, a structure where an opening portion is not provided and two gate electrodes are not connected to each other may be employed. Note that in the structure where two gate electrodes are not connected to each other, different potentials can be applied to the two gate electrodes.

The structures, methods, and the like described in this embodiment can be used as appropriate in combination with any of the structures, methods, and the like described in the other embodiments.

### Embodiment 2

In this embodiment, an oxide semiconductor included in a semiconductor device of one embodiment of the present invention will be described in detail below.

### <Structure of Oxide Semiconductor>

First a structure of an oxide semiconductor is described below.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Note that an a-like OS has a periodic structure in a microscopic region, but at the same time has a void and has an unstable structure. For this reason, an a-like OS has physical properties similar to those of an amorphous oxide semiconductor.

### <CAAC-OS>

First, a CAAC-OS is described.

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

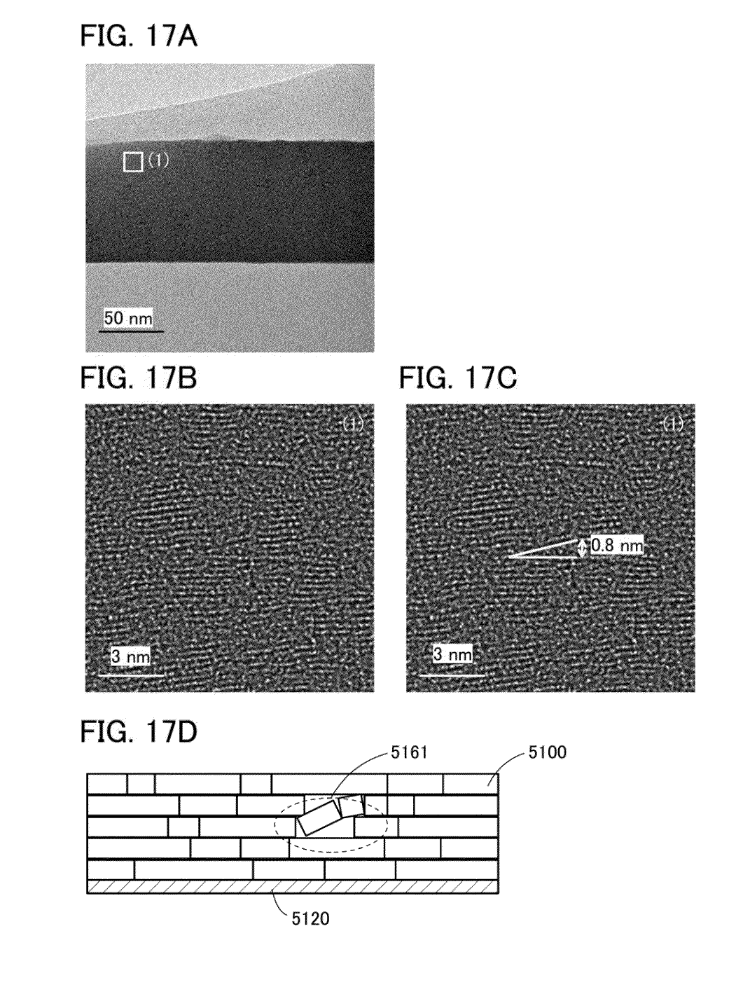

The CAAC-OS observed with a TEM is described below. FIG. 17A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 17B is an enlarged Cs-corrected high-resolution TEM image of a region (1) in FIG. 17A. FIG. 17B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 17B, the CAAC-OS has a characteristic atomic arrangement. The characteristic atomic arrangement is denoted by an auxiliary line in FIG. 17C. FIGS. 17B and 17C prove that the size of a pellet is greater than or equal to 1 nm or less than or equal to 3 nm, and the size of a space caused by tilt of the pellets is approximately 0.8 nm Therefore, the pellet can also be referred to as a nanocrystal (nc). Furthermore, the CAAC-OS can also be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 17D). The part in which the pellets are tilted as observed in FIG. 17C corresponds to a region 5161 shown in FIG. 17D.

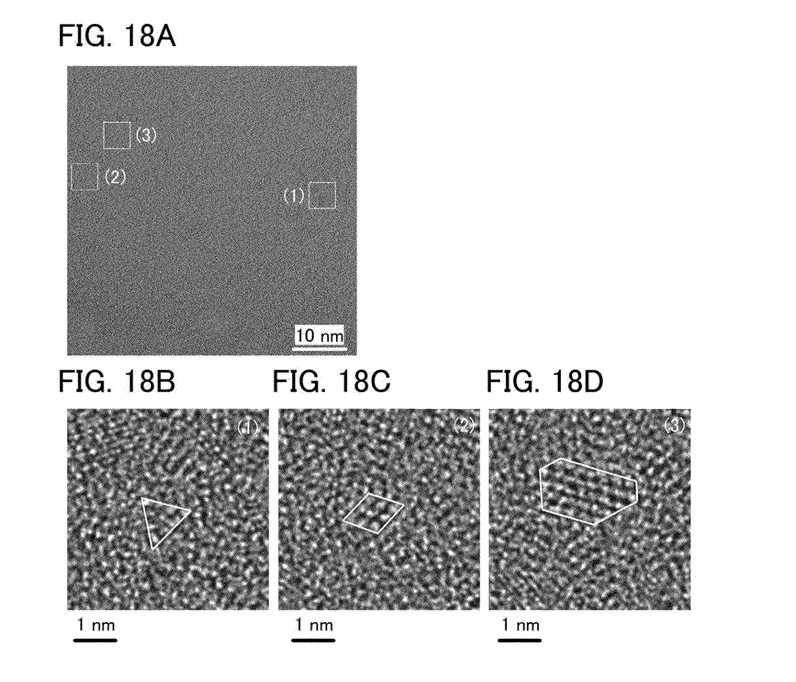

FIG. 18A shows a Cs-corrected high-resolution TEM image of a plane of the CAAC-OS observed from a direction substantially perpendicular to the sample surface. FIGS. 18B, 18C, and 18D are enlarged Cs-corrected high-resolution TEM images of regions (1), (2), and (3) in FIG. 18A, respectively. FIGS. 18B, 18C, and 18D indicate that metal atoms are arranged in a triangular, quadrangular, or hexagonal configuration in a pellet. However, there is no regularity of arrangement of metal atoms between different pellets.

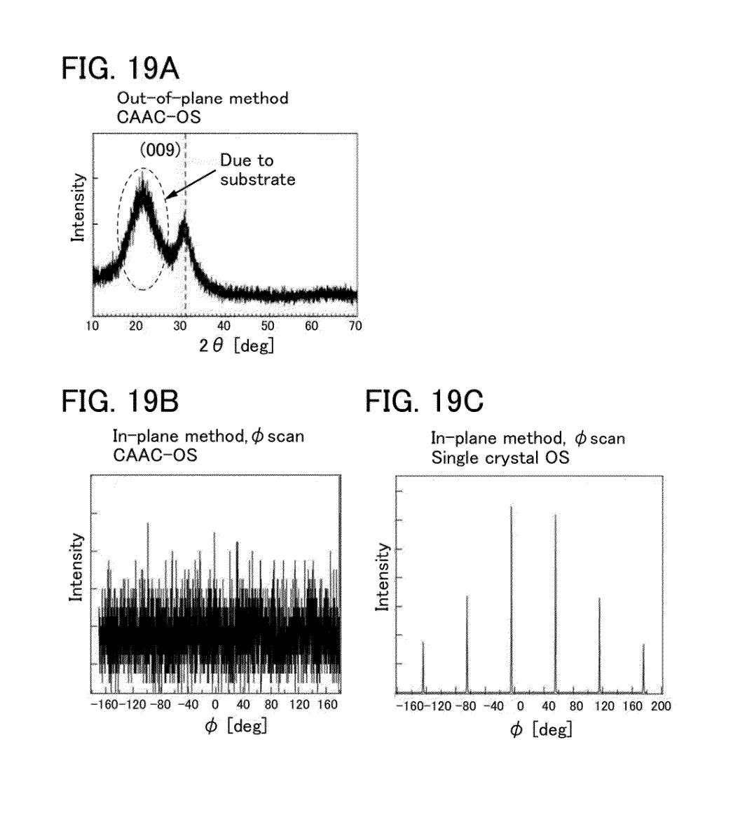

Next, a CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 19A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2θ of around 31°. The peak of 2θ at around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is derived from the (110) plane of the InGaZnO₄ crystal. In the case of the CAAC-OS, when analysis (φ scan) is performed with 2θ fixed at around 56° and with the sample rotated using a normal vector of the sample surface as an axis (φ axis), as shown in FIG. 19B, a peak is not clearly observed. In contrast, in the case of a single crystal oxide semiconductor of InGaZnO₄, when φ scan is performed with 2θ fixed at around 56°, as shown in FIG. 19C, six peaks which are derived from crystal planes equivalent to the (110) plane are observed. Accordingly, the structural analysis using XRD shows that the directions of a-axes and b-axes are irregularly oriented in the CAAC-OS.

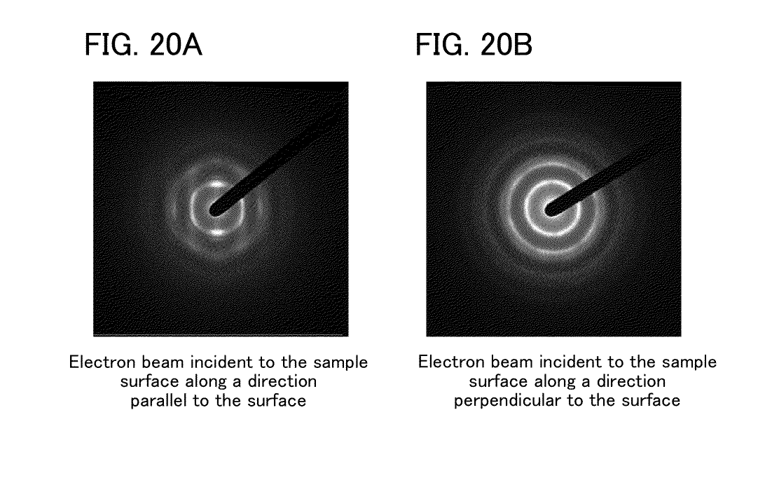

Next, a CAAC-OS analyzed by electron diffraction is described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 20A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 20B shows a diffraction pattern obtained in such a manner that an electron beam with a probe diameter of 300 nm is incident on the same sample in a direction perpendicular to the sample surface. As shown in FIG. 20B, a ring-like diffraction pattern is observed. Thus, the electron diffraction also indicates that the a-axes and b-axes of the pellets included in the CAAC-OS do not have regular alignment. The first ring in FIG. 20B is considered to be derived from the (010) plane, the (100) plane, and the like of the InGaZnO₄ crystal. The second ring in FIG. 20B is considered to be derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. Furthermore, oxygen vacancies in the oxide semiconductor serve as carrier traps or serve as carrier generation sources when hydrogen is captured therein.

The CAAC-OS having small amounts of impurities and oxygen vacancies is an oxide semiconductor with low carrier density (specifically, lower than 8×10¹¹/cm³, preferably lower than 1×10¹¹/cm³, further preferably lower than 1×10¹⁰/cm³, and is higher than or equal to 1×10⁻⁹/cm³). Such an oxide semiconductor is referred to as a highly purified intrinsic or substantially highly purified intrinsic oxide semiconductor. A CAAC-OS has a low impurity concentration and a low density of defect states. Thus, the CAAC-OS can be referred to as an oxide semiconductor having stable characteristics.

<nc-OS>

Next, an nc-OS is described.

An nc-OS has a region in which a crystal part is observed and a region in which a crystal part is not clearly observed in a high-resolution TEM image. In most cases, the size of a crystal part included in the nc-OS film is greater than or equal to 1 nm and less than or equal to 10 nm, or greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS or an amorphous oxide semiconductor, depending on an analysis method. For example, when the nc-OS is analyzed by an out-of-plane method using an X-ray beam having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet. Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots is shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

Thus, the nc-OS is an oxide semiconductor that has high regularity as compared to an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

<a-Like OS>

An a-like OS has a structure between those of the nc-OS and the amorphous oxide semiconductor.

In a high-resolution TEM image of the a-like OS film, a void may be observed. Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in structure caused by electron irradiation is described below.

An a-like OS (referred to as Sample A), an nc-OS (referred to as Sample B), and a CAAC-OS (referred to as Sample C) are prepared as samples subjected to electron irradiation. Each of the samples is an In—Ga—Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of the InGaZnO₄ crystal has a structure in which nine layers including three In—O layers and six Ga—Zn—O layers are stacked in the c-axis direction. Accordingly, the distance between the adjacent layers is equivalent to the lattice spacing on the (009) plane (also referred to as d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

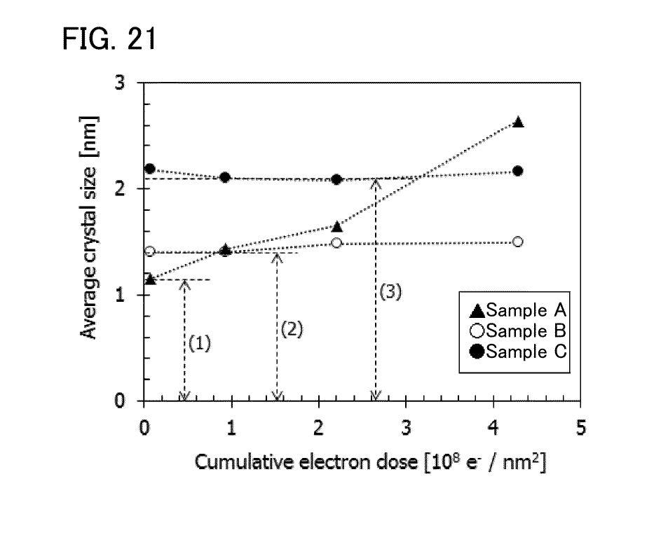

FIG. 21 shows change in the average size of crystal parts (measured in 22 to 45 points) in each sample. Note that the crystal part size corresponds to the length of a lattice fringe. FIG. 21 indicates that the crystal part size in the a-like OS increases with an increase in the cumulative electron dose. Specifically, as shown by (1) in FIG. 21, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 21, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that single crystals with the same composition do not exist in some cases. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more of an amorphous oxide semiconductor, an a-like OS, an nc-OS, and a CAAC-OS, for example.

<Formation Method of CAAC-OS and nc-OS>

An example of a method for forming a CAAC-OS film will be described below.

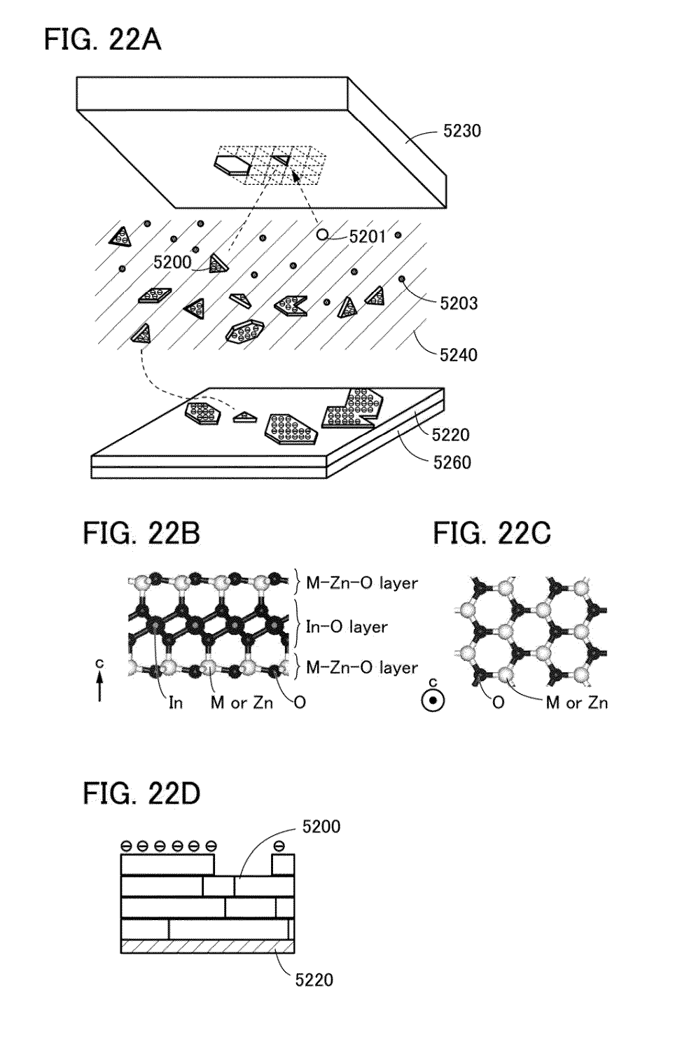

FIG. 22A is a schematic view of the inside of a film formation chamber. The CAAC-OS film can be formed by a sputtering method.

As shown in FIG. 22A, a substrate 5220 and a target 5230 are arranged to face each other. Plasma 5240 is generated between the substrate 5220 and the target 5230. A heating mechanism 5260 is under the substrate 5220. The target 5230 is attached to a backing plate (not illustrated in the drawing). A plurality of magnets is arranged to face the target 5230 with the backing plate positioned therebetween. A sputtering method in which the disposition speed is increased by utilizing a magnetic field of magnets is referred to as a magnetron sputtering method.

The distance d between the substrate 5220 and the target 5230 (also referred to as a target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 5 vol % or higher) and the pressure in the deposition chamber is controlled to be higher than or equal to 0.01 Pa and lower than or equal to 100 Pa, preferably higher than or equal to 0.1 Pa and lower than or equal to 10 Pa. Here, discharge starts by application of a voltage at a constant value or higher to the target 5230, and the plasma 5240 is observed. The magnetic field forms a high-density plasma region in the vicinity of the target 5230. In the high-density plasma region, the deposition gas is ionized, so that an ion 5201 is generated. Examples of the ion 5201 include an oxygen cation (O⁺) and an argon cation (Ar⁺).

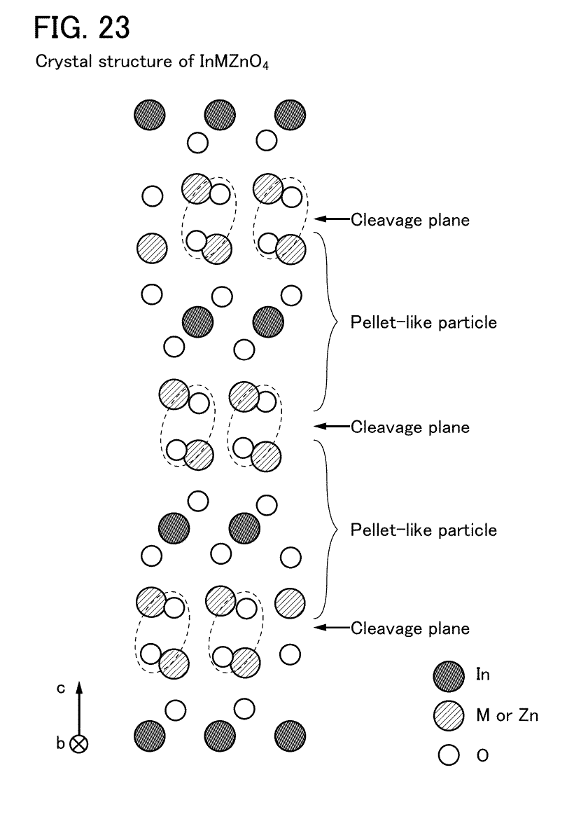

The target 5230 has a polycrystalline structure which includes a plurality of crystal grains and in which a cleavage plane exists in any of the crystal grains. FIG. 23 shows a crystal structure of InMZnO₄ (M is an element such as gallium, yttrium, or tin) included in the target 5230 as an example. Note that the crystal structure shown in FIG. 23 is InMZnO₄ observed from a direction parallel to a b-axis. In the crystal of InMZnO₄, oxygen atoms are negatively charged, whereby repulsive force is generated between the two adjacent M—Zn—O layers. Thus, the InMZnO₄ crystal has a cleavage plane between the two adjacent M—Zn—O layers.

The ion 5201 generated in the high-density plasma region is accelerated to move toward the target 5230 side by an electric field, and then collides with the target 5230. At this time, the pellet 5200 which is a flat-plate-like or pellet-like sputtered particle is separated from the cleavage plane (see FIG. 22A).

The pellet 5200 corresponds to a portion between the two cleavage planes shown in FIG. 23. Thus, when the pellet 5200 is observed, the cross-section thereof is as shown in FIG. 22B, and the top surface thereof is as shown in FIG. 22C. Note that structure of the pellet 5200 may be distorted by an impact of collision of the ion 5201. Note that along with the separation of the pellet 5200, a particle 5203 is also sputtered from the target 5230. The particle 5203 has an atom or an aggregate of several atoms. Therefore, the particle 5203 can be referred to as an atomic particle.

The pellet 5200 is a flat-plate-like (pellet-like) sputtered particle having a triangle plane, e.g., regular triangle plane. Alternatively, the pellet 5200 is a flat-plate-like (pellet-like) sputtered particle having a hexagon plane, e.g., regular hexagon plane. However, the shape of a flat plane of the pellet 5200 is not limited to a triangle or a hexagon. For example, the flat plane may have a shape formed by combining two or more triangles. For example, a quadrangle (e.g., rhombus) may be formed by combining two triangles (e.g., regular triangles).

The thickness of the pellet 5200 is determined depending on the kind of deposition gas and the like. For example, the thickness of the pellet 5200 is greater than or equal to 0.4 nm and less than or equal to 1 nm, preferably greater than or equal to 0.6 nm and less than or equal to 0.8 nm. In addition, the width of the pellet 5200 is, for example, greater than or equal to 1 nm and less than or equal to 3 nm, preferably greater than or equal to 1.2 nm and less than or equal to 2.5 nm. For example, the ion 5201 collides with the target 5230 including the In-M—Zn oxide. Then, the pellet 5200 including three layers of an M—Zn—O layer, an In—O layer, and an M—Zn—O layer is separated. Note that along with the separation of the pellet 5200, a particle 5203 is also sputtered from the target 5230.

The pellet 5200 may receive a charge when passing through the plasma 5240, so that surfaces thereof are negatively or positively charged. For example, the pellet 5200 receives a negative charge from O²⁻ in the plasma 5240. As a result, oxygen atoms on the surfaces of the pellet 5200 may be negatively charged. In addition, when passing through the plasma 5240, the pellet 5200 is sometimes combined with indium, the element M, zinc, oxygen, or the like in the plasma 5240 to grow up.

The pellet 5200 and the particle 5203 that have passed through the plasma 5240 reach the surface of the substrate 5220. Note that part of the particle 5203 is discharged to the outside by a vacuum pump or the like because the particle 5203 is small in mass.

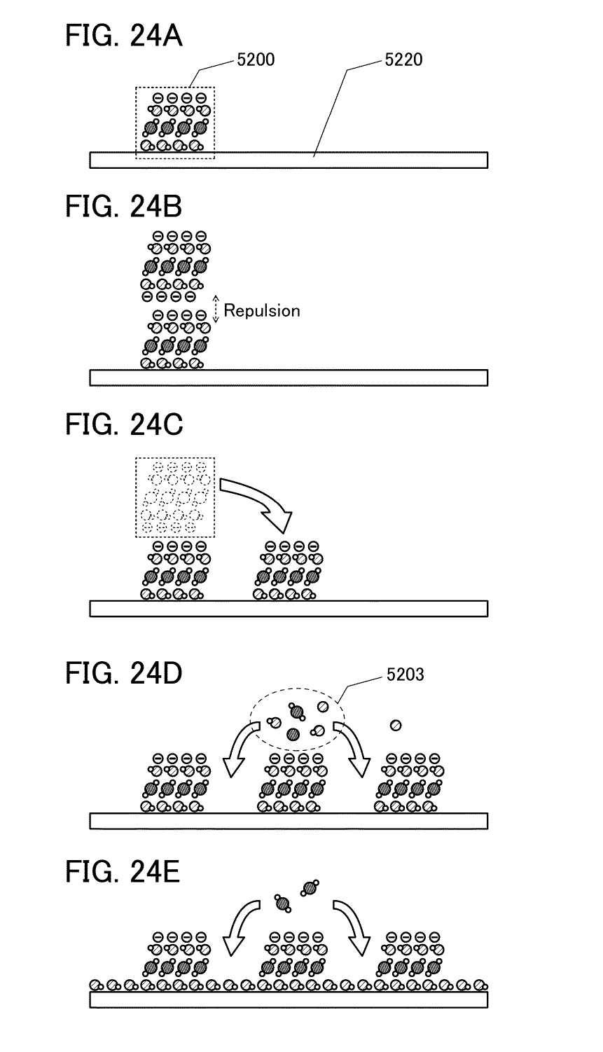

Next, deposition of the pellet 5200 and the particle 5203 over the surface of the substrate 5220 is described with reference to FIGS. 24A to 24E.

First, a first of the pellets 5200 is deposited over the substrate 5220. Since the pellet 5200 has a flat-plate-like shape, it is deposited so that the flat plane faces the surface of the substrate 5220 (FIG. 24A). Here, a charge on a surface of the pellet 5200 on the substrate 5220 side is lost through the substrate 5220.

Next, a second of the pellets 5200 reaches the substrate 5220. Here, since the surface of the first of the pellets 5200 and the surface of the second of the pellets 5200 are charged, they repel each other (FIG. 24B).

As a result, the second of the pellets 5200 avoids being deposited over the first of the pellets 5200, and is deposited over the surface of the substrate 5220 so as to be a little distance away from the first of the pellets 5200 (FIG. 24C). With repetition of this, millions of the pellets 5200 are deposited over the surface of the substrate 5220 to have a thickness of one layer. A region where any pellet 5200 is not deposited is generated between adjacent pellets 5200.

Next, the particle 5203 reaches the surface of the substrate 5220 (FIG. 24D).

The particle 5203 cannot be deposited over an active region such as the surface of the pellet 5200. Therefore, the particle 5203 is deposited so as to fill a region where the pellets 5200 are not deposited. The particles 5203 grow in the horizontal (lateral) direction between the pellets 5200, thereby connecting the pellets 5200. In this way, the particles 5203 are deposited until they fill regions where the pellets 5200 are not deposited. This mechanism is similar to a deposition mechanism of an atomic layer deposition (ALD) method.

Note that there can be several mechanisms for the lateral growth of the particles 5203 between the pellets 5200. For example, as shown in FIG. 24E, the pellets 5200 can be connected from side surfaces of the first M—Zn—O layers. In this case, after the first M—Zn—O layers make connection, the In—O layers and the second M—Zn—O layers are connected in this order (the first mechanism).

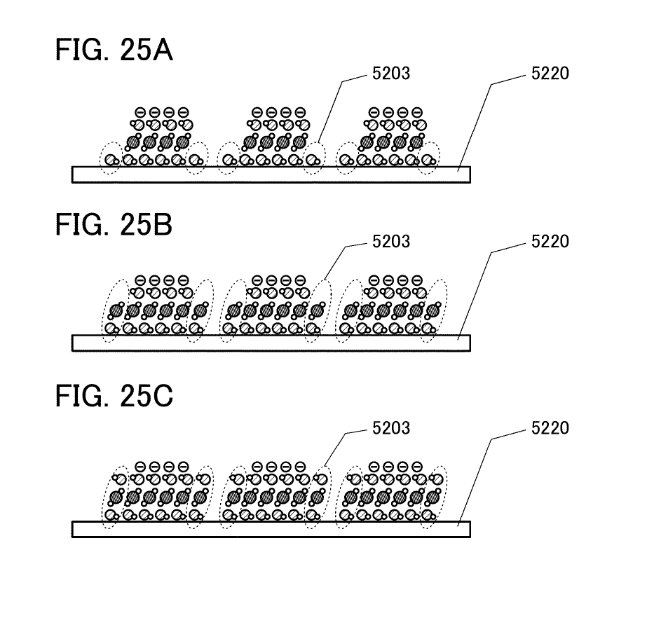

Alternatively, as shown in FIG. 25A, first, the particles 5203 are connected to the sides of the first M—Zn—O layers so that each side of the first M—Zn—O layer has one particle 5203. Then, as shown in FIG. 25B, the particle 5203 is connected to each side of the In—O layers. After that, as shown in FIG. 25C, the particle 5203 is connected to each side of the second M—Zn—O layers (the second mechanism).

Note that the connection can also be made by the simultaneous occurrence of the deposition in FIGS. 25A, 25B, and 25C (the third mechanism).

As shown in the above, the above three mechanisms are considered as the mechanisms of the lateral growth of the particles 5203 between the pellets 5200. However, the particles 5203 may grow up laterally between the pellets 5200 by other mechanisms.

Therefore, even when the orientations of a plurality of pellets 5200 are different from each other, generation of crystal boundaries can be suppressed since the particles 5203 laterally grow to fill gaps between the plurality of pellets 5200. In addition, as the particles 5203 make smooth connection between the plurality of pellets 5200, a crystal structure different from a single crystal and a polycrystal is formed. In other words, a crystal structure including distortion between minute crystal regions (pellets 5200) is formed. The regions filling the gaps between the crystal regions are distorted crystal regions, and thus, it will be not appropriate to say that the regions have an amorphous structure.

After the gaps between the pellets 5200 are filled with the particles 5203, a first layer with a thickness approximately the same as that of the pellet 5200 is formed. Then, a new first of the pellets 5200 is deposited over the first layer, and a second layer is formed. Thus, a second layer is formed. With repetition of this cycle, the stacked-layer thin film structure is formed.

A deposition way of the pellets 5200 changes depending on the surface temperature of the substrate 5220 or the like. For example, if the surface temperature of the substrate 5220 is high, migration of the pellets 5200 occurs over the substrate 5220. As a result, a proportion of the pellets 5200 that are directly connected with each other without the particles 5203 increases, whereby a CAAC-OS with high orientation is made. The surface temperature of the substrate 5220 for formation of the CAAC-OS is higher than or equal to 100° C. and lower than 500° C., preferably higher than or equal to 140° C. and lower than 450° C., or further preferably higher than or equal to 170° C. and lower than 400° C. Therefore, even when a large-sized substrate of the 8th generation or more is used as the substrate 5220, a warp or the like hardly occurs.

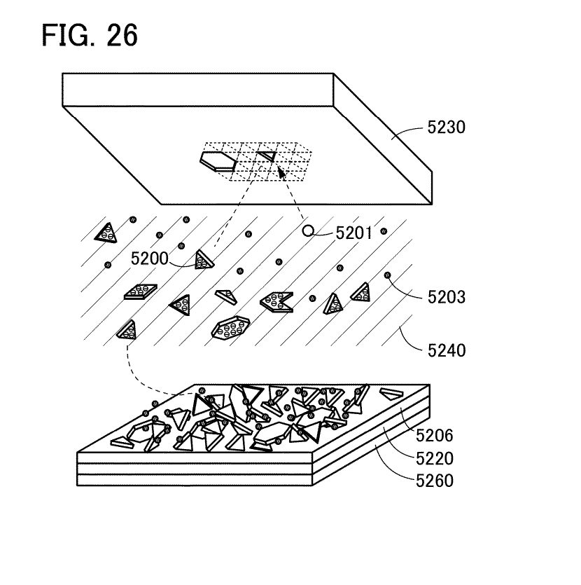

On the other hand, if the surface temperature of the substrate 5220 is low, the migration of the pellets 5200 over the substrate 5220 does not easily occur. As a result, the pellets 5200 overlap with each other, whereby an nc-OS with low orientation or the like is made (see FIG. 26). In the nc-OS, the pellets 5200 are deposited with certain gaps because the pellets 5200 are negatively charged. Therefore, the nc-OS film has low orientation but some regularity, and thus it has a denser structure than an amorphous oxide semiconductor.

When gaps between the pellets are extremely small in a CAAC-OS, the pellets may form a large pellet. The inside of the large pellet has a single crystal structure. For example, the size of the pellet may be greater than or equal to 10 nm and less than or equal to 200 nm, greater than or equal to 15 nm and less than or equal to 100 nm, or greater than or equal to 20 nm and less than or equal to 50 nm, when seen from the above.

According to such a model, the pellets 5200 are considered to be deposited on the surface of the substrate 5220. Thus, a CAAC-OS can be deposited even when a formation surface does not have a crystal structure; therefore, a growth mechanism in this case is different from epitaxial growth. In addition, a uniform film of a CAAC-OS or an nc-OS can be formed even over a large-sized glass substrate or the like. For example, even when the surface of the substrate 5220 (formation surface) has an amorphous structure (e.g., such as amorphous silicon oxide), a CAAC-OS can be formed.

Furthermore, it is found that the pellets 5200 are arranged in accordance with a surface shape of the substrate 5220 that is the film formation surface even when the film formation surface has unevenness.

The structure and method described in this embodiment can be implemented by being combined as appropriate with any of the other structures and methods described in the other embodiments.

### Embodiment 3

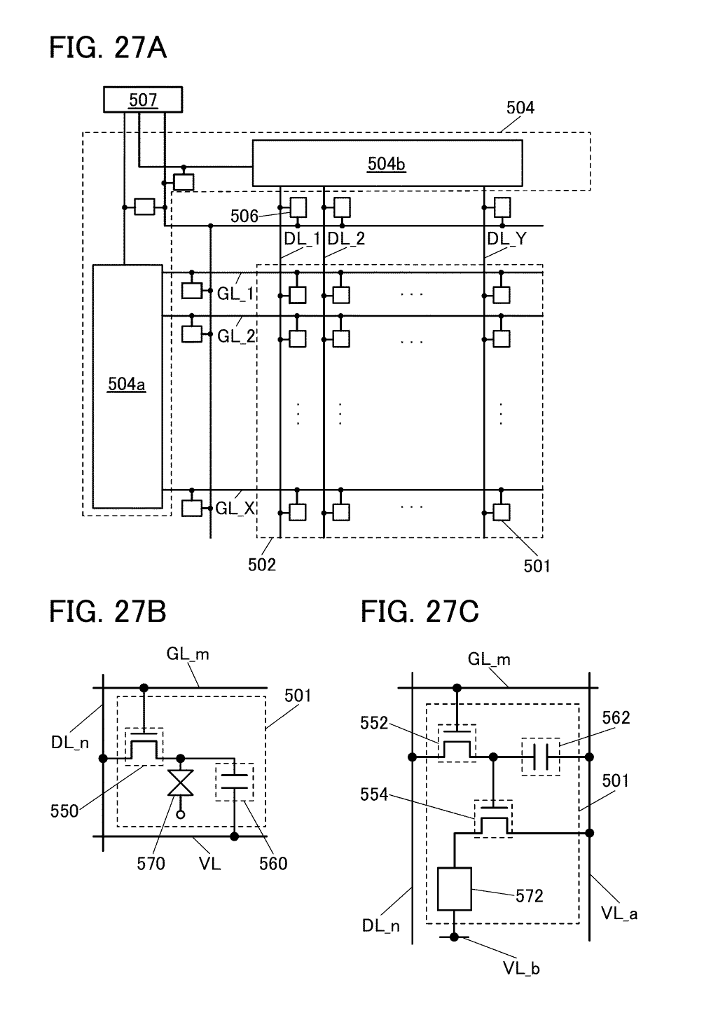

In this embodiment, a display device that includes a semiconductor device of one embodiment of the present invention is described with reference to FIGS. 27A to 27C.

### <Display Device>

The display device illustrated in FIG. 27A includes a region including pixels of display elements (hereinafter the region is referred to as a pixel portion 502), a circuit portion provided outside the pixel portion 502 and including a circuit for driving the pixels (hereinafter the portion is referred to as a driver circuit portion 504), circuits each having a function of protecting an element (hereinafter the circuits are referred to as protection circuits 506), and a terminal portion 507. Note that the protection circuits 506 are not necessarily provided.

A part or the whole of the driver circuit portion 504 is preferably formed over a substrate over which the pixel portion 502 is formed, in which case the number of components and the number of terminals can be reduced. When a part or the whole of the driver circuit portion 504 is not formed over the substrate over which the pixel portion 502 is formed, the part or the whole of the driver circuit portion 504 can be mounted by COG or tape automated bonding (TAB).

The pixel portion 502 includes a plurality of circuits for driving display elements arranged in X rows (X is a natural number of 2 or more) and Y columns (Y is a natural number of 2 or more) (hereinafter, such circuits are referred to as pixel circuits 501). The driver circuit portion 504 includes driver circuits such as a circuit for supplying a signal (scan signal) to select a pixel (hereinafter, the circuit is referred to as a gate driver 504a) and a circuit for supplying a signal (data signal) to drive a display element in a pixel (hereinafter, the circuit is referred to as a source driver 504b).

The gate driver 504a includes a shift register or the like. The gate driver 504a receives a signal for driving the shift register through the terminal portion 507 and outputs a signal. For example, the gate driver 504a receives a start pulse signal, a clock signal, or the like and outputs a pulse signal. The gate driver 504a has a function of controlling the potentials of wirings supplied with scan signals (hereinafter, such wirings are referred to as scan lines GL_1 to GL_X). Note that a plurality of gate drivers 504a may be provided to control the scan lines GL_1 to GL_X separately. Alternatively, the gate driver 504a has a function of supplying an initialization signal. Without being limited thereto, the gate driver 504a can supply another signal.

The source driver 504b includes a shift register or the like. The source driver 504b receives a signal (video signal) from which a data signal is derived, as well as a signal for driving the shift register, through the terminal portion 507. The source driver 504b has a function of generating a data signal to be written to the pixel circuit 501 which is based on the video signal. In addition, the source driver 504b has a function of controlling output of a data signal in response to a pulse signal produced by input of a start pulse signal, a clock signal, or the like. Furthermore, the source driver 504b has a function of controlling the potentials of wirings supplied with data signals (hereinafter such wirings are referred to as data lines DL_1 to DL_Y. Alternatively, the source driver 504b has a function of supplying an initialization signal. Without being limited thereto, the source driver 504b can supply another signal.

The source driver 504b includes a plurality of analog switches or the like, for example. The source driver 504b can output, as the data signals, signals obtained by time-dividing the video signal by sequentially turning on the plurality of analog switches. The source driver 504b may include a shift register or the like.

A pulse signal and a data signal are input to each of the plurality of pixel circuits 501 through one of the plurality of scan lines GL supplied with scan signals and one of the plurality of data lines DL supplied with data signals, respectively. Writing and holding of the data signal to and in each of the plurality of pixel circuits 501 are controlled by the gate driver 504a. For example, to the pixel circuit 501 in the m-th row and the n-th column (m is a natural number of less than or equal to X, and n is a natural number of less than or equal to Y), a pulse signal is input from the gate driver 504a through the scan line GL_m, and a data signal is input from the source driver 504b through the data line DL_n in accordance with the potential of the scan line GL_m.

The protection circuit 506 shown in FIG. 27A is connected to, for example, the scan line GL between the gate driver 504a and the pixel circuit 501. Alternatively, the protection circuit 506 is connected to the data line DL between the source driver 504b and the pixel circuit 501. Alternatively, the protection circuit 506 can be connected to a wiring between the gate driver 504a and the terminal portion 507. Alternatively, the protection circuit 506 can be connected to a wiring between the source driver 504b and the terminal portion 507. Note that the terminal portion 507 means a portion having terminals for inputting power, control signals, and video signals to the display device from external circuits.

The protection circuit 506 is a circuit that electrically connects a wiring connected to the protection circuit to another wiring when a potential out of a certain range is applied to the wiring connected to the protection circuit.

As illustrated in FIG. 27A, the protection circuits 506 are provided for the pixel portion 502 and the driver circuit portion 504, so that the resistance of the display device to overcurrent generated by electrostatic discharge (ESD) or the like can be improved. Note that the configuration of the protection circuits 506 is not limited to that, and for example, the protection circuit 506 may be configured to be connected to the gate driver 504a or the protection circuit 506 may be configured to be connected to the source driver 504b. Alternatively, the protection circuit 506 may be configured to be connected to the terminal portion 507.

In FIG. 27A, an example in which the driver circuit portion 504 includes the gate driver 504a and the source driver 504b is shown; however, the structure is not limited thereto. For example, only the gate driver 504a may be formed and a separately prepared substrate where a source driver circuit is formed (e.g., a driver circuit substrate formed with a single crystal semiconductor film or a polycrystalline semiconductor film) may be mounted.

Each of the plurality of pixel circuits 501 in FIG. 27A can have the structure illustrated in FIG. 27B, for example.

The pixel circuit 501 illustrated in FIG. 27B includes a liquid crystal element 570, a transistor 550, and a capacitor 560. As the transistor 550, any of the transistors described in the above embodiments can be used.

The potential of one of a pair of electrodes of the liquid crystal element 570 is set in accordance with the specifications of the pixel circuit 501 as appropriate. The alignment state of the liquid crystal element 570 depends on written data. A common potential may be supplied to one of the pair of electrodes of the liquid crystal element 570 included in each of the plurality of pixel circuits 501. Furthermore, the potential supplied to one of the pair of electrodes of the liquid crystal element 570 in the pixel circuit 501 in one row may be different from the potential supplied to one of the pair of electrodes of the liquid crystal element 570 in the pixel circuit 501 in another row.

As a driving method of the display device including the liquid crystal element 570, any of the following modes can be used, for example: a twisted nematic (TN) mode, a super-twisted nematic (STN) mode, a vertical alignment (VA) mode, a multi-domain vertical alignment (MVA) mode, a patterned vertical alignment (PVA) mode, an in-plane-switching (IPS) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, an FFS mode, a transverse bend alignment (TBA) mode, and the like.

Other examples of the driving method of the display device include an electrically controlled birefringence (ECB) mode, a polymer dispersed liquid crystal (PDLC) mode, a polymer network liquid crystal (PNLC) mode, and a guest-host mode. Note that the present invention is not limited to these examples, and various liquid crystal elements and driving methods can be applied to the liquid crystal element and the driving method thereof.

In the pixel circuit 501 in the m-th row and the n-th column, one of a source electrode and a drain electrode of the transistor 550 is electrically connected to the data line DL_n, and the other is electrically connected to the other of the pair of electrodes of the liquid crystal element 570. A gate electrode of the transistor 550 is electrically connected to the scan line GL_m. The transistor 550 has a function of controlling whether to write a data signal.

One of a pair of electrodes of the capacitor 560 is electrically connected to a wiring to which a potential is supplied (hereinafter referred to as a potential supply line VL), and the other is electrically connected to the other of the pair of electrodes of the liquid crystal element 570. The potential of the potential supply line VL is set in accordance with the specifications of the pixel circuit 501 as appropriate. The capacitor 560 functions as a storage capacitor for storing written data.

For example, in the display device including the pixel circuit 501 in FIG. 27B, the pixel circuits 501 are sequentially selected row by row by the gate driver 504a illustrated in FIG. 27A, whereby the transistors 550 are turned on and a data signal is written.

When the transistors 550 are turned off, the pixel circuits 501 in which the data has been written are brought into a holding state. This operation is sequentially performed row by row; thus, an image can be displayed.

Alternatively, each of the plurality of pixel circuits 501 in FIG. 27A can have the structure illustrated in FIG. 27C, for example.

The pixel circuit 501 illustrated in FIG. 27C includes transistors 552 and 554, a capacitor 562, and a light-emitting element 572. Any of the transistors described in the above embodiments can be used as one or both of the transistors 552 and 554.

One of a source electrode and a drain electrode of the transistor 552 is electrically connected to a wiring to which a data signal is supplied (hereinafter referred to as a data line DL_n). A gate electrode of the transistor 552 is electrically connected to a wiring to which a gate signal is supplied (hereinafter referred to as a scan line GL_m).

The transistor 552 has a function of controlling whether to write a data signal.

One of a pair of electrodes of the capacitor 562 is electrically connected to a wiring to which a potential is supplied (hereinafter referred to as a potential supply line VL_a), and the other is electrically connected to the other of the source electrode and the drain electrode of the transistor 552.

The capacitor 562 functions as a storage capacitor for storing written data.

One of a source electrode and a drain electrode of the transistor 554 is electrically connected to the potential supply line VL_a. Furthermore, a gate electrode of the transistor 554 is electrically connected to the other of the source electrode and the drain electrode of the transistor 552.

One of an anode and a cathode of the light-emitting element 572 is electrically connected to a potential supply line VL_b, and the other is electrically connected to the other of the source electrode and the drain electrode of the transistor 554.

As the light-emitting element 572, an organic electroluminescent element (also referred to as an organic EL element) or the like can be used, for example. Note that the light-emitting element 572 is not limited to an organic EL element; an inorganic EL element including an inorganic material may be used.

A high power supply potential VDD is supplied to one of the potential supply line VL_a and the potential supply line VL_b, and a low power supply potential VSS is supplied to the other.

For example, in the display device including the pixel circuit 501 in FIG. 27C, the pixel circuits 501 are sequentially selected row by row by the gate driver 504a illustrated in FIG. 27A, whereby the transistors 552 are turned on and a data signal is written.

When the transistors 552 are turned off, the pixel circuits 501 in which the data has been written are brought into a holding state. Furthermore, the amount of current flowing between the source electrode and the drain electrode of the transistor 554 is controlled in accordance with the potential of the written data signal. The light-emitting element 572 emits light with a luminance corresponding to the amount of flowing current. This operation is sequentially performed row by row; thus, an image can be displayed.

Although the structures including the liquid crystal element 570 or the light-emitting element 572 as a display element of the display device are described in this embodiment, one embodiment of the present invention is not limited to these structures and a variety of elements may be included in the display device.

For example, the display device includes at least one of a liquid crystal element, an EL element (e.g., an EL element including organic and inorganic materials, an organic EL element, or an inorganic EL element), an LED (e.g., a white LED, a red LED, a green LED, or a blue LED), a transistor (a transistor that emits light depending on current), an electron emitter, electronic ink, an electrophoretic element, a grating light valve (GLV), a plasma display panel (PDP), a display element using micro electro mechanical systems (MEMS), a digital micromirror device (DMD), a digital micro shutter (DMS), MIRASOL (registered trademark), an interferometric modulator display (IMOD) element, a MEMS shutter display element, an optical-interference-type MEMS display element, an electrowetting element, a piezoelectric ceramic display, a display element using a carbon nanotube, and the like. Alternatively, the display device may include a display medium whose contrast, luminance, reflectivity, transmittance, or the like is changed by electrical or magnetic effect. Examples of display devices including electron emitters are a field emission display (FED) and an SED-type flat panel display (SED: surface-conduction electron-emitter display). Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). An example of a display device including electronic ink or electrophoretic elements is electronic paper. In the case of a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes. Thus, the power consumption can be further reduced.

A progressive type display, an interlace type display, or the like can be employed as the display type of the display device of this embodiment. Further, color elements controlled in a pixel at the time of color display are not limited to three colors: R, G, and B (R, G, and B correspond to red, green, and blue, respectively). For example, four pixels of the R pixel, the G pixel, the B pixel, and a W (white) pixel may be included. Alternatively, a color element may be composed of two colors among R, G, and B as in PenTile layout. The two colors may differ among color elements. Alternatively, one or more colors of yellow, cyan, magenta, and the like may be added to RGB. Further, the size of a display region may be different depending on respective dots of the color elements. Embodiments of the disclosed invention are not limited to a display device for color display; the disclosed invention can also be applied to a display device for monochrome display.

White light (W) may be emitted from a backlight (e.g., an organic EL element, an inorganic EL element, an LED, or a fluorescent lamp) in the display device. Furthermore, a coloring layer (also referred to as a color filter) may be provided in the display device. As the coloring layer, red (R), green (G), blue (B), yellow (Y), or the like may be combined as appropriate, for example. With the use of the coloring layer, higher color reproducibility can be obtained than in the case without the coloring layer. In this case, by providing a region with the coloring layer and a region without the coloring layer, white light in the region without the coloring layer may be directly utilized for display. By partly providing the region without the coloring layer, a decrease in luminance due to the coloring layer can be suppressed, and 20% to 30% of power consumption can be reduced in some cases when an image is displayed brightly. Note that in the case where full-color display is performed using self-luminous elements such as organic EL elements or inorganic EL elements, the elements may emit light of their respective colors R, G, B, Y, and W. By using self-luminous elements, power consumption can be further reduced as compared to the case of using the coloring layer in some cases.

The structures described in this embodiment can be used in appropriate combination with any of the structures described in the other embodiments.

### Embodiment 4

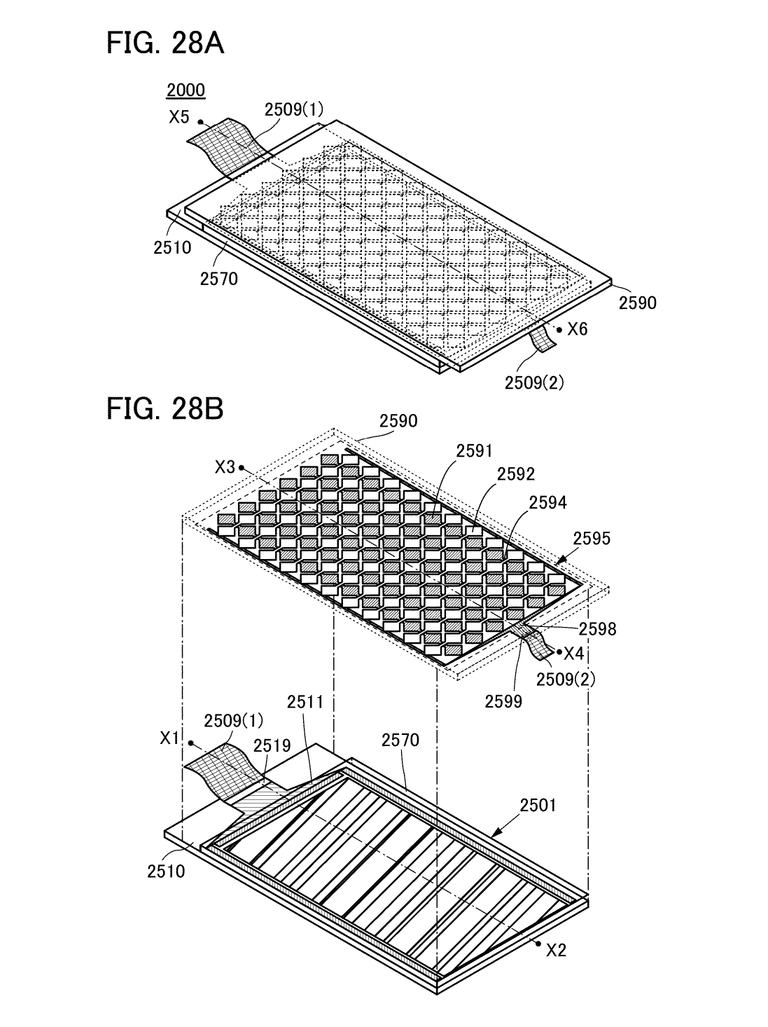

In this embodiment, a display device including a semiconductor device of one embodiment of the present invention and an electronic device in which the display device is provided with an input device will be described with reference to FIGS. 28A and 28B, FIGS. 29A and 29B, FIG. 30, FIGS. 31A and 31B, FIGS. 32A and 32B, and FIG. 33.

### <Touch Panel>

In this embodiment, a touch panel 2000 including a display device and an input device will be described as an example of an electronic device. In addition, an example in which a touch sensor is used as an input device will be described.

FIGS. 28A and 28B are perspective views of the touch panel 2000. Note that FIGS. 28A and 28B illustrate only main components of the touch panel 2000 for simplicity.

The touch panel 2000 includes a display device 2501 and a touch sensor 2595 (see FIG. 28B). The touch panel 2000 also includes a substrate 2510, a substrate 2570, and a substrate 2590. The substrate 2510, the substrate 2570, and the substrate 2590 each have flexibility. Note that one or all of the substrates 2510, 2570, and 2590 may be inflexible.

The display device 2501 includes a plurality of pixels over the substrate 2510 and a plurality of wirings 2511 through which signals are supplied to the pixels. The plurality of wirings 2511 are led to a peripheral portion of the substrate 2510, and parts of the plurality of wirings 2511 form a terminal 2519. The terminal 2519 is electrically connected to an FPC 2509(1).

The substrate 2590 includes the touch sensor 2595 and a plurality of wirings 2598 electrically connected to the touch sensor 2595. The plurality of wirings 2598 are led to a peripheral portion of the substrate 2590, and parts of the plurality of wirings 2598 form a terminal. The terminal is electrically connected to an FPC 2509(2). Note that in FIG. 28B, electrodes, wirings, and the like of the touch sensor 2595 provided on the back side of the substrate 2590 (the side facing the substrate 2510) are indicated by solid lines for clarity.

As the touch sensor 2595, a capacitive touch sensor can be used. Examples of the capacitive touch sensor are a surface capacitive touch sensor and a projected capacitive touch sensor.

Examples of the projected capacitive touch sensor are a self capacitive touch sensor and a mutual capacitive touch sensor, which differ mainly in the driving method. The use of a mutual capacitive type is preferable because multiple points can be sensed simultaneously.

Note that the touch sensor 2595 illustrated in FIG. 28B is an example of using a projected capacitive touch sensor.

Note that a variety of sensors that can sense proximity or touch of a sensing target such as a finger can be used as the touch sensor 2595.

The projected capacitive touch sensor 2595 includes electrodes 2591 and electrodes 2592. The electrodes 2591 are electrically connected to any of the plurality of wirings 2598, and the electrodes 2592 are electrically connected to any of the other wirings 2598.

The electrodes 2592 each have a shape of a plurality of quadrangles arranged in one direction with one corner of a quadrangle connected to one corner of another quadrangle as illustrated in FIGS. 28A and 28B.

The electrodes 2591 each have a quadrangular shape and are arranged in a direction intersecting with the direction in which the electrodes 2592 extend.

A wiring 2594 electrically connects two electrodes 2591 between which the electrode 2592 is positioned. The intersecting area of the electrode 2592 and the wiring 2594 is preferably as small as possible. Such a structure allows a reduction in the area of a region where the electrodes are not provided, reducing variation in transmittance. As a result, variation in luminance of light passing through the touch sensor 2595 can be reduced.

Note that the shapes of the electrodes 2591 and the electrodes 2592 are not limited thereto and can be any of a variety of shapes. For example, a structure may be employed in which the plurality of electrodes 2591 are arranged so that gaps between the electrodes 2591 are reduced as much as possible, and the electrodes 2592 are spaced apart from the electrodes 2591 with an insulating layer interposed therebetween to have regions not overlapping with the electrodes 2591. In this case, it is preferable to provide, between two adjacent electrodes 2592, a dummy electrode electrically insulated from these electrodes because the area of regions having different transmittances can be reduced.

Note that as a material of the conductive films such as the electrodes 2591, the electrodes 2592, and the wirings 2598, that is, wirings and electrodes forming the touch panel, a transparent conductive film containing indium oxide, tin oxide, zinc oxide, or the like (e.g., ITO) can be given. For example, a low-resistance material is preferably used as a material that can be used as the wirings and electrodes forming the touch panel. For example, silver, copper, aluminum, a carbon nanotube, graphene, or a metal halide (such as a silver halide) may be used. Alternatively, a metal nanowire including a plurality of conductors with an extremely small width (for example, a diameter of several nanometers) may be used. Further alternatively, a net-like metal mesh with a conductor may be used. For example, an Ag nanowire, a Cu nanowire, an Al nanowire, an Ag mesh, a Cu mesh, or an Al mesh may be used. For example, in the case of using an Ag nanowire as the wirings and electrodes forming the touch panel, a visible light transmittance of 89% or more and a sheet resistance of 40 Ω/cm² or more and 100 Ω/cm² or less can be achieved. Since the above-described metal nanowire, metal mesh, carbon nanotube, graphene, and the like, which are examples of the material that can be used as the wirings and electrodes forming the touch panel, have high visible light transmittances, they may be used as electrodes of display elements (e.g., a pixel electrode or a common electrode).

### <Display Device>

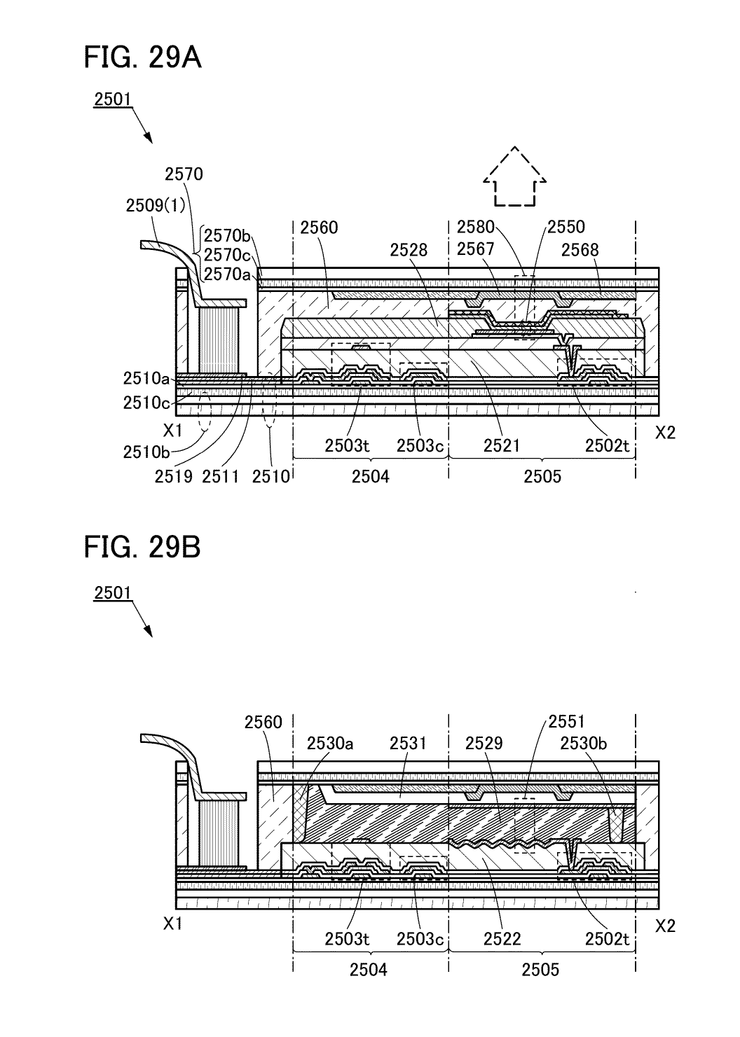

Next, the display device 2501 will be described in detail with reference to FIGS. 29A and 29B. FIGS. 29A and 29B correspond to cross-sectional views taken along dashed-dotted line X1-X2 in FIG. 28B.

The display device 2501 includes a plurality of pixels arranged in a matrix. Each of the pixels includes a display element and a pixel circuit for driving the display element.

(Structure with EL Element as Display Element)

First, a structure that uses an EL element as a display element will be described below with reference to FIG. 29A. In the following description, an example of using an EL element that emits white light will be described; however, the EL element is not limited to this element. For example, EL elements that emit light of different colors may be included so that the light of different colors can be emitted from adjacent pixels.

For the substrate 2510 and the substrate 2570, for example, a flexible material with a vapor permeability of lower than or equal to 1×10⁻⁵ g/(m²·day), preferably lower than or equal to 1×10⁻⁶ g/(m²·day) can be favorably used. Alternatively, materials whose thermal expansion coefficients are substantially equal to each other are preferably used for the substrate 2510 and the substrate 2570. For example, the coefficients of linear expansion of the materials are preferably lower than or equal to 1×10⁻³/K, further preferably lower than or equal to 5×10⁻⁵/K, and still further preferably lower than or equal to 1×10⁻⁵/K.

Note that the substrate 2510 is a stacked body including an insulating layer 2510a for preventing impurity diffusion into the EL element, a flexible substrate 2510b, and an adhesive layer 2510c for attaching the insulating layer 2510a and the flexible substrate 2510b to each other. The substrate 2570 is a stacked body including an insulating layer 2570a for preventing impurity diffusion into the EL element, a flexible substrate 2570b, and an adhesive layer 2570c for attaching the insulating layer 2570a and the flexible substrate 2570b to each other.

For the adhesive layer 2510c and the adhesive layer 2570c, for example, polyester, polyolefin, polyamide (e.g., nylon, aramid), polyimide, polycarbonate, an acrylic resin, polyurethane, an epoxy resin, or a resin having a siloxane bond can be used.

A sealing layer 2560 is provided between the substrate 2510 and the substrate 2570. The sealing layer 2560 preferably has a refractive index higher than that of air. In the case where light is extracted to the sealing layer 2560 side as illustrated in FIG. 29A, the sealing layer 2560 can also serve as an optical element.

A sealant may be formed in the peripheral portion of the sealing layer 2560. With the use of the sealant, an EL element 2550 can be provided in a region surrounded by the substrate 2510, the substrate 2570, the sealing layer 2560, and the sealant. Note that an inert gas (such as nitrogen or argon) may be used instead of the sealing layer 2560. A drying agent may be provided in the inert gas so as to adsorb moisture or the like. For example, an epoxy-based resin or a glass frit is preferably used as the sealant. As a material used for the sealant, a material which is impermeable to moisture or oxygen is preferably used.

The display device 2501 illustrated in FIG. 29A includes a pixel 2505. The pixel 2505 includes a light-emitting module 2580, the EL element 2550 and a transistor 2502t that can supply electric power to the EL element 2550. Note that the transistor 2502t functions as part of the pixel circuit.

The light-emitting module 2580 includes the EL element 2550 and a coloring layer 2567. The EL element 2550 includes a lower electrode, an upper electrode, and an EL layer between the lower electrode and the upper electrode.

In the case where the sealing layer 2560 is provided on the light extraction side, the sealing layer 2560 is in contact with the EL element 2550 and the coloring layer 2567.

The coloring layer 2567 is positioned in a region overlapping with the EL element 2550. Accordingly, part of light emitted from the EL element 2550 passes through the coloring layer 2567 and is emitted to the outside of the light-emitting module 2580 as indicated by an arrow in FIG. 29A.

The display device 2501 includes a light-blocking layer 2568 on the light extraction side. The light-blocking layer 2568 is provided so as to surround the coloring layer 2567.

The coloring layer 2567 is a coloring layer having a function of transmitting light in a particular wavelength region. For example, a color filter for transmitting light in a red wavelength range, a color filter for transmitting light in a green wavelength range, a color filter for transmitting light in a blue wavelength range, a color filter for transmitting light in a yellow wavelength range, or the like can be used. Each color filter can be formed with any of various materials by a printing method, an inkjet method, an etching method using a photolithography technique, or the like.

An insulating layer 2521 is provided in the display device 2501. The insulating layer 2521 covers the transistor 2502t and the like. Note that the insulating layer 2521 has a function of covering the roughness caused by the pixel circuit to provide a flat surface. The insulating layer 2521 may have a function of suppressing impurity diffusion. This can prevent the reliability of the transistor 2502t or the like from being lowered by impurity diffusion.

The EL element 2550 is formed over the insulating layer 2521. A partition 2528 is provided so as to overlap with an end portion of the lower electrode of the EL element 2550. Note that a spacer for controlling the distance between the substrate 2510 and the substrate 2570 may be formed over the partition 2528.

A gate driver circuit 2504 includes a transistor 2503t and a capacitor 2503c. Note that the driver circuit can be formed in the same process and over the same substrate as those of the pixel circuits.

The wirings 2511 through which signals can be supplied are provided over the substrate 2510. The terminal 2519 is provided over the wirings 2511. The FPC 2509(1) is electrically connected to the terminal 2519. The FPC 2509(1) has a function of supplying a video signal, a clock signal, a start signal, a reset signal, or the like. Note that the FPC 2509(1) may be provided with a printed wiring board (PWB).

Any of the transistors described in the above embodiments may be used as one or both of the transistors 2502t and 2503t. The transistors used in this embodiment each include an oxide semiconductor film which is highly purified and in which formation of oxygen vacancies is suppressed. In the transistors, the current in an off state (off-state current) can be made small. Accordingly, an electrical signal such as an image signal can be held for a longer period, and a writing interval can be set longer in an on state. Accordingly, the frequency of refresh operation can be reduced, which leads to an effect of suppressing power consumption. In addition, the transistors used in this embodiment can have relatively high field-effect mobility and thus are capable of high speed operation. For example, with such transistors which can operate at high speed used for the display device 2501, a switching transistor of a pixel circuit and a driver transistor in a driver circuit portion can be formed over one substrate. That is, a semiconductor device formed using a silicon wafer or the like is not additionally needed as a driver circuit, by which the number of components of the semiconductor device can be reduced. In addition, by using a transistor which can operate at high speed in a pixel circuit, a high-quality image can be provided.

(Structure with Liquid Crystal Element as Display Element)

Next, a structure including a liquid crystal element as a display element is described below with reference to FIG. 29B. In the description below, a reflective liquid crystal display device that performs display by reflecting external light is described; however, one embodiment of the present invention is not limited to this type of liquid crystal display device. For example, a light source (e.g., a back light or a side light) may be provided to form a transmissive liquid crystal display device or a transflective liquid crystal display device.

The display device 2501 illustrated in FIG. 29B has the same structure as the display device 2501 illustrated in FIG. 29A except the following points.

The pixel 2505 in the display device 2501 illustrated in FIG. 29B includes a liquid crystal element 2551 and the transistor 2502t that can supply electric power to the liquid crystal element 2551.

The liquid crystal element 2551 includes a lower electrode (also referred to as a pixel electrode), an upper electrode, and a liquid crystal layer 2529 between the lower electrode and the upper electrode. By the application of a voltage between the lower electrode and the upper electrode, the alignment state of the liquid crystal layer 2529 in the liquid crystal element 2551 can be changed. Furthermore, in the liquid crystal layer 2529, a spacer 2530a and a spacer 2530b are provided. Although not illustrated in FIG. 29B, an alignment film may be provided on each of the upper electrode and the lower electrode on the side in contact with the liquid crystal layer 2529.

As the liquid crystal layer 2529, thermotropic liquid crystal, low-molecular liquid crystal, high-molecular liquid crystal, polymer dispersed liquid crystal, ferroelectric liquid crystal, or anti-ferroelectric liquid crystal can be used. Such a liquid crystal material exhibits a cholesteric phase, a smectic phase, a cubic phase, a chiral nematic phase, an isotropic phase, or the like depending on conditions. In the case of employing a horizontal electric field mode liquid crystal display device, liquid crystal exhibiting a blue phase for which an alignment film is unnecessary may be used. In the case where a liquid crystal exhibiting a blue phase is used, an alignment film is not necessarily provided, so that rubbing treatment is also unnecessary. Accordingly, electrostatic discharge damage caused by the rubbing treatment can be prevented and defects and damage of the liquid crystal display device in the manufacturing process can be reduced.

The spacers 2530a and 2530b are formed by selectively etching an insulating film. The spacers 2530a and 2530b are provided in order to control the distance between the substrate 2510 and the substrate 2570 (the cell gap). Note that the spacers 2530a and 2530b may have different sizes from each other and are preferably have a columnar or spherical shape. Although the spacers 2530a and 2530b are provided on the substrate 2570 side in the non-limiting structure in FIG. 29B, they may be provided on the substrate 2510 side.

The upper electrode of the liquid crystal element 2551 is provided on the substrate 2570 side. An insulating layer 2531 is provided between the upper electrode and the coloring layer 2567 and the light-blocking layer 2568. The insulating layer 2531 has a function of covering the roughness caused by the coloring layer 2567 and the light-blocking layer 2568 to provide a flat surface. As the insulating layer 2531, a resin film may be used, for example. The lower electrode of the liquid crystal element 2551 has a function of a reflective electrode. The display device 2501 illustrated in FIG. 29B is of a reflective type which performs display by reflecting external light at the lower electrode and making the light pass through the coloring layer 2567. Note that in the case of forming a transmissive liquid crystal display device, a transparent electrode is provided as the lower electrode.

The display device 2501 illustrated in FIG. 29B includes an insulating layer 2522. The insulating layer 2522 covers the transistor 2502t and the like. The insulating layer 2522 has a function of covering the roughness caused by the pixel circuit to provide a flat surface and a function of forming roughness on the lower electrode of the liquid crystal element. In this way, roughness can be formed on the surface of the lower electrode. Therefore, when external light is incident on the lower electrode, the light is reflected diffusely at the surface of the lower electrode, whereby visibility can be improved. Note that in the case of forming a transmissive liquid crystal display device, a structure without such roughness may be employed.

### <Touch Sensor>

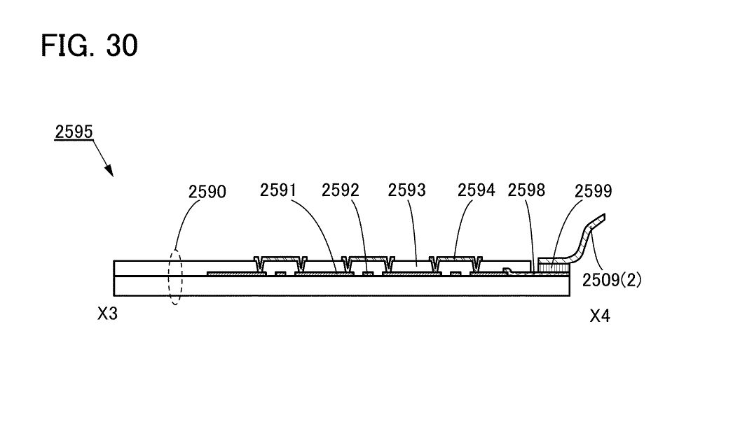

Next, the touch sensor 2595 will be described in detail with reference to FIG. 30. FIG. 30 corresponds to a cross-sectional view taken along dashed-dotted line X3-X4 in FIG. 28B.

The touch sensor 2595 includes the electrodes 2591 and the electrodes 2592 provided in a staggered arrangement on the substrate 2590, an insulating layer 2593 covering the electrodes 2591 and the electrodes 2592, and the wiring 2594 that electrically connects the adjacent electrodes 2591 to each other.

The electrodes 2591 and the electrodes 2592 are formed using a light-transmitting conductive material. As a light-transmitting conductive material, a conductive oxide such as indium oxide, indium tin oxide, indium zinc oxide, zinc oxide, or zinc oxide to which gallium is added can be used. Note that a film containing graphene may be used as well. The film containing graphene can be formed, for example, by reducing a film containing graphene oxide. As a reducing method, a method with application of heat or the like can be employed.

The electrodes 2591 and the electrodes 2592 may be formed by, for example, depositing a light-transmitting conductive material on the substrate 2590 by a sputtering method and then removing an unnecessary portion by any of various pattern forming techniques such as photolithography.

Examples of a material for the insulating layer 2593 are a resin such as an acrylic resin or an epoxy resin, a resin having a siloxane bond such as silicon, and an inorganic insulating material such as silicon oxide, silicon oxynitride, or aluminum oxide.

Openings reaching the electrodes 2591 are formed in the insulating layer 2593, and the wiring 2594 electrically connects the adjacent electrodes 2591. A light-transmitting conductive material can be favorably used as the wiring 2594 because the aperture ratio of the touch panel can be increased. Moreover, a material with higher conductivity than the conductivities of the electrodes 2591 and 2592 can be favorably used for the wiring 2594 because electric resistance can be reduced.

One electrode 2592 extends in one direction, and a plurality of electrodes 2592 are provided in the form of stripes. The wiring 2594 intersects with the electrode 2592.

Adjacent electrodes 2591 are provided with one electrode 2592 provided therebetween. The wiring 2594 electrically connects the adjacent electrodes 2591.

Note that the plurality of electrodes 2591 are not necessarily arranged in the direction orthogonal to one electrode 2592 and may be arranged to intersect with one electrode 2592 at an angle of more than 0 degrees and less than 90 degrees.

The wiring 2598 is electrically connected to any of the electrodes 2591 and 2592. Part of the wiring 2598 functions as a terminal. For the wiring 2598, a metal material such as aluminum, gold, platinum, silver, nickel, titanium, tungsten, chromium, molybdenum, iron, cobalt, copper, or palladium or an alloy material containing any of these metal materials can be used.

Note that an insulating layer that covers the insulating layer 2593 and the wiring 2594 may be provided to protect the touch sensor 2595.

A connection layer 2599 electrically connects the wiring 2598 to the FPC 2509(2).

As the connection layer 2599, any of various anisotropic conductive films (ACF), anisotropic conductive pastes (ACP), or the like can be used.

### <Touch Panel>

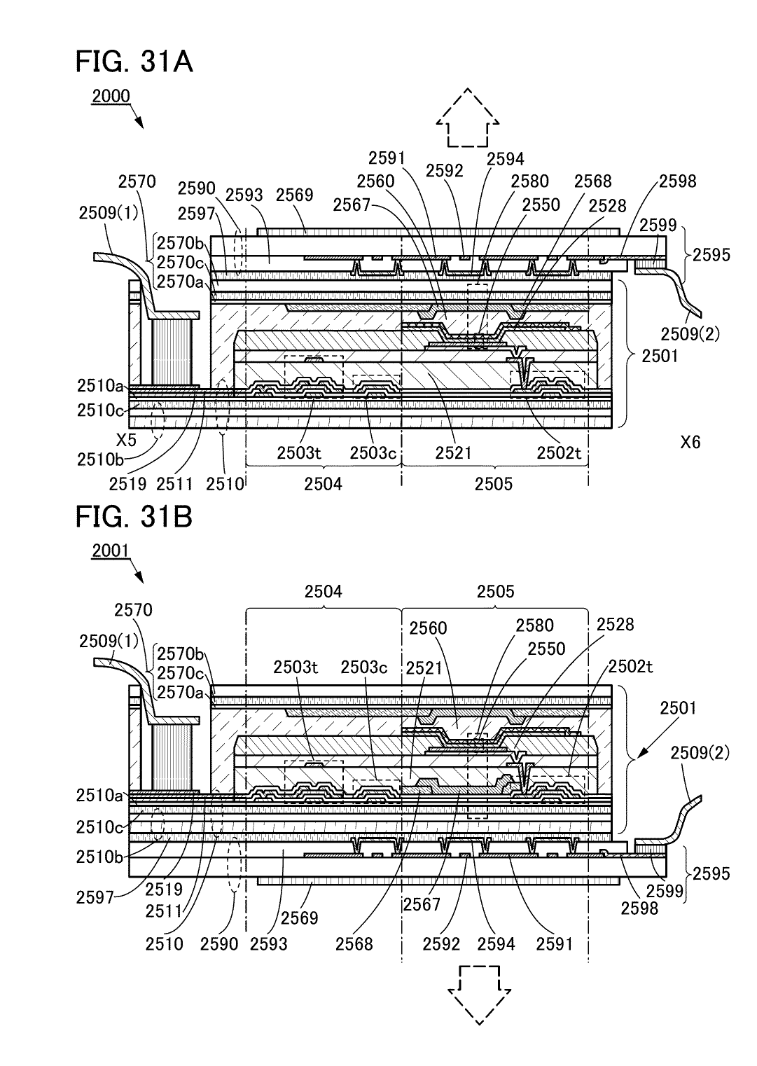

Next, the touch panel 2000 will be described in detail with reference to FIG. 31A. FIG. 31A corresponds to a cross-sectional view taken along dashed-dotted line X5-X6 in FIG. 28A.

In the touch panel 2000 illustrated in FIG. 31A, the display device 2501 described with reference to FIG. 29A and the touch sensor 2595 described with reference to FIG. 30 are attached to each other.

The touch panel 2000 illustrated in FIG. 31A includes an adhesive layer 2597 and an anti-reflective layer 2569 in addition to the components described with reference to FIG. 29A.

The adhesive layer 2597 is provided in contact with the wiring 2594. Note that the adhesive layer 2597 attaches the substrate 2590 to the substrate 2570 so that the touch sensor 2595 overlaps with the display device 2501. The adhesive layer 2597 preferably has a light-transmitting property. A heat curable resin or an ultraviolet curable resin can be used for the adhesive layer 2597. For example, an acrylic resin, a urethane-based resin, an epoxy-based resin, or a siloxane-based resin can be used.

The anti-reflective layer 2569 is positioned in a region overlapping with pixels. As the anti-reflective layer 2569, a circularly polarizing plate can be used, for example.

Next, a touch panel having a structure different from that illustrated in FIG. 31A will be described with reference to FIG. 31B.

FIG. 31B is a cross-sectional view of a touch panel 2001. The touch panel 2001 illustrated in FIG. 31B differs from the touch panel 2000 illustrated in FIG. 31A in the position of the touch sensor 2595 relative to the display device 2501. Different parts are described in detail below, and the above description of the touch panel 2000 is referred to for the other similar parts.

The coloring layer 2567 is positioned under the EL element 2550. The EL element 2550 illustrated in FIG. 31B emits light to the side where the transistor 2502t is provided. Accordingly, part of light emitted from the EL element 2550 passes through the coloring layer 2567 and is emitted to the outside of the light-emitting module 2580 as indicated by an arrow in FIG. 31B.

The touch sensor 2595 is provided on the substrate 2510 side of the display device 2501.

The adhesive layer 2597 is provided between the substrate 2510 and the substrate 2590 and attaches the touch sensor 2595 to the display device 2501.

As illustrated in FIG. 31A or FIG. 31B, light may be emitted from the light-emitting element to one or both of upper and lower sides of the substrate.

### <Driving Method of Touch Panel>

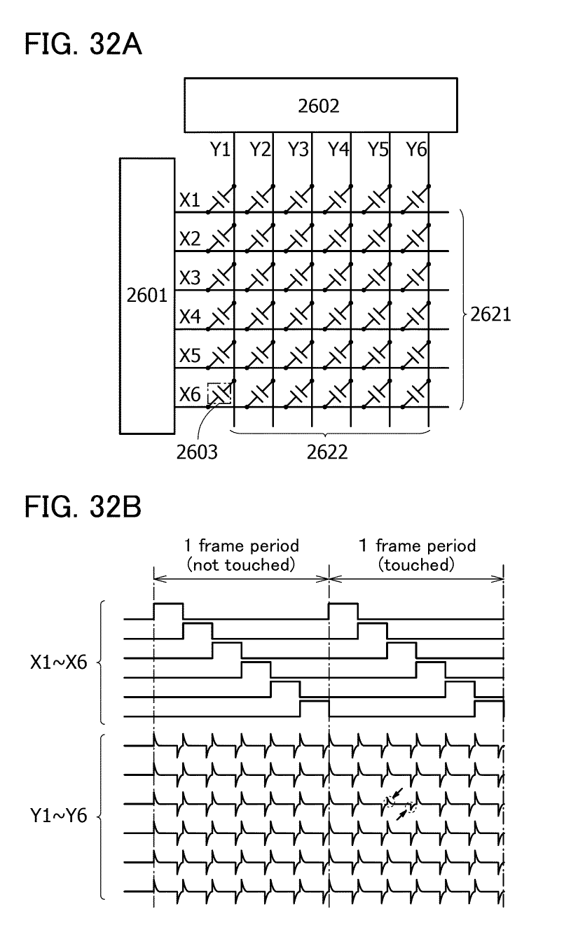

Next, an example of a method for driving a touch panel will be described with reference to FIGS. 32A and 32B.

FIG. 32A is a block diagram illustrating the structure of a mutual capacitive touch sensor. FIG. 32A illustrates a pulse voltage output circuit 2601 and a current sensing circuit 2602. Note that in FIG. 32A, six wirings X1 to X6 represent the electrodes 2621 to which a pulse voltage is applied, and six wirings Y1 to Y6 represent the electrodes 2622 that detect changes in current. FIG. 32A also illustrates capacitors 2603 that are each formed in a region where the electrodes 2621 and 2622 overlap with each other. Note that functional replacement between the electrodes 2621 and 2622 is possible.

The pulse voltage output circuit 2601 is a circuit for sequentially applying a pulse voltage to the wirings X1 to X6. By application of a pulse voltage to the wirings X1 to X6, an electric field is generated between the electrodes 2621 and 2622 of the capacitor 2603. When the electric field between the electrodes is shielded, for example, a change occurs in the capacitor 2603 (mutual capacitance). The approach or contact of a sensing target can be sensed by utilizing this change.

The current sensing circuit 2602 is a circuit for detecting changes in current flowing through the wirings Y1 to Y6 that are caused by the change in mutual capacitance in the capacitor 2603. No change in current value is detected in the wirings Y1 to Y6 when there is no approach or contact of a sensing target, whereas a decrease in current value is detected when mutual capacitance is decreased owing to the approach or contact of a sensing target. Note that an integrator circuit or the like is used for sensing of current values.

FIG. 32B is a timing chart showing input and output waveforms in the mutual capacitive touch sensor illustrated in FIG. 32A. In FIG. 32B, sensing of a sensing target is performed in all the rows and columns in one frame period. FIG. 32B shows a period when a sensing target is not sensed (not touched) and a period when a sensing target is sensed (touched). Sensed current values of the wirings Y1 to Y6 are shown as the waveforms of voltage values.

A pulse voltage is sequentially applied to the wirings X1 to X6, and the waveforms of the wirings Y1 to Y6 change in accordance with the pulse voltage. When there is no approach or contact of a sensing target, the waveforms of the wirings Y1 to Y6 change in accordance with changes in the voltages of the wirings X1 to X6. The current value is decreased at the point of approach or contact of a sensing target and accordingly the waveform of the voltage value changes.

By detecting a change in mutual capacitance in this manner, the approach or contact of a sensing target can be sensed.

### <Sensor Circuit>

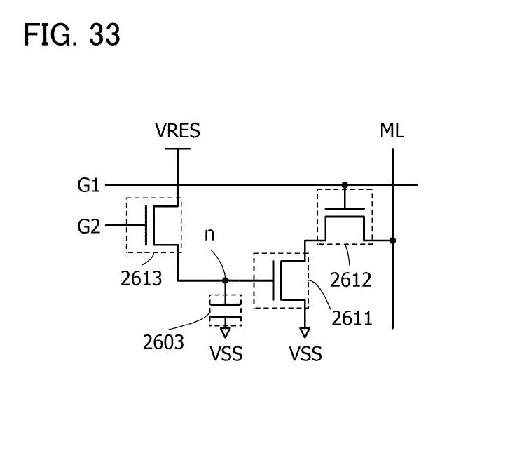

Although FIG. 32A illustrates a passive matrix type touch sensor in which only the capacitor 2603 is provided at the intersection of wirings as a touch sensor, an active matrix type touch sensor including a transistor and a capacitor may be used. FIG. 33 illustrates an example of a sensor circuit included in an active matrix type touch sensor.

The sensor circuit in FIG. 33 includes the capacitor 2603 and transistors 2611, 2612, and 2613.

A signal G2 is input to a gate of the transistor 2613. A voltage VRES is applied to one of a source and a drain of the transistor 2613, and one electrode of the capacitor 2603 and a gate of the transistor 2611 are electrically connected to the other of the source and the drain of the transistor 2613. One of a source and a drain of the transistor 2611 is electrically connected to one of a source and a drain of the transistor 2612, and a voltage VSS is applied to the other of the source and the drain of the transistor 2611. A signal G1 is input to a gate of the transistor 2612, and a wiring ML is electrically connected to the other of the source and the drain of the transistor 2612. The voltage VSS is applied to the other electrode of the capacitor 2603.

Next, the operation of the sensor circuit in FIG. 33 will be described. First, a potential for turning on the transistor 2613 is supplied as the signal G2, and a potential with respect to the voltage VRES is thus applied to the node n connected to the gate of the transistor 2611. Then, a potential for turning off the transistor 2613 is applied as the signal G2, whereby the potential of the node n is maintained.

Then, mutual capacitance of the capacitor 2603 changes owing to the approach or contact of a sensing target such as a finger, and accordingly the potential of the node n is changed from VRES.

In reading operation, a potential for turning on the transistor 2612 is supplied as the signal G1. A current flowing through the transistor 2611, that is, a current flowing through the wiring ML is changed in accordance with the potential of the node n. By sensing this current, the approach or contact of a sensing target can be sensed.

In each of the transistors 2611, 2612, and 2613, any of the transistors described in the above embodiments can be used. In particular, it is preferable to use any of the transistors described in the above embodiments as the transistor 2613 because the potential of the node n can be held for a long time and the frequency of operation of resupplying VRES to the node n (refresh operation) can be reduced.

The structures described in this embodiment can be used in appropriate combination with any of the structures described in the other embodiments.

### Embodiment 5

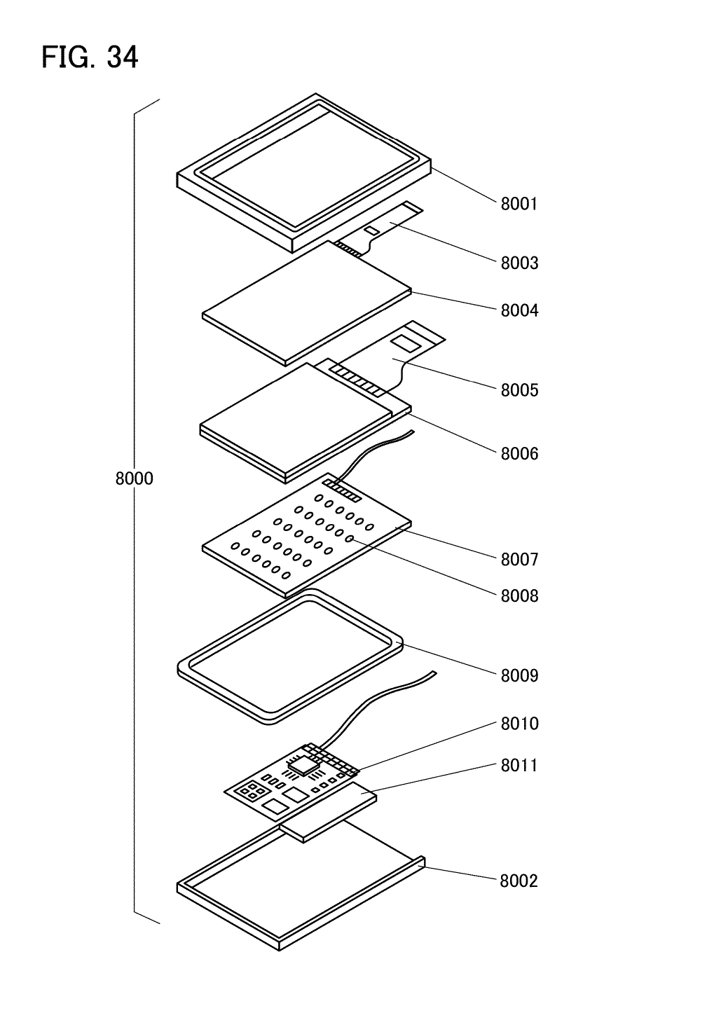

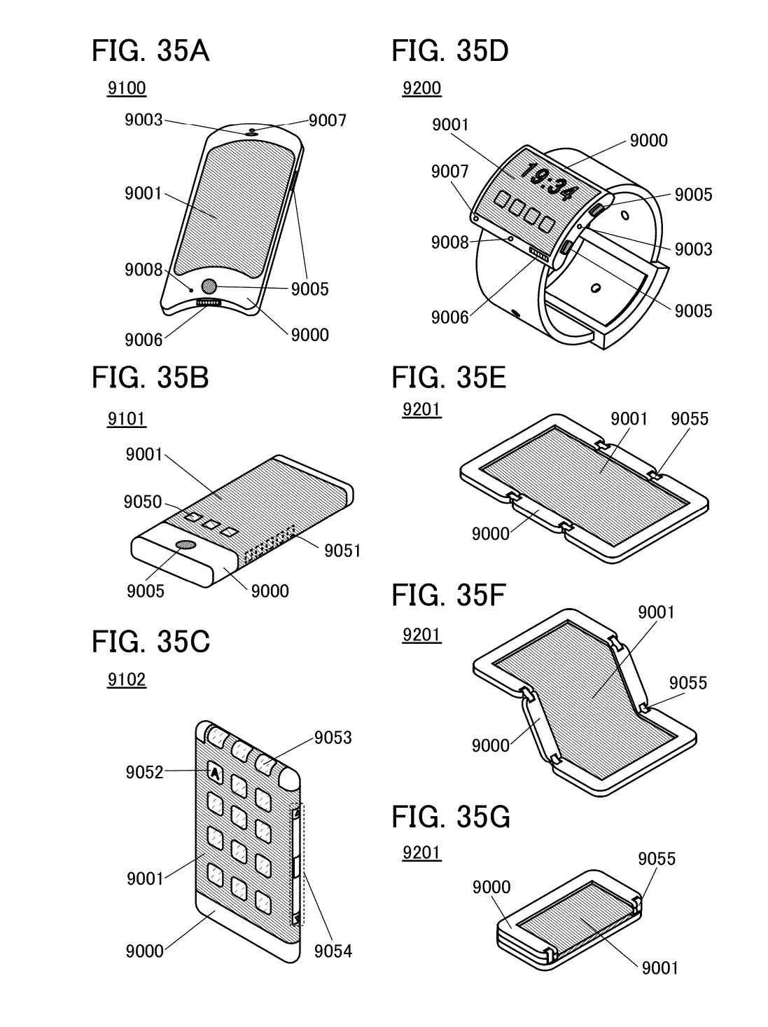

In this embodiment, a display module and electronic devices that include a semiconductor device of one embodiment of the present invention are described with reference to FIG. 34 and FIGS. 35A to 35G.

### <Display Module>

In a display module 8000 illustrated in FIG. 34, a touch sensor 8004 connected to an FPC 8003, a display panel 8006 connected to an FPC 8005, a backlight 8007, a frame 8009, a printed board 8010, and a battery 8011 are provided between an upper cover 8001 and a lower cover 8002.

The semiconductor device of one embodiment of the present invention can be used for, for example, the display panel 8006.

The shapes and sizes of the upper cover 8001 and the lower cover 8002 can be changed as appropriate in accordance with the sizes of the touch sensor 8004 and the display panel 8006.

The touch sensor 8004 can be a resistive touch sensor or a capacitive touch sensor and can be formed to overlap the display panel 8006. A counter substrate (sealing substrate) of the display panel 8006 can have a touch sensor function. A photosensor may be provided in each pixel of the display panel 8006 to form an optical touch sensor.

The backlight 8007 includes light sources 8008. Note that although a structure in which the light sources 8008 are provided over the backlight 8007 is illustrated in FIG. 34, one embodiment of the present invention is not limited to this structure. For example, a structure in which the light sources 8008 are provided at an end portion of the backlight 8007 and a light diffusion plate is further provided may be employed. Note that the backlight 8007 need not be provided in the case where a self-luminous light-emitting element such as an organic EL element is used or in the case where a reflective panel or the like is employed.

The frame 8009 protects the display panel 8006 and also functions as an electromagnetic shield for blocking electromagnetic waves generated by the operation of the printed board 8010. The frame 8009 may function as a radiator plate.

The printed board 8010 is provided with a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 may be additionally provided with a member such as a polarizing plate, a retardation plate, or a prism sheet.

### <Electronic Device>

FIGS. 35A to 35G illustrate electronic devices. These electronic devices can each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays), a microphone 9008, and the like.

The electronic devices illustrated in FIGS. 35A to 35G can have a variety of functions, for example, a function of displaying a variety of information (a still image, a moving image, a text image, and the like) on the display portion, a touch panel function, a function of displaying a calendar, the date, the time, and the like, a function of controlling processing with a variety of software (programs), a wireless communication function, a function of being connected to a variety of computer networks with a wireless communication function, a function of transmitting and receiving a variety of data with a wireless communication function, a function of reading a program or data stored in a storage medium and displaying the program or data on the display portion, and the like. Note that functions of the electronic devices illustrated in FIGS. 35A to 35G are not limited thereto, and the electronic devices can have a variety of functions. Although not illustrated in FIGS. 35A to 35G, the electronic devices may each have a plurality of display portions. The electronic devices may each have a camera or the like and a function of taking a still image, a function of taking a moving image, a function of storing the taken image in a storage medium (an external storage medium or a storage medium incorporated in the camera), a function of displaying the taken image on the display portion, and the like. Although not illustrated in FIGS. 35A to 35G, the electronic devices may be provided with an antenna or the like to have a wireless communication function.

The electronic devices illustrated in FIGS. 35A to 35G will be described in detail below.

FIG. 35A is a perspective view of a portable information terminal 9100. The display portion 9001 of the portable information terminal 9100 is flexible and thus can be incorporated along the curved surface of the housing 9000. Furthermore, the display portion 9001 includes a touch sensor, and operation can be performed by touching a screen with a finger, a stylus, or the like. For example, by touching an icon displayed on the display portion 9001, an application can be started.

FIG. 35B is a perspective view of a portable information terminal 9101. The portable information terminal 9101 functions as, for example, one or more of a telephone set, a notebook, an information browsing system, and the like. Specifically, the portable information terminal 9101 can be used as a smartphone. Note that the speaker 9003, the connection terminal 9006, the sensor 9007, and the like, which are not illustrated in FIG. 35B, can be positioned in the portable information terminal 9101 as in the portable information terminal 9100 illustrated in FIG. 35A. The portable information terminal 9101 can display characters and image information on its plurality of surfaces. For example, three operation buttons 9050 (also referred to as operation icons, or simply, icons) can be displayed on one surface of the display portion 9001. Furthermore, information 9051 indicated by dashed rectangles can be displayed on another surface of the display portion 9001. Examples of the information 9051 include notification from a social networking service (SNS), display indicating reception of an e-mail or an incoming call, the title of the e-mail, the SNS, or the like, the sender of the e-mail, the SNS, or the like, the date, the time, remaining battery, and the strength of a received signal. Instead of the information 9051, the operation buttons 9050 or the like may be displayed in the position where the information 9051 is displayed.

FIG. 35C is a perspective view of a portable information terminal 9102. The portable information terminal 9102 has a function of displaying information on three or more surfaces of the display portion 9001. Here, information 9052, information 9053, and information 9054 are displayed on different surfaces. For example, a user of the portable information terminal 9102 can see the display (here, the information 9053) with the portable information terminal 9102 put in a breast pocket of his/her clothes. Specifically, a caller's phone number, name, or the like of an incoming call is displayed in the position that can be seen from above the portable information terminal 9102. Thus, the user can see the display without taking out the portable information terminal 9102 from the pocket and decide whether to answer the call.

FIG. 35D is a perspective view of a watch-type portable information terminal 9200. The portable information terminal 9200 is capable of executing a variety of applications such as mobile phone calls, e-mailing, viewing and editing texts, music reproduction, Internet communication, and computer games. The display surface of the display portion 9001 is curved, and images can be displayed on the curved display surface. The portable information terminal 9200 can employ near field communication conformable to a communication standard. For example, hands-free calling can be achieved with mutual communication between the portable information terminal 9200 and a headset capable of wireless communication. Moreover, the portable information terminal 9200 includes the connection terminal 9006, and data can be directly transmitted to and received from another information terminal via a connector. Charging through the connection terminal 9006 is also possible. Note that the charging operation may be performed by wireless power feeding without using the connection terminal 9006.

FIGS. 35E, 35F, and 35G are perspective views of a foldable portable information terminal 9201 that is opened, that is shifted from the opened state to the folded state or from the folded state to the opened state, and that is folded, respectively. The portable information terminal 9201 is highly portable when folded. When the portable information terminal 9201 is opened, a seamless large display region provides high browsability. The display portion 9001 of the portable information terminal 9201 is supported by three housings 9000 joined together by hinges 9055. By folding the portable information terminal 9201 at a connection portion between two housings 9000 with the hinges 9055, the portable information terminal 9201 can be reversibly changed in shape from the opened state to the folded state. For example, the portable information terminal 9201 can be bent with a radius of curvature of greater than or equal to 1 mm and less than or equal to 150 mm.

The electronic devices described in this embodiment each include the display portion for displaying some kinds of information. However, a semiconductor device according to one embodiment of the present invention can also be used for an electronic device that does not include a display portion. Furthermore, the display portions of the electronic devices described in this embodiment may also be non-flexible and can display images on a flat surface without limitation to a flexible mode capable of displaying images on a curved display surface or a foldable mode.

The structures described in this embodiment can be used in appropriate combination with any of the structures described in the other embodiments.

### Embodiment 6

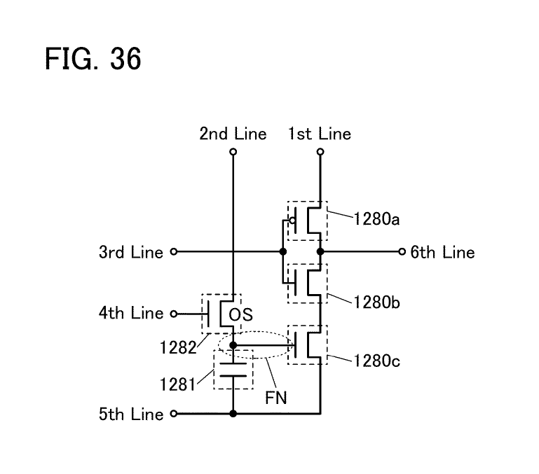

In this embodiment, an example of a circuit configuration of a semiconductor device, which can hold stored data even when not powered, and which does not have a limitation on the number of write cycles, will be described with reference to FIG. 36.

### <Circuit Configuration>

FIG. 36 shows an example of a circuit configuration of a semiconductor device. In FIG. 36, a first wiring (1st Line) is electrically connected to one of a source electrode and a drain electrode of a p-channel transistor 1280a. Further, the other of the source electrode and the drain electrode of the p-channel transistor 1280a is electrically connected to one of a source electrode and a drain electrode of an n-channel transistor 1280b. Further, the other of the source electrode and the drain electrode of the n-channel transistor 1280b is electrically connected to one of a source electrode and a drain electrode of an n-channel transistor 1280c.

A second wiring (2nd Line) is electrically connected to one of a source electrode and a drain electrode of a transistor 1282. Further, the other of the source electrode and the drain electrode of the transistor 1282, one electrode of a capacitor 1281, and a gate electrode of the n-channel transistor 1280c are electrically connected to each other.

A third wiring (3rd Line) and gate electrodes of the p-channel transistor 1280a and the n-channel transistor 1280b are electrically connected to each other. Further, a fourth wiring (4th Line) is electrically connected to a gate electrode of the transistor 1282. Further, a fifth wiring (5th Line), the other electrode of the capacitor 1281, and the other of the source electrode and the drain electrode of the n-channel transistor 1280c are electrically connected to each other. Further, a sixth wiring (6th Line), the other of the source electrode and the drain electrode of the p-channel transistor 1280a, and one of the source electrode and the drain electrode of the n-channel transistor 1280b are electrically connected to each other.

Note that the transistor 1282 can be formed using an oxide semiconductor (OS). Therefore, in FIG. 36, “OS” is written beside the transistor 1282. Note that the transistor 1282 may be formed using a material other than an oxide semiconductor.

Further, in FIG. 36, a floating node (FN) is written at a connection portion of the other of the source electrode and the drain electrode of the transistor 1282, the one electrode of the capacitor 1281, and the gate electrode of the n-channel transistor 1280c. When the transistor 1282 is turned off, potentials supplied to the floating node, the one electrode of the capacitor 1281, and the gate electrode of the n-channel transistor 1280c can be held.

The circuit configuration in FIG. 36 utilizes the advantage that the potential of the gate electrode of the n-channel transistor 1280c can be held, whereby writing, holding, and reading of data can be performed as described below.

### <Writing and Holding of Data>

First, writing and holding of data will be described. The potential of the fourth wiring is set to a potential at which the transistor 1282 is turned on, so that the transistor 1282 is turned on. Accordingly, the potential of the second wiring is supplied to the gate electrode of the n-channel transistor 1280c and the capacitor 1281. That is, predetermined charge is supplied to the gate electrode of the n-channel transistor 1280c (writing). After that, the potential of the fourth wiring is set to a potential at which the transistor 1282 is turned off, and the transistor 1282 is turned off. Accordingly, charge applied to the gate electrode of the n-channel transistor 1280c is held (holding).

Since the off-state current of the transistor 1282 is significantly small, the charge in the gate electrode of the n-channel transistor 1280c is held for a long time.

### <Reading of Data>

Next, reading of data is described. When the potential of the third wiring is a Low-level potential, the p-channel transistor 1280a is turned on and the n-channel transistor 1280b is turned off. At this time, the potential of the first wiring is applied to the sixth wiring. On the other hand, when the potential of the third wiring is a High-level potential, the p-channel transistor 1280a is turned off and the n-channel transistor 1280b is turned on. At this time, the potential of the sixth wiring varies in response to the amount of charge held in the floating node (FN). Therefore, the retained data can be read by measuring the potential of the sixth wiring (reading).

The transistor 1282 in which a channel formation region is formed using an oxide semiconductor has a significantly low off-state current. The off-state current of the transistor 1282 using an oxide semiconductor is lower than or equal to one hundred-thousandth of that of the off-state current of a transistor formed using a silicon semiconductor or the like; thus, loss of the electrical charge accumulated in the floating node (FN) due to leakage of the transistor 1282 is as small as negligible. That is, the transistor 1282 formed using an oxide semiconductor makes it possible to obtain a nonvolatile memory circuit which can hold data even without being supplied with power.

By applying the semiconductor device including the above-described circuit configuration to a memory device such as a register or a cache memory, data in the memory device can be prevented from being erased owing to the stop of the supply of the power supply voltage. In addition, after the supply of the power supply voltage is resumed, the storage element can return to the state same as that before the power supply voltage is stopped in a short time. Therefore, the power supply can be stopped even for a short time when the whole memory device or one or a plurality of logic circuits included in the memory device is in a standby state. Accordingly, power consumption can be suppressed.

The structures and methods described in this embodiment can be combined as appropriate with any of the structures and methods described in the other embodiments.

### Embodiment 7

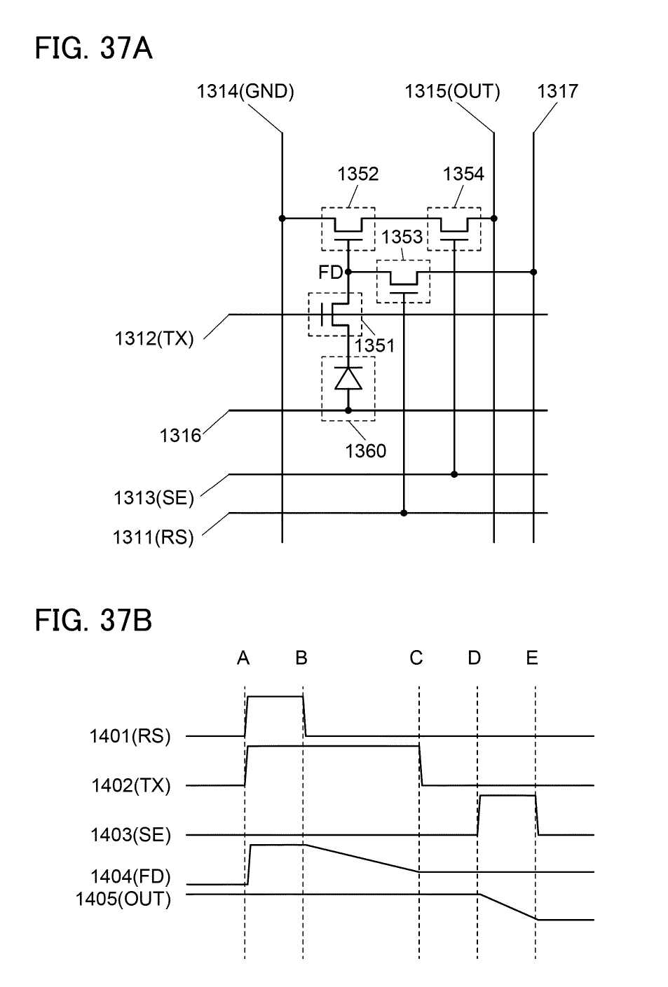

In this embodiment, a configuration of a pixel circuit capable of being used in a semiconductor device of one embodiment of the present invention will be described below with reference to FIG. 37A.

### <Configuration of Pixel Circuit>

FIG. 37A illustrates a configuration of the pixel circuit. The circuit in FIG. 37A includes a photoelectric conversion element 1360, a transistor 1351, a transistor 1352, a transistor 1353, and a transistor 1354.

An anode of the photoelectric conversion element 1360 is connected to a wiring 1316, and a cathode of the photoelectric conversion element 1360 is connected to one of a source electrode and a drain electrode of the transistor 1351. The other of the source electrode and the drain electrode of the transistor 1351 is connected to a charge accumulation portion (FD), and a gate electrode of the transistor 1351 is connected to a wiring 1312 (TX). One of a source electrode and a drain electrode of the transistor 1352 is connected to a wiring 1314 (GND), and the other of the source electrode and the drain electrode of the transistor 1352 is connected to one of a source electrode and a drain electrode of the transistor 1354. A gate electrode of the transistor 1352 is connected to the charge accumulation portion (FD). One of a source electrode and a drain electrode of the transistor 1353 is connected to the charge accumulation portion (FD), and the other of the source electrode and the drain electrode of the transistor 1353 is connected to a wiring 1317. A gate electrode of the transistor 1353 is connected to a wiring 1311 (RS). The other of the source electrode and the drain electrode of the transistor 1354 is connected to a wiring 1315 (OUT), and a gate electrode of the transistor 1354 is connected to a wiring 1313 (SE). Note that all the connection is electrical connection.

A potential such as GND, VSS, or VDD may be applied to the wiring 1314. Here, a potential or voltage has a relative value. Therefore, the potential GND is not necessarily 0 V.

The photoelectric conversion element 1360 is a light-receiving element and has a function of generating current based on the amount of light that enters the pixel circuit. The transistor 1353 has a function of controlling accumulation of charge in the charge accumulation portion (FD) by the photoelectric conversion element 1360. The transistor 1354 has a function of outputting a signal based on the potential of the charge accumulation portion (FD). The transistor 1352 has a function of resetting the potential of the charge accumulation portion (FD). The transistor 1352 has a function of controlling selection of the pixel circuit at the time of reading.

Note that the charge accumulation portion (FD) is a charge retention node and retains charge that is changed depending on the amount of light received by the photoelectric conversion element 1360.

Note that the transistors 1352 and 1354 only need to be connected in series between the wirings 1314 and 1315. Thus, the wiring 1314, the transistor 1352, the transistor 1354, and the wiring 1315 may be arranged in that order, or the wiring 1314, the transistor 1354, the transistor 1352, and the wiring 1315 may be arranged in that order.

The wiring 1311 (RS) functions as a signal line for controlling the transistor 1353. The wiring 1312 (TX) functions as a signal line for controlling the transistor 1351. The wiring 1313 (SE) functions as a signal line for controlling the transistor 1354. The wiring 1314 (GND) functions as a signal line for supplying a reference potential (e.g., GND). The wiring 1315 (OUT) functions as a signal line for reading a signal output from the transistor 1352. The wiring 1316 functions as a signal line for outputting charge from the charge accumulation portion (FD) through the photoelectric conversion element 1360 and is a low-potential line in the circuit in FIG. 37A. The wiring 1317 functions as a signal line for resetting the potential of the charge accumulation portion (FD) and is a high-potential line in the circuit in FIG. 37A.

Next, a structure of each component illustrated in FIG. 37A will be described.

### <Photoelectric Conversion Element>

An element including selenium or a selenium-containing compound (hereinafter referred to as a selenium-based material) or an element including silicon (e.g., an element in which a pin junction is formed) can be used as the photoelectric conversion element 1360. The photoelectric conversion element including the selenium-based material is preferably used in combination with a transistor including an oxide semiconductor, in which case high reliability can be achieved.

### <Transistor>

Although a silicon semiconductor such as amorphous silicon, microcrystalline silicon, polycrystalline silicon, or single crystal silicon can be used to form the transistors 1351 to 1354, the transistors 1351 to 1354 are preferably OS transistors. A transistor in which a channel formation region is formed using an oxide semiconductor has extremely low off-state current. The transistor described in Embodiment 1, for example, can be used as the transistor in which the channel formation region is formed of an oxide semiconductor.

In particular, when the transistors 1351 and 1353 connected to the charge accumulation portion (FD) has high leakage current, charge accumulated in the charge accumulation portion (FD) cannot be held for a sufficiently long time. The use of OS transistors as the transistors 1351 and 1353 can prevent unwanted output of charge from the charge accumulation portion (FD).

Unwanted output of charge also occurs in the wiring 1314 or 1315 when the transistors 1352 and 1354 have high leakage current; thus, a transistor in which a channel formation region is formed using an oxide semiconductor is preferably used as each of these transistors.

The transistor shown in FIG. 37A includes one gate electrode. However, the transistor is not limited thereto and may include a plurality of gate electrodes, for example. The transistor including a plurality of gate electrodes is, for example, a transistor including a first gate electrode and a second gate electrode (also referred to as a back-gate electrode) which overlap with a semiconductor film in which a channel formation region is formed. The back-gate electrode may be supplied with a potential which is the same as that supplied to the first gate electrode, a floating potential, or a potential which is different from that supplied to the first gate electrode.

### <Timing Chart of Circuit Operation>

An example of an operation circuit of the circuit shown in FIG. 37A will be described with reference to a timing chart in FIG. 37B.

In FIG. 37B, the potential of each wiring is a signal that varies between two levels for simplicity. Since each potential is an analog signal, the potential can, in practice, have various levels depending on conditions without being limited to two levels. In FIG. 37B, a signal 1401 corresponds to the potential of the wiring 1311 (RS); a signal 1402 corresponds to the potential of the wiring 1312 (TX); a signal 1403 corresponds to the potential of the wiring 1313 (SE); a signal 1404 corresponds to the potential of the charge accumulation portion (FD); and a signal 1405 corresponds to the potential of the wiring 1315 (OUT). Note that the potential of the wiring 1316 is always at a low level, and the potential of the wiring 1317 is always at a high level.

At time A, the potential (signal 1401) of the wiring 1311 is at a high level and the potential (signal 1402) of the wiring 1312 is at a high level, so that the potential (signal 1404) of the charge accumulation portion (FD) is initialized to the potential (high level) of the wiring 1317, and reset operation is started. Note that the potential (signal 1405) of the wiring 1315 is precharged to a high level.

At time B, the potential (signal 1401) of the wiring 1311 is set at a low level, so that the reset operation is terminated to start accumulation operation. Here, a reverse bias is applied to the photoelectric conversion element 1360, so that the potential (signal 1404) of the charge accumulation portion (FD) starts to decrease due to reverse current. Since irradiation of the photoelectric conversion element 1360 with light increases the reverse current, the rate of decrease in the potential (signal 1404) of the charge accumulation portion (FD) changes depending on the amount of the light irradiation. In other words, channel resistance between the source electrode and the drain electrode of the transistor 1354 changes depending on the amount of light delivered to the photoelectric conversion element 1360.

At time C, the potential (signal 1402) of the wiring 1312 is set to a low level to terminate the accumulation operation, so that the potential (signal 1404) of the charge accumulation portion (FD) becomes constant. Here, the potential is determined by the amount of charge generated by the photoelectric conversion element 1360 during the accumulation operation. That is, the potential changes depending on the amount of light delivered to the photoelectric conversion element 1360. Furthermore, since each of the transistors 1351 and 1353 is a transistor that includes a channel formation region formed using an oxide semiconductor and has extremely low off-state current, the potential of the charge accumulation portion (FD) can be kept constant until subsequent selection operation (read operation) is performed.

Note that when the potential (signal 1402) of the wiring 1312 is set at a low level, the potential of the charge accumulation portion (FD) might change owing to parasitic capacitance between the wiring 1312 and the charge accumulation portion (FD). In the case where the amount of change in the potential is large, the amount of charge generated by the photoelectric conversion element 1360 during the accumulation operation cannot be obtained accurately. Examples of effective measures to reduce the amount of change in the potential include reducing capacitance between the gate electrode and the source electrode (or between the gate electrode and the drain electrode) of the transistor 1351, increasing the gate capacitance of the transistor 1352, and providing a storage capacitor in the charge accumulation portion (FD). Note that in this embodiment, the change in the potential can be ignored by taking these measures.

At time D, the potential (signal 1403) of the wiring 1313 is set at a high level to turn on the transistor 1354, so that selection operation starts and the wirings 1314 and 1315 are electrically connected to each other through the transistors 1352 and 1354. The potential (signal 1405) of the wiring 1315 starts to decrease. Note that precharge of the wiring 1315 is terminated before the time D. Here, the rate at which the potential (signal 1405) of the wiring 1315 decreases depends on current between the source electrode and the drain electrode of the transistor 1352. That is, the potential (signal 1405) of the wiring 1315 changes depending on the amount of light delivered to the photoelectric conversion element 1360 during the accumulation operation.

At time E, the potential (signal 1403) of the wiring 1313 is set at a low level to turn off the transistor 1354, so that the selection operation is terminated and the potential (signal 1405) of the wiring 1315 becomes a constant value. Here, the constant value changes depending on the amount of light delivered to the photoelectric conversion element 1360. Therefore, the amount of light delivered to the photoelectric conversion element 1360 during the accumulation operation can be determined by measuring the potential of the wiring 1315.

Specifically, when the photoelectric conversion element 1360 is irradiated with light with high intensity, the potential of the charge accumulation portion (FD), that is, the gate voltage of the transistor 1352 is decreased. Therefore, current flowing between the source electrode and the drain electrode of the transistor 1352 becomes small; as a result, the potential (signal 1405) of the wiring 1315 is gradually decreased. Thus, a comparatively high potential can be read from the wiring 1315.

In contrast, when the photoelectric conversion element 1360 is irradiated with light with low intensity, the potential of the charge accumulation portion (FD), that is, the gate voltage of the transistor 1352 is increased. Therefore, the current flowing between the source electrode and the drain electrode of the transistor 1352 becomes large; as a result, the potential (signal 1405) of the wiring 1315 is rapidly decreased. Thus, a comparatively low potential can be read from the wiring 1315.

This embodiment can be implemented in an appropriate combination with any of the structures described in the other embodiments.

### Embodiment 8

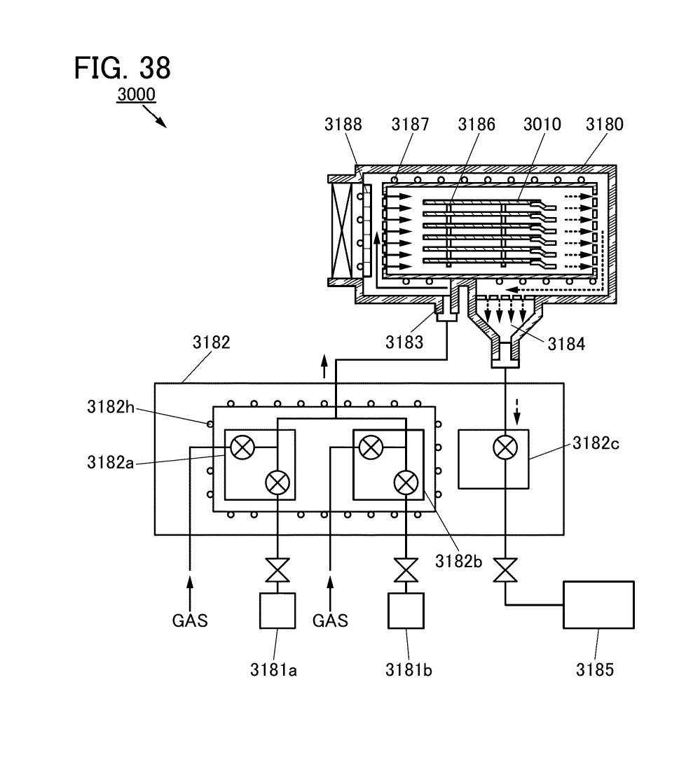

In this embodiment, a deposition apparatus which can be used for manufacture of a display module of one embodiment of the present invention will be described with reference to FIG. 38.

FIG. 38 illustrates a deposition apparatus 3000 which can be used for manufacture of a display module of one embodiment of the present invention. Note that the deposition apparatus 3000 is an example of a batch-type ALD apparatus.

### <Structural Example of Deposition Apparatus>

The deposition apparatus 3000 described in this embodiment includes a deposition chamber 3180 and a control portion 3182 connected to the deposition chamber 3180 (see FIG. 38).

The control portion 3182 includes a control unit (not illustrated) which supplies control signals and flow rate controllers 3182a, 3182b, and 3182c to which the control signals are supplied. For example, high-speed valves can be used as the flow rate controllers. Specifically, flow rates can be precisely controlled by using ALD valves or the like. The control portion 3182 also includes a heating mechanism 3182h which controls the temperatures of the flow rate controllers and pipes.

The flow rate controller 3182a is supplied with a control signal, a first source material, and an inert gas and has a function of supplying the first source material or the inert gas in accordance with the control signal.

The flow rate controller 3182b is supplied with a control signal, a second source material, and an inert gas and has a function of supplying the second source material or the inert gas in accordance with the control signal.

The flow rate controller 3182c is supplied with a control signal and has a function of connecting to an evacuation unit 3185 in accordance with the control signal.

### <Source Material Supply Portion>

A source material supply portion 3181a has a function of supplying the first source material and is connected to the flow rate controller 3182a.

A source material supply portion 3181b has a function of supplying the second source material and is connected to the flow rate controller 3182b.

A vaporizer, a heating unit, or the like can be used as each of the source material supply portions. Thus, a gaseous source material can be generated from a solid or liquid source material.

Note that the number of source material supply portions is not limited to two and may be three or more.

### <Source Material>

Any of a variety of substances can be used as the first source material. For example, a volatile organometallic compound, a volatile metal alkoxide, or the like can be used as the first source material. Any of a variety of substances which react with the first source material can be used as the second source material. For example, a substance which contributes to an oxidation reaction, a substance which contributes to a reduction reaction, a substance which contributes to an addition reaction, a substance which contributes to a decomposition reaction, a substance which contributes to a hydrolysis reaction, or the like can be used as the second source material.

Furthermore, a radical or the like can be used. For example, plasma obtained by supplying a source material to a plasma source or the like can be used. Specifically, an oxygen radical, a nitrogen radical, or the like can be used.

The second source material which is used in combination with the first source material is preferably a source material which reacts with the first source material at a temperature close to room temperature. For example, a source material which reacts at a temperature higher than or equal to room temperature and lower than or equal to 200° C., preferably higher than or equal to 50° C. and lower than or equal to 150° C., is preferable.

### <Evacuation Unit>

The evacuation unit 3185 has an evacuating function and is connected to the flow rate controller 3182c. Note that a trap for capturing the source material to be evacuated may be provided between an outlet port 3184 and the flow rate controller 3182c. The evacuated gas or the like is removed by using a removal unit.

### <Control Portion>

The control portion 3182 supplies the control signals for controlling the flow rate controllers, a control signal for controlling the heating mechanism, or the like. For example, in a first step, the first source material is supplied to a surface of a process base. Then, in a second step, the second source material which reacts with the first source material is supplied. Accordingly, a reaction product of the first source material and the second source material can be deposited onto a surface of a process member 3010.

Note that the amount of the reaction product to be deposited onto the surface of the process member 3010 can be controlled by a repetition of the first step and the second step.

Note that the amount of the first source material to be supplied to the process member 3010 is limited by the maximum possible amount of adsorption on the surface of the process member 3010. For example, conditions are selected so that a monomolecular layer of the first source material is formed on the surface of the process member 3010, and the formed monomolecular layer of the first source material is reacted with the second source material, whereby a significantly uniform layer containing the reaction product of the first source material and the second source material can be formed.

Accordingly, a variety of materials can be deposited on a surface of the process member 3010 even when the surface has a complicated structure. For example, a film having a thickness greater than or equal to 3 nm and less than or equal to 200 nm can be formed on the process member 3010.

In the case where, for example, a small hole called a pinhole or the like is formed in the surface of the process member 3010, the pinhole can be filled by depositing a material into the pinhole.

The remainder of the first source material or the second source material is evacuated from the deposition chamber 3180 with use of the evacuation unit 3185. For example, the evacuation may be performed while an inert gas such as argon or nitrogen is introduced.

### <Deposition Chamber>

The deposition chamber 3180 includes an inlet port 3183 from which the first source material, the second source material, and the inert gas are supplied and the outlet port 3184 from which the first source material, the second source material, and the inert gas are evacuated.

The deposition chamber 3180 includes a support portion 3186 which has a function of supporting one or a plurality of process members 3010, a heating mechanism 3187 which has a function of heating the one or plurality of process members, and a door 3188 which has a function of opening or closing to load and unload the one or plurality of process members 3010.

For example, a resistive heater, an infrared lamp, or the like can be used as the heating mechanism 3187. The heating mechanism 3187 has a function of heating up, for example, to 80° C. or higher, 100° C. or higher, or 150° C. or higher. The heating mechanism 3187 heats the one or plurality of process members 3010 to a temperature higher than or equal to room temperature and lower than or equal to 200° C., preferably higher than or equal to 50° C. and lower than or equal to 150° C.

The deposition chamber 3180 may also include a pressure regulator and a pressure detector.

### <Support Portion>

The support portion 3186 supports the one or plurality of process members 3010. Accordingly, an insulating film, for example, can be formed over the one or plurality of process members 3010 in each treatment.

### <Example of Film>

Films which can be formed using the deposition apparatus 3000 described in this embodiment will be described.

For example, a film containing an oxide, a nitride, a fluoride, a sulfide, a ternary compound, a metal, or a polymer can be formed.

For example, a material containing aluminum oxide, hafnium oxide, aluminum silicate, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like can be deposited.

For example, a material containing aluminum nitride, hafnium nitride, silicon nitride, tantalum nitride, titanium nitride, niobium nitride, molybdenum nitride, zirconium nitride, gallium nitride, or the like can be deposited.

For example, a material containing copper, platinum, ruthenium, tungsten, iridium, palladium, iron, cobalt, nickel, or the like can be deposited.

For example, a material containing zinc sulfide, strontium sulfide, calcium sulfide, lead sulfide, calcium fluoride, strontium fluoride, zinc fluoride, or the like can be deposited.

For example, a material that includes a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like can be deposited.

This embodiment can be combined with any of the other embodiments in this specification as appropriate.

### Example 1

In this example, the crystallinity of oxide semiconductor films was evaluated using XRD analysis and cross-sectional TEM images.

### <1-1. Evaluation by XRD>

Sample A1 and Sample A2 were formed and used for evaluation by XRD analysis.

In Sample A1, a 100-nm-thick IGZO film was formed over a glass substrate with a sputtering apparatus. Note that the IGZO film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a metal oxide sputtering target (having an atomic ratio of In:Ga:Zn=1:1:1.2).

In Sample A2, a 100-nm-thick IGZO film was formed over a glass substrate with a sputtering apparatus. Note that the IGZO film was deposited under the conditions where the substrate temperature was 170° C., an argon gas at a flow rate of 140 sccm and an oxygen gas at a flow rate of 60 sccm were introduced into a chamber, the pressure was 0.6 Pa, and an AC power of 2500 W was applied to a metal oxide sputtering target (having an atomic ratio of In:Ga:Zn=4:2:4.1).

Through the above steps, Sample A1 and Sample A2 were formed.

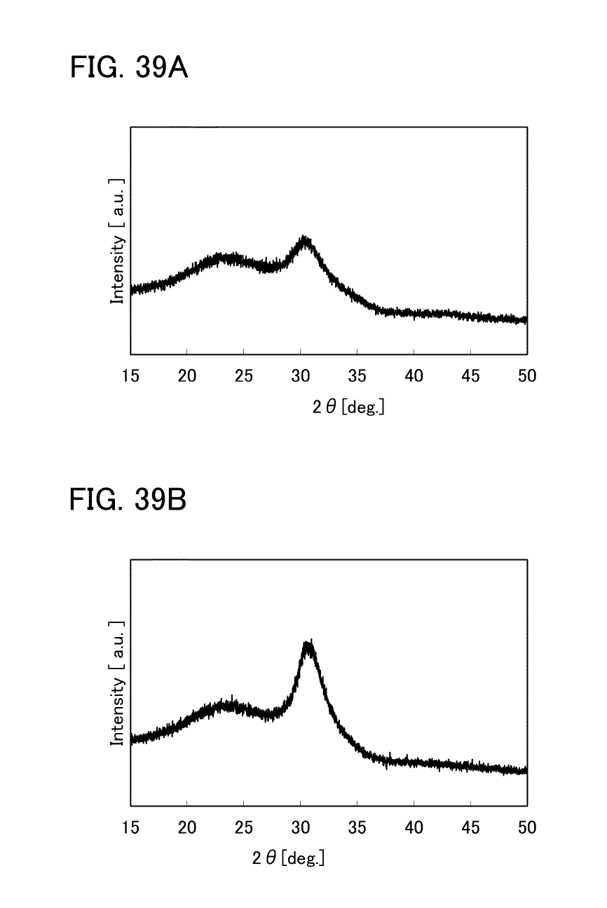

Sample A1 and Sample A2 were evaluated with a multifunction thin film material evaluation X-ray diffractometer, D8 DISCOVER Hybrid manufactured by Bruker AXS. FIGS. 39A and 39B show XRD profiles. Note that the results of analysis by an out-of-plane method are shown in FIGS. 39A and 39B. The result of Sample A1 is shown in FIG. 39A, and the result of Sample A2 is shown in FIG. 39B.

As shown in FIGS. 39A and 39B, a peak was observed at around 2θ=31° in each of Samples Al and A2. This peak is derived from the (009) plane of an InGaZnO₄ crystal, which indicates that crystals in the oxide semiconductor film in each of Sample A1 and Sample A2 have c-axis alignment, and that the c-axes are aligned in a direction substantially perpendicular to a formation surface or the top surface of the oxide semiconductor film. When the peaks at around 2θ=31° are compared with each other, the peak in Sample A2 is narrower and sharper than the peak in Sample A1. Therefore, the crystallinity of Sample A2 is higher than that of Sample A1.

### <1-2. Cross-Sectional TEM Evaluation>

Sample B1 and Sample B2 were formed and used for cross-sectional TEM evaluation.

In Sample B1, a 100-nm-thick IGZO film was formed over a glass substrate with a sputtering apparatus. Note that the IGZO film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a metal oxide sputtering target (having an atomic ratio of In:Ga:Zn=1:1:1.2).

In Sample B2, a 100-nm-thick IGZO film was formed over a glass substrate with a sputtering apparatus. Note that the IGZO film was deposited under the conditions where the substrate temperature was 170° C., an argon gas at a flow rate of 140 sccm and an oxygen gas at a flow rate of 60 sccm were introduced into a chamber, the pressure was 0.6 Pa, and an AC power of 2500 W was applied to a metal oxide sputtering target (having an atomic ratio of In:Ga:Zn=4:2:4.1).

Through the above steps, Samples B1 and Sample B2 were formed.

Next, a TEM image was obtained with a spherical aberration corrector function. Note that a combined analysis image of a bright-field image which is obtained by TEM analysis and a diffraction pattern is referred to as a high-resolution TEM image. Furthermore, a high-resolution TEM image obtained with a spherical aberration corrector function is particularly referred to as a Cs-corrected high-resolution TEM image. The Cs-corrected high-resolution TEM images was obtained using an atomic resolution analytical electron microscope JEM-ARM200F manufactured by JEOL Ltd. The accelerating voltage was 200 kV.

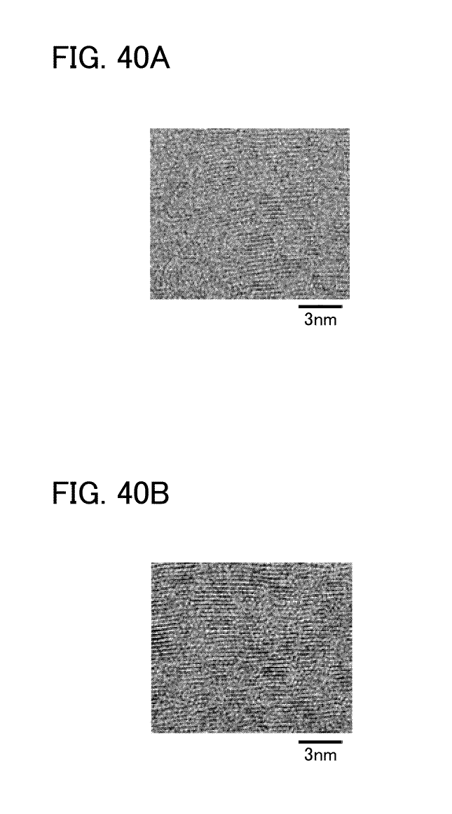

FIG. 40A shows a cross-sectional TEM image of Sample B1. FIG. 40B shows a cross-sectional TEM image of Sample B2.

As shown in FIGS. 40A and 40B, layered atomic arrangement in the c-axis direction was observed. It has been confirmed that there is a stronger c-axis alignment in Sample B2 than in Sample B1.

The structure described in this example can be combined as appropriate with any of the structures described in the embodiments and the other examples.

### Example 2

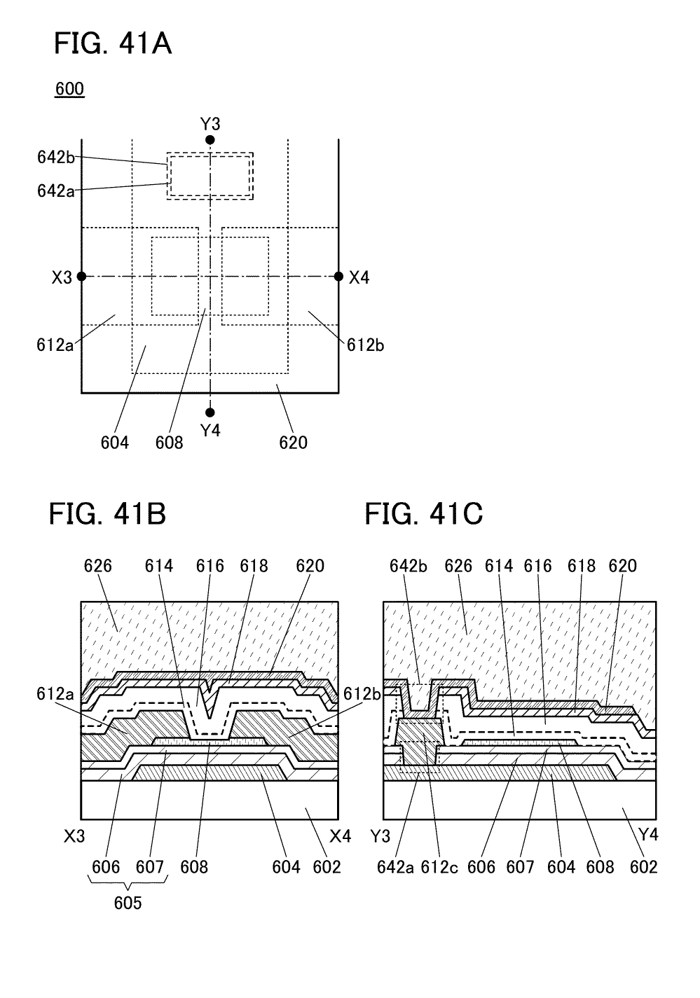

In this example, transistors each corresponding to a transistor 600 in FIGS. 41A to 41C were formed and subjected to evaluation for electrical characteristics and reliability.

### <2-1. Transistor Structure>

First, the transistor 600 in FIGS. 41A to 41C will be described. FIG. 41A is a top view of the transistor 600. FIG. 41B is a cross-sectional view taken along the dashed dotted line X3-X4 in FIG. 41A, and FIG. 41C is a cross-sectional view taken along the dashed dotted line Y3-Y4 in FIG. 41A.

The transistor 600 includes a conductive film 604 functioning as a first gate electrode over a substrate 602, an insulating film 606 over the substrate 602 and the conductive film 604, an insulating film 607 over the insulating film 606, an oxide semiconductor film 608 over the insulating film 607, a conductive film 612a functioning as a source electrode electrically connected to the oxide semiconductor film 608, and a conductive film 612b functioning as a drain electrode electrically connected to the oxide semiconductor film 608.

Over the transistor 600, specifically, over the conductive films 612a and 612b and the oxide semiconductor film 608, insulating films 614, 616, and 618 are provided. A conductive film 620 is provided over the insulating film 618. An opening portion 642a reaching the conductive film 604 is provided in the insulating films 606 and 607, and a conductive film 612c is formed to cover the opening portion 642a. An opening portion 642b reaching the conductive film 612c is formed in the insulating films 614, 616, and 618. The conductive film 620 is connected to the conductive film 612c through the opening portion 642b. That is, the conductive film 604 and the conductive film 620 are electrically connected to each other. A planarization insulating film 626 is provided over the conductive film 620. Note that the conductive film 620 functions as a second gate electrode (also referred to as a back-gate electrode) of the transistor 600.

For the evaluation in this example, Sample C1 and Sample C2 were formed as transistors each corresponding to the transistor 600 shown in FIGS. 41A to 41C. In each of Samples C1 and C2, the channel length L was 2 μm and the channel width W was 50 μm. The structure of the oxide semiconductor film 608 in Sample C1 is different from that in Sample C2, and other components in Sample C1 and Sample C2 are the same. Formation conditions of the oxide semiconductor film 608 will be described in detail in Method for Manufacturing Transistor. Note that Sample C1 is a transistor for comparison, and Sample C2 is a transistor of one embodiment of the present invention.

### <2-2. Method for Manufacturing Transistor>

First, the conductive film 604 was formed over the substrate 602. A glass substrate was used as the substrate 602. As the conductive film 604, a 100-nm-thick tungsten film was formed with a sputtering apparatus.

Next, the insulating film 606 and the insulating film 607 were formed over the substrate 602 and the conductive film 604. As the insulating film 606, a 400-nm-thick silicon nitride film was formed with a PECVD apparatus. As the insulating film 607, a 50-nm-thick silicon oxynitride film was formed with a PECVD apparatus.

Next, the oxide semiconductor film 608 was formed over the insulating film 607. Note that the oxide semiconductor film 608 in Sample C1 had a single-layer structure, and the oxide semiconductor film 608 in Sample C2 had a stacked-layer structure.

As the oxide semiconductor film 608 of Sample C1, a 35-nm-thick IGZO film was formed with a sputtering apparatus. Note that the IGZO film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a metal oxide sputtering target (having an atomic ratio of In:Ga:Zn=1:1:1.2).

As the oxide semiconductor film 608 of Sample C2, with a sputtering apparatus, a 10-nm-thick IGZO film (hereinafter referred to as “IGZO-1 film” for convenience) was formed, and a 15-nm-thick IGZO film (hereinafter referred to as “IGZO-2 film” for convenience) was formed over the IGZO-1 film. The IGZO-1 film was deposited under the conditions where the substrate temperature was 170° C., an argon gas at a flow rate of 140 sccm and an oxygen gas at a flow rate of 60 sccm were introduced into a chamber, the pressure was 0.6 Pa, and an AC power of 2500 W was applied to a metal oxide sputtering target (having an atomic ratio of In:Ga:Zn=4:2:4.1). The IGZO-2 film was deposited under the conditions where the substrate temperature was 170° C., an argon gas at a flow rate of 100 sccm and an oxygen gas at a flow rate of 100 sccm were introduced into the chamber, the pressure was 0.6 Pa, and an AC power of 2500 W was applied to a metal oxide sputtering target (having an atomic ratio of In:Ga:Zn=1:1:1.2). Note that the IGZO-1 film and the IGZO-2 film were successively formed in a vacuum.

Then, first heat treatment was performed. As the first heat treatment, heat treatment was performed at 450° C. for 1 hour in a nitrogen atmosphere and then heat treatment was performed at 450° C. for 1 hour in a mixed atmosphere of nitrogen and oxygen.

Next, a resist mask was formed over the insulating film 607 and the oxide semiconductor film 608, and a desired region was etched to form the opening portion 642a reaching the conductive film 604. The opening portion 642a was formed with a dry etching apparatus. Note that the resist mask was removed after the formation of the opening portion 642a.

Next, a conductive film was formed over the insulating film 607, the oxide semiconductor film 608, and the opening portion 642a. A resist mask was formed over the conductive film, and a desired region was etched to form the conductive films 612a, 612b, and 612c. As the conductive films 612a, 612b, and 612c, a 50-nm-thick tungsten film, a 400-nm-thick aluminum film, and a 100-nm-thick titanium film were successively formed in a vacuum with a sputtering apparatus. The resist mask was removed after the formation of the conductive films 612a, 612b, and 612c.

Next, a phosphoric acid solution (a solution obtained by diluting an 85% phosphoric acid solution with pure water by 100 times) was applied from above the insulating film 607, the oxide semiconductor film 608, and the conductive films 612a and 612b. Thus, part of the surface of the oxide semiconductor film 608 which is not covered with the conductive films 612a and 612b was removed.

Next, the insulating films 614 and 616 were formed over the insulating film 607, the oxide semiconductor film 608, and the conductive films 612a and 612b. As the insulating film 614, a 50-nm-thick silicon oxynitride film was formed with a PECVD apparatus. As the insulating film 616, a 400-nm-thick silicon oxynitride film was formed with a PECVD apparatus. Note that the insulating film 614 and the insulating film 616 were formed successively in a vacuum with a PECVD apparatus.

The insulating film 614 was deposited under the conditions where the substrate temperature was 220° C., a silane gas at a flow rate of 50 sccm and a dinitrogen monoxide gas at a flow rate of 2000 sccm were introduced into a chamber, the pressure was 20 Pa, and an RF power of 100 W was supplied between parallel-plate electrodes provided in a PECVD apparatus. The insulating film 616 was deposited under the conditions where the substrate temperature was 220° C., a silane gas at a flow rate of 160 sccm and a dinitrogen monoxide gas at a flow rate of 4000 sccm were introduced into a chamber, the pressure was 200 Pa, and an RF power of 1500 W was supplied between parallel-plate electrodes provided in a PECVD apparatus.

Then, second heat treatment was performed. The second heat treatment was performed at 350° C. in an atmosphere containing nitrogen for 1 hour.

Next, oxygen addition treatment was performed on the insulating films 614 and 616 with an ashing apparatus under the conditions where the substrate temperature was 40° C., an oxygen gas at a flow rate of 250 sccm was introduced into a chamber, the pressure was 15 Pa, and an RF power of 4500 W was supplied between parallel-plate electrodes provided in the ashing apparatus so that a bias would be applied to the substrate side.

Next, the insulating film 618 was formed over the insulating film 616. As the insulating film 618, a 100-nm-thick silicon nitride film was formed with a PECVD apparatus. The insulating film 618 was deposited under the conditions where the substrate temperature was 350° C.; a silane gas at a flow rate of 50 sccm, a nitrogen gas at a flow rate of 5000 sccm, and an ammonia gas at a flow rate of 100 sccm were introduced into a chamber; the pressure was 100 Pa; and an RF power of 1000 W was supplied between parallel-plate electrodes provided in a PECVD apparatus.

A resist mask was formed over the insulating film 618, and a desired region was etched to form the opening portion 642b reaching the conductive film 612c. The opening portion 642b was formed with a dry etching apparatus. Note that the resist mask was removed after the formation of the opening portion 642b.

Next, a conductive film was formed over the insulating film 618 to cover the opening portion 642b, and the conductive film was processed to form the conductive film 620. As the conductive film 620, a 100-nm-thick ITSO film was formed with a sputtering apparatus. The ITSO film was deposited under the conditions where the substrate temperature was room temperature, an argon gas at a flow rate of 72 sccm and an oxygen gas at a flow rate of 5 sccm were introduced into a chamber, the pressure was 0.15 Pa, and a DC power of 3200 W was supplied to a metal oxide target provided in a sputtering apparatus. Note that the composition of the metal oxide target used for forming the ITSO film was In₂O₃:SnO₂:SiO₂=85:10:5 [wt %].

Then, third heat treatment was performed. The third heat treatment was performed at 250° C. for 1 hour in a nitrogen atmosphere.

Through the above process, Sample C1 and Sample C2 were fabricated.

### <2-3. Evaluation of Electrical Characteristics of Transistors>

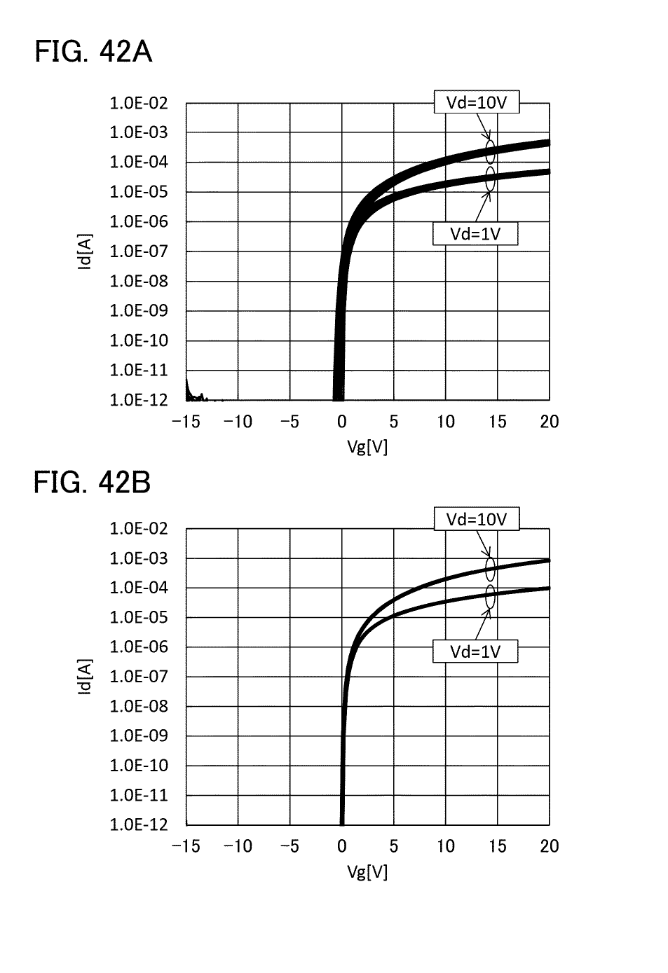

Electrical characteristics of Samples C1 and C2 were evaluated. The evaluation results of Samples C1 and C2 are shown in FIGS. 42A and 42B.

Note that FIG. 42A shows the electrical characteristics of Samples C1, and FIG. 42B shows the electrical characteristics of Samples C2.

In FIGS. 42A and 42B, the voltage (V_{d}) between the source electrode and the drain electrode was set at 1 V and 10 V, and V_{g} was applied from −15 V to 20 V at intervals of 0.25 V. Furthermore, the vertical axis shows the drain current (I_{d}), and the horizontal axis shows the gate voltage (V_{g}). Data of ten transistors are shown for each of them.

The results shown in FIGS. 42A and 42B reveal that the on-state current of Samples C2 of one embodiment of the present invention is higher than that of Samples C1 for comparison. In addition, Samples C2 are normally-off transistors with small variation in transistor characteristics.

### <2-4. Reliability Evaluation by Gate BT Test>

The reliability of transistors each corresponding to Sample C2 (transistors each having the same structure as Sample C2 and having a channel length L of 6 μm and a channel width W of 50 μm) was evaluated by a gate bias temperature (BT) test where stress voltage was applied to the gate electrodes. Note that the following four test methods were employed as the gate BT test.

### (I. PBTS: Positive Bias Temperature Stress)

The gate voltage (V_{g}) and the back-gate voltage (V_{bg}) were +30 V, the drain voltage (V_{d}) and the source voltage (Vₛ) were 0 V (COMMON), the stress temperature was 60° C., the stress time was 1 hour, and the measurement environment was a dark environment. In other words, a source electrode and a drain electrode of the transistor were set at the same potential, and a potential different from that of the source and drain electrodes was applied to a gate electrode of the transistor for a certain time. The potential applied to the gate electrode was higher than the potential applied to the source electrode and the drain electrode (a potential applied to the gate electrode was more on the positive side than that applied to the source electrode and the drain electrode).

### (II. NBTS: Nagative Bias Temperature Stress)

The gate voltage (V_{g}) and the back-gate voltage (V_{bg}) were −30 V, the drain voltage (V_{d}) and the source voltage (Vₛ) were 0 V (COMMON), the stress temperature was 60° C., the stress time was 1 hour, and the measurement environment was a dark environment. In other words, a source electrode and a drain electrode of the transistor were set at the same potential, and a potential different from that of the source and drain electrodes was applied to a gate electrode of the transistor for a certain time. The potential applied to the gate electrode was lower than the potential applied to the source electrode and the drain electrode (a potential applied to the gate electrode was more on the negative side than that applied to the source electrode and the drain electrode).

### (III. PBITS: Positive Bias Illuminations Temperature Stress)

The gate voltage (V_{g}) and the back-gate voltage (V_{bg}) were +30 V, the drain voltage (V_{d}) and the source voltage (Vₛ) were 0 V (COMMON), the stress temperature was 60° C., the stress time was 1 hour, and the measurement environment was a photo environment (approximately 10000 lx with a white LED). In other words, a source electrode and a drain electrode of the transistor were set at the same potential, and a potential different from that of the source and drain electrodes was applied to a gate electrode of the transistor for a certain time. The potential applied to the gate electrode was higher than the potential applied to the source electrode and the drain electrode (a potential applied to the gate electrode was more on the positive side than that applied to the source electrode and the drain electrode).

### (IV. NBITS: Nagative Bias Illuminations Temperature Stress)

The gate voltage (V_{g}) and the back-gate voltage (V_{bg}) were −30 V, the drain voltage (V_{d}) and the source voltage (Vₛ) were 0 V (COMMON), the stress temperature was 60° C., the stress time was 1 hour, and the measurement environment was a photo environment (approximately 10000 lx with a white LED). In other words, a source electrode and a drain electrode of the transistor were set at the same potential, and a potential different from that of the source and drain electrodes was applied to a gate electrode of the transistor for a certain time. The potential applied to the gate electrode was lower than the potential applied to the source electrode and the drain electrode (a potential applied to the gate electrode was more on the negative side than that applied to the source electrode and the drain electrode).

Note that the gate BT test is one kind of accelerated test and can evaluate change in characteristics, caused by long-term usage, of transistors in a short time. In particular, the amount of change in threshold voltage (ΔVₜₕ) and the amount of change in shift value (ΔShift) of a transistor between before and after the gate BT test is an important indicator for examining the reliability. Between before and after the GBT test, a smaller amount of change in threshold voltage (ΔVₜₕ) and a smaller amount of change in shift value (ΔShift) of a transistor means higher reliability of the transistor.

Note that the shift value of a transistor means, in the drain current (I_{d})-gate voltage (V_{g}) characteristics of the transistor, the gate voltage (V_{g}) at a point of intersection of an axis of 1×10⁻¹² A and a tangent line of the logarithm of a drain current (I_{d}) having the highest gradient. ΔVₜₕ represents the change in Vₜₕ and is obtained by subtraction of Vₜₕ before the stress test from Vₜₕ after the stress test. ΔShift represents the change in shift value and is obtained by subtraction of a shift value before the stress test from a shift value after the stress test.

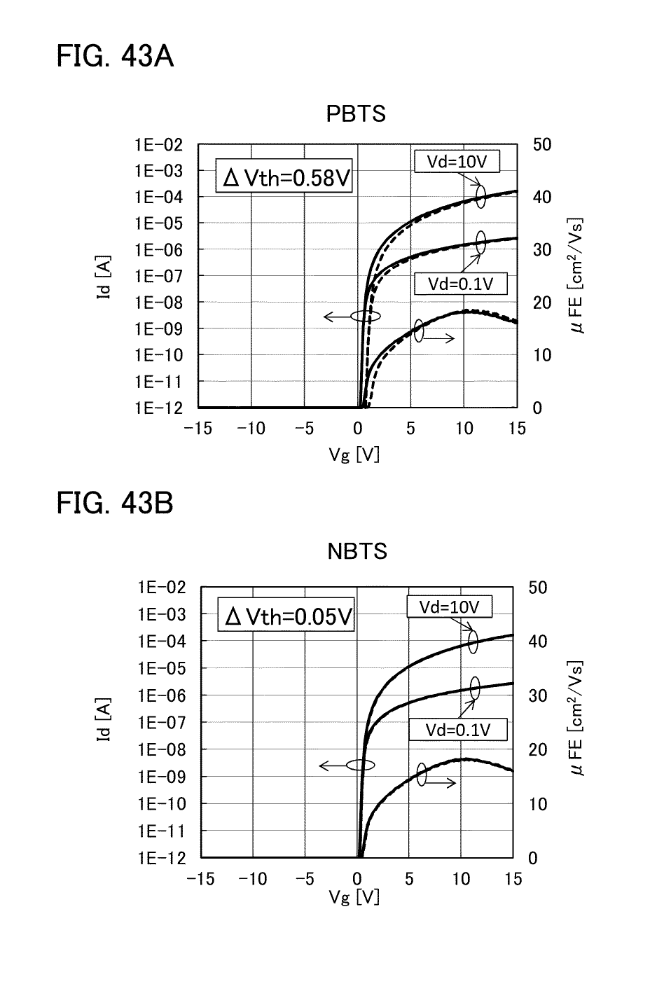

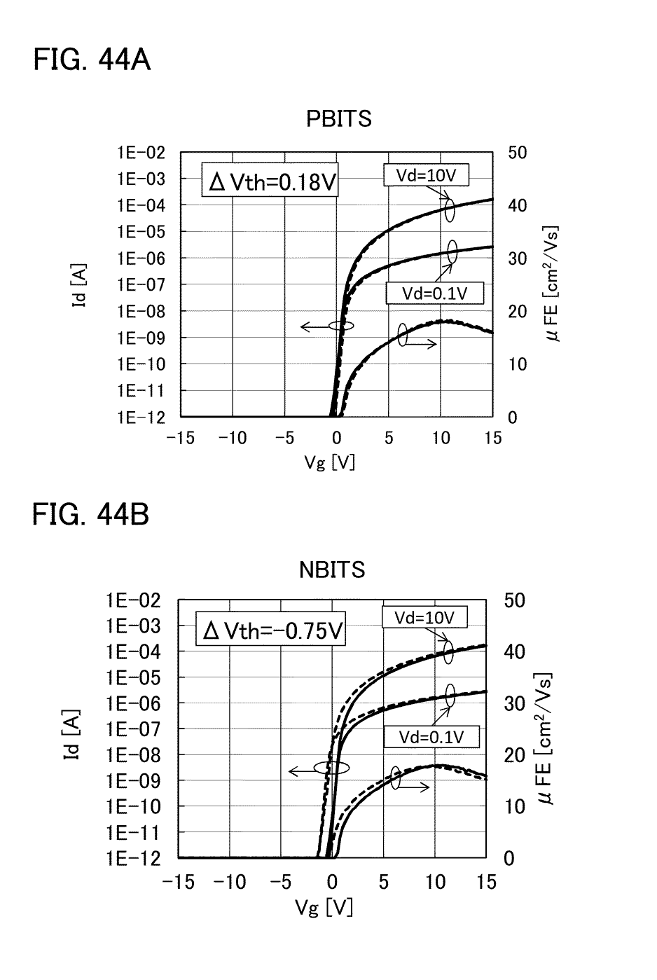

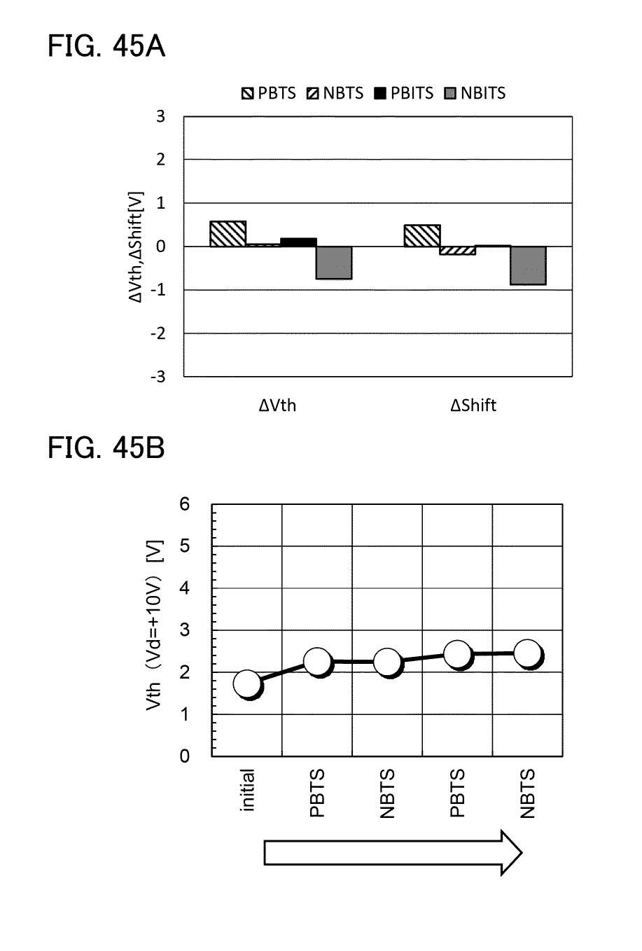

Gate BT test results of transistors each corresponding to Sample C2 are shown in FIGS. 43A and 43B, FIGS. 44A and 44B, and FIG. 45A. FIG. 43A shows the I_{d}-V_{g} characteristics of transistors before and after the PBTS test. FIG. 43B show the I_{d}-V_{g} characteristics of transistors before and after the NBTS test. FIG. 44A shows the I_{d}-V_{g} characteristics of transistors before and after the PBITS test. FIG. 44B shows the I_{d}-V_{g} characteristics of transistors before and after the NBITS test. Note that in FIGS. 43A and 43B and FIGS. 44A and 44B, solid lines indicate the I_{d}-V_{g} characteristics of transistors before the test, and dashed lines indicate the I_{d}-V_{g} characteristics of transistors after the test. In FIGS. 43A and 43B and FIGS. 44A and 44B, the voltage (V_{d}) between the source electrode and the drain electrode was set at 0.1 V and 10 V, and V_{g} was applied from −15 V to 15 V at intervals of 0.25 V. Furthermore, the first vertical axis shows the drain current (I_{d}), the second vertical axis shows the field-effect mobility (μ_{FE}) when V_{d} is 10 V, and the horizontal axis shows the gate voltage (V_{g}). FIG. 45A shows ΔVₜₕ and ΔShift of the transistors having the I_{d}-V_{g} characteristics shown in FIGS. 43A and 43B and FIGS. 44A and 44B.

The results in FIGS. 43A and 43B, FIGS. 44A and 44B, and FIG. 45A show that ΔVₜₕ and ΔShift of the transistors corresponding to Sample C2 of one embodiment of the present invention are small (variations lower than 1 V) in the gate BT stress test.

### <2-5. Gate BT Test by Applying Positive Voltage and Negative Voltage Alternately>

A transistor corresponding to Sample C2 (a transistor having the same structure as Sample C2 and having a channel length L of 6 μm and a channel width W of 50 μm) was subjected to a gate BT test. In the test, a positive voltage and a negative voltage were applied alternately to the gate electrode of the transistor. Note that PBTS and NBTS described in <2-4. Reliability Evaluation by Gate BT Test> were employed in this gate BT test.

FIG. 45B shows the result of the gate BT test with alternate positive and negative voltages were applied alternately to the gate electrode. As shown in FIG. 45B, the amount of change in Vₜₕ of the transistor corresponding to Sample C2 of one embodiment of the present invention is small also in the gate BT test with alternate positive and negative voltages.

Thus, the transistor corresponding to Sample C2 of one embodiment of the present invention is highly reliable.

The structure described in this example can be combined as appropriate with any of the structures described in the embodiments and the other examples.

### Example 3

In this example, transistors each corresponding to the transistor 600 shown in FIGS. 41A to 41C were formed and their electrical characteristics were evaluated.

### <3-1. Transistor Structure and Manufacturing Method 1>

A transistor structure in this example was the same as that of Sample C2 in Example 2. A manufacturing method of the transistors in this example was the same as that of Sample C2 in Example 2. Note that the transistors of this example had a channel length L of 2 μm, 3 μm, and 6 μm and a channel width W of 50 μm. Furthermore, four transistors having the same channel length L were formed over each substrate.

### <3-2. Evaluation of Electrical Characteristics>

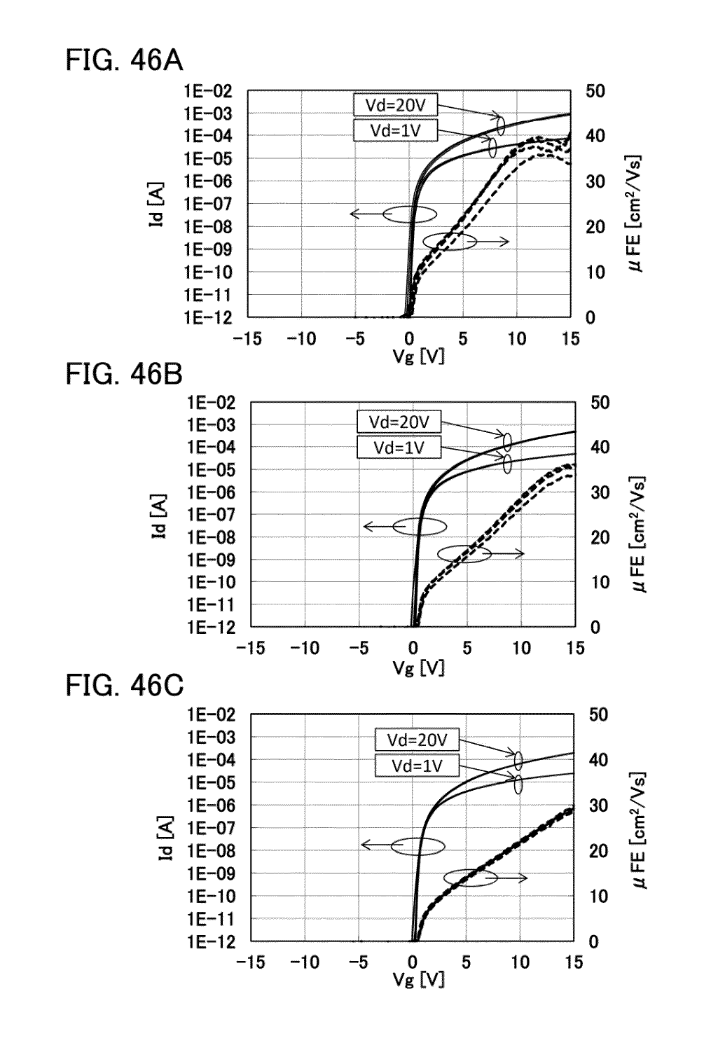

The electrical characteristics of the manufactured transistors were evaluated. FIGS. 46A to 46C show the evaluation result of the electrical characteristics of the transistors. Note that the characteristics of four transistors are shown in each of FIGS. 46A to 46C. FIG. 46A shows I_{d}-V_{g} curves of transistors each having W/L of 50/2 μm. FIG. 46B shows I_{d}-V_{g} curves of transistors each having W/L of 50/3 μm. FIG. 46C shows I_{d}-V_{g} curves of transistors each having W/L of 50/6 μm. In FIGS. 46A to 46C, the voltage (V_{d}) between the source electrode and the drain electrode was set at 1 V and 20 V, and V_{g} was applied from −15 V to 15 V at intervals of 0.25 V. Furthermore, the first vertical axis shows the drain current (I_{d}), the second vertical axis shows the field-effect mobility (μ_{FE}) when V_{d} is 20 V, and the horizontal axis shows the gate voltage (V_{g}). In FIGS. 46A to 46C, solid lines indicate I_{d} and dashed lines indicate μ_{FE}.

The results in FIGS. 46A to 46C show that the transistors of one embodiment of the present invention have high field-effect mobility (μ_{FE}). In particular, the transistors having a channel length L of 2 μm and a channel length L of 3 μm in FIGS. 46A and 46B exhibit field-effect mobility (μ_{FE}) higher than 30 cm²/V·s.

### <3-3. Transistor Structure and Manufacturing Method 2>

In FIGS. 46A and 46B, the transistors having a channel length L of 2 μm and a channel length L of 3 μm of this example have field-effect mobility (μ_{FE}) higher than 30 cm²/V·s. To confirm the reproducibility of the electrical characteristics, transistors different from the transistors shown in FIGS. 46A and 46B were manufactured. Note that a structure and a manufacturing method of the transistors were similar to those of Sample C2 in Example 2. Note that the transistors of this example had a channel length L of 2 μm and a channel length L of 3 μm and a channel width W of 50 μm.

### <3-4. Evaluation of Electrical Characteristics>

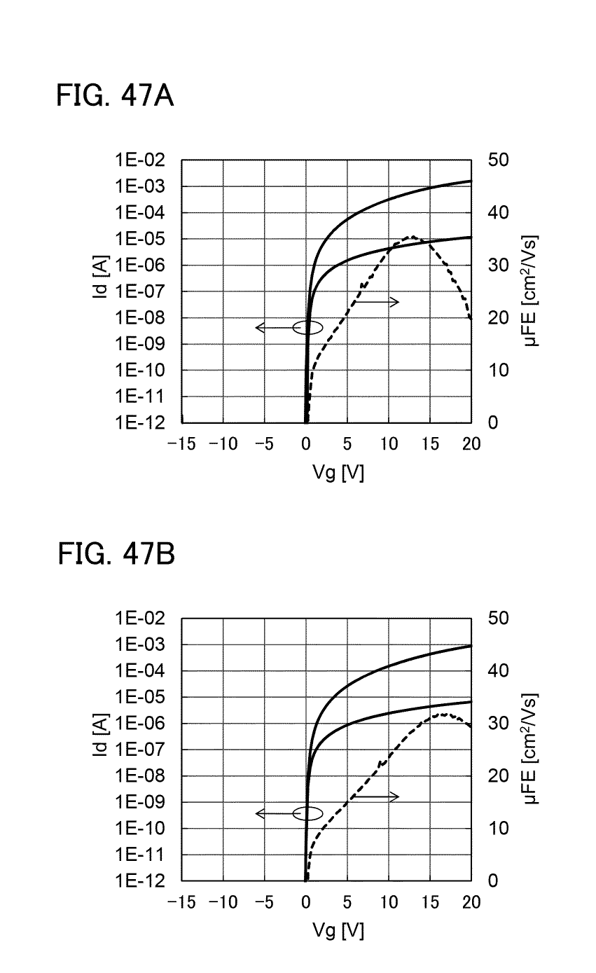

The electrical characteristics of the transistors were evaluated. FIGS. 47A and 47B show the evaluation results of the electrical characteristics of the transistors. FIG. 47A shows I_{d}-V_{g} curves of transistors each having W/L of 50/2 μm. FIG. 47B shows I_{d}-V_{g} curves of transistors each having W/L of 50/3 μm. In FIGS. 47A and 47B, the voltage (V_{d}) between the source electrode and the drain electrode was set at 1 V and 20 V, and V_{g} was applied from −15 V to 20 V at intervals of 0.25 V. Furthermore, the first vertical axis shows the drain current (I_{d}), the second vertical axis shows the mobility μ_{FE} (cm²/Vs) when V_{d} is 20 V, and the horizontal axis shows the gate voltage (V_{g}). In FIGS. 47A and 47B, solid lines indicate I_{d} and dashed lines indicate μ_{FE}.

The results in FIGS. 47A and 47B show that the transistors having a channel length L of 2 μm and a channel length L of 3 μm have field-effect mobility (μ_{FE}) of 30 cm²/V·s or higher, and thus, the reproducibility of the electrical characteristics of the transistors was confirmed.

The structure described in this example can be combined as appropriate with any of the structures described in the embodiments and the other examples.

### Example 4

In this example, transistors (Sample D1 and Sample D2) each corresponding to the transistor 150 shown in FIGS. 1A to 1C were manufactured, and a constant-current stress test was performed on the transistors. Sample D1 was the transistor of one embodiment of the present invention and had a channel length L of 3 μm and a channel width W of 5 μm. Sample D2 was a transistor for comparison and had a channel length L of 6 μm and a channel width W of 5 μm.

Note that the structure of the oxide semiconductor film 120 in Sample D1 was different from that in Sample D2. Specifically, the oxide semiconductor film 120 in Sample D1 had a stacked-layer structure, whereas the oxide semiconductor film 120 in Sample D2 had a single-layer structure.

Samples formed in this example are described below. Note that the reference numerals used for the transistor 150 in FIGS. 1A to 1C are used in the following description.

### <4-1. Manufacturing Method of Sample D1>

First, the gate electrode 114 was formed over the substrate 100. A glass substrate was used as the substrate 100. As the gate electrode 114, a 100-nm-thick tungsten film was formed with a sputtering apparatus.

The insulating films 102 and 103 were formed over the substrate 100 and the gate electrode 114. As the insulating film 102, a 400-nm-thick silicon nitride film was formed with a PECVD apparatus. As the insulating film 103, a 50-nm-thick silicon oxynitride film was formed with a PECVD apparatus.

The insulating film 102 was deposited as follows. First, a 50-nm-thick silicon nitride film was deposited under the conditions where the substrate temperature was 350° C.; a silane gas at a flow rate of 200 sccm, a nitrogen gas at a flow rate of 2000 sccm, and an ammonia gas at a flow rate of 100 sccm were introduced into a chamber; the pressure was set to 100 Pa; and an RF power of 2000 W was supplied between parallel-plate electrodes placed in a PECVD apparatus. Then, the flow rate of an ammonia gas was changed to 2000 sccm to deposit a 300-nm-thick silicon nitride film. Finally, the flow rate of an ammonia gas was changed to 100 sccm to deposit a 50-nm-thick silicon nitride film.

The insulating film 103 was deposited under the conditions where the substrate temperature was 350° C., a silane gas at a flow rate of 20 sccm and a dinitrogen monoxide gas at a flow rate of 3000 sccm were introduced into a chamber, the pressure was 40 Pa, and an RF power of 100 W was supplied between parallel-plate electrodes provided in a PECVD apparatus.

Then, the oxide semiconductor film 120 was formed over the insulating film 103. As the oxide semiconductor film 120, the oxide semiconductor film 120a and the oxide semiconductor film 120b were successively formed in a vacuum with a sputtering apparatus.

Note that, as the oxide semiconductor film 120a, a 10-nm-thick IGZO film was deposited under the conditions where the substrate temperature was 170° C., an argon gas at a flow rate of 140 sccm and an oxygen gas at a flow rate of 60 sccm were introduced into a chamber, the pressure was 0.6 Pa, and an AC power of 2500 W was applied to a polycrystalline metal oxide sputtering target (having an atomic ratio of In:Ga:Zn=4:2:4.1).

Note that, as the oxide semiconductor film 120b, a 15-nm-thick IGZO film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a polycrystalline metal oxide sputtering target (having an atomic ratio of In:Ga:Zn=1:1:1.2).

Then, first heat treatment was performed. Then, first heat treatment was performed. As the first heat treatment, heat treatment was performed at 450° C. for 1 hour in a nitrogen atmosphere and then heat treatment was performed at 450° C. for 1 hour in a mixed atmosphere of nitrogen and oxygen.

Next, the pair of electrodes 116a and 116b was formed over the insulating film 103 and the oxide semiconductor film 120. As the pair of electrodes 116a and 116b, a 50-nm-thick tungsten film, a 400-nm-thick aluminum film, and a 100-nm-thick titanium film were successively formed in a vacuum with a sputtering apparatus.

Next, a surface of the oxide semiconductor film 120 (on the back-channel side) was cleaned. As the cleaning method, a phosphoric acid solution obtained by diluting phosphoric acid (concentration of 85 vol %) 100 times with water was applied to the oxide semiconductor film 120 and the pair of electrodes 116a and 116b with a spin cleaning apparatus. Note that the cleaning was performed for 15 seconds.

Next, the insulating films 106 and 107 were formed over the oxide semiconductor film 120 and the pair of electrodes 116a and 116b. As the insulating film 106, a 50-nm-thick silicon oxynitride film was formed with a PECVD apparatus. As the insulating film 107, a 400-nm-thick silicon oxynitride film was formed with a PECVD apparatus. Note that the insulating film 106 and the insulating film 107 were formed successively in a vacuum with a PECVD apparatus.

The insulating film 106 was deposited under the conditions where the substrate temperature was 220° C., a silane gas at a flow rate of 50 sccm and a dinitrogen monoxide gas at a flow rate of 2000 sccm were introduced into a chamber, the pressure was 20 Pa, and an RF power of 100 W was supplied between parallel-plate electrodes provided in a PECVD apparatus. The insulating film 107 was deposited under the conditions where the substrate temperature was 220° C., a silane gas at a flow rate of 160 sccm and a dinitrogen monoxide gas at a flow rate of 4000 sccm were introduced into a chamber, the pressure was 200 Pa, and an RF power of 1500 W was supplied between parallel-plate electrodes provided in a PECVD apparatus.

Then, second heat treatment was performed. The second heat treatment was performed at 350° C. in a nitrogen gas atmosphere for 1 hour.

A 5-nm-thick ITSO film was formed over the insulating film 107 with a sputtering apparatus. The ITSO film was deposited under the conditions where the substrate temperature was room temperature, an argon gas at a flow rate of 72 sccm and an oxygen gas at a flow rate of 5 sccm were introduced into a chamber, the pressure was 0.15 Pa, and a DC power of 1000 W was supplied to a metal oxide target (In₂O₃:SnO₂:SiO₂=85:10:5 [wt. %]) provided in a sputtering apparatus.

Next, oxygen addition treatment was performed on the oxide semiconductor film 120 and the insulating films 106 and 107 through the ITSO film. The oxygen addition treatment was performed with an ashing apparatus under the conditions where the substrate temperature was 40° C., an oxygen gas at a flow rate of 250 sccm was introduced into a chamber, the pressure was 15 Pa, and an RF power of 4500 W was supplied for 120 seconds between parallel-plate electrodes provided in the ashing apparatus so as to apply a bias to the substrate side.

Next, the ITSO film was removed to expose the insulating film 108. The ITSO film war removed using a wet-etching apparatus in such a manner that etching was performed using an oxalic acid solution at a concentration of 5% for 300 seconds and then etching was performed using hydrofluoric acid at a concentration of 0.5% for 15 seconds.

Next, the insulating film 108 was formed over the insulating film 107. As the insulating film 108, a 100-nm-thick silicon nitride film was formed with a PECVD apparatus. The insulating film 108 was deposited under the conditions where the substrate temperature was 350° C., a silane gas at a flow rate of 50 sccm, a nitrogen gas at a flow rate of 5000 sccm, and an ammonia gas at a flow rate of 100 sccm were introduced into a chamber, the pressure was 100 Pa, and high-frequency power of 1000 W was supplied between parallel-plate electrodes provided in a PECVD apparatus with the use of a 27.12 MHz high-frequency power source.

Next, the opening portion 130a reaching the electrode 116b and the opening portions 130b and 130c reaching the gate electrode 114 were formed. The opening portions 130a, 130b, and 130c were formed with a dry etching apparatus.

A conductive film was formed over the insulating film 108 to cover the opening portions 130a, 130b, and 130c, and the conductive film was processed into desired shapes to form the gate electrode 118 and the electrode 119.

Next, third heat treatment was performed. The third heat treatment was performed at 250° C. under a nitrogen atmosphere for 1 hour.

Through the above process, Sample D1 of this example was manufactured.

### <4-2. Manufacturing Method of Sample D2>

The manufacturing method of Sample D2 differs from that of Sample D1 only in the formation conditions of the oxide semiconductor film 120, and the rest of the manufacturing method was the same as that of Sample D1.

The oxide semiconductor film 120 of Sample D2 has a single-layer structure of the oxide semiconductor film 120a. As the oxide semiconductor film 120a of Sample D2, a 35-nm-thickness IGZO film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a polycrystalline metal oxide sputtering target (having an atomic ratio of In:Ga:Zn=1:1:1.2).

### <4-3. Constant-Current Stress Test>

Next, a constant-current stress test was performed on Sample D1 and Sample D2. Note that the constant-current stress test was performed under an air atmosphere in a dark state (dark).

Note that the measurement of I_{d}-V_{g} characteristics was performed by measuring drain current when drain voltage was set to 0.1 V and 10 V and gate voltage was swept in the range of −15 V to 15 V.

In the constant-current stress test for Sample D1, the substrate temperature was set at room temperature, and the first measurement of I_{d}-V_{g} characteristics and I_{d}-V_{d} characteristics was performed. Then, the substrate temperature was set to 60° C., a source potential was set to a ground potential (GND), a drain potential was set to 10 V, and a gate potential was set to 2.02 V, and the state was maintained for 48 hours. After that, the substrate temperature was decreased to room temperature, and the second measurement of I_{d}-V_{g} characteristics and I_{d}-V_{d} characteristics was performed.

In the constant-current stress test for Sample D2, the substrate temperature was set at room temperature, and the first measurement of I_{d}-V_{g} characteristics and I_{d}-V_{d} characteristics was performed. Then, the substrate temperature was set to 60° C., a source potential was set to a ground potential (GND), a drain potential was set to 10 V, and a gate potential was set to 4.30 V, and the state was maintained for 24 hours. After that, the substrate temperature was decreased to room temperature, and the second measurement of I_{d}-V_{g} characteristics and I_{d}-V_{d} characteristics was performed.

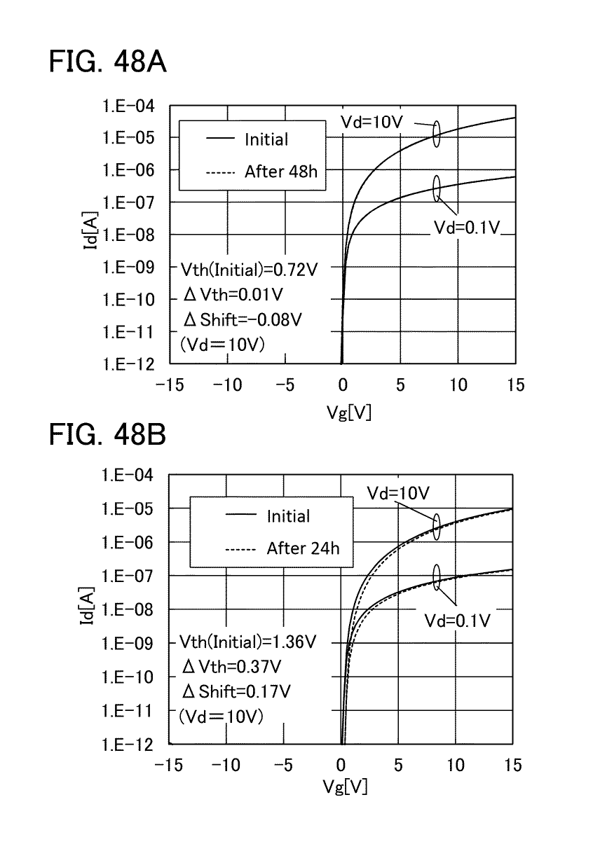

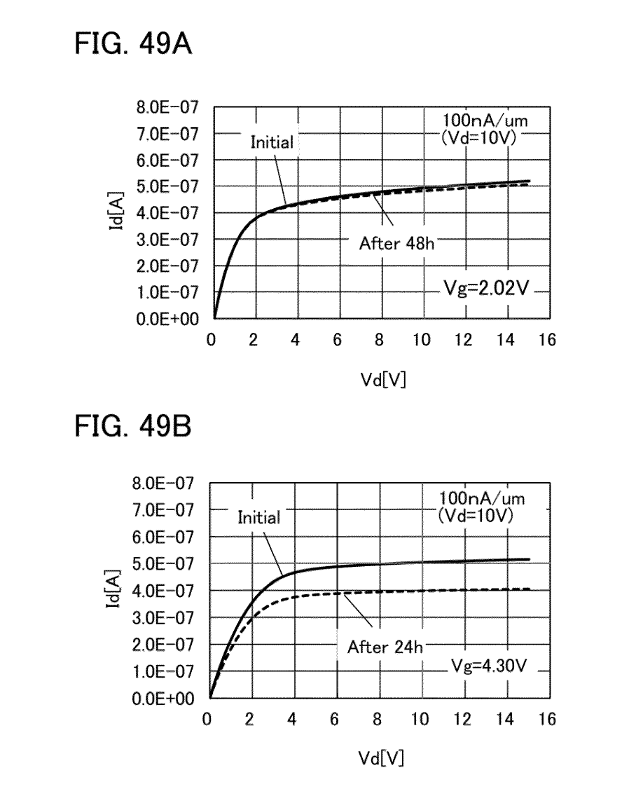

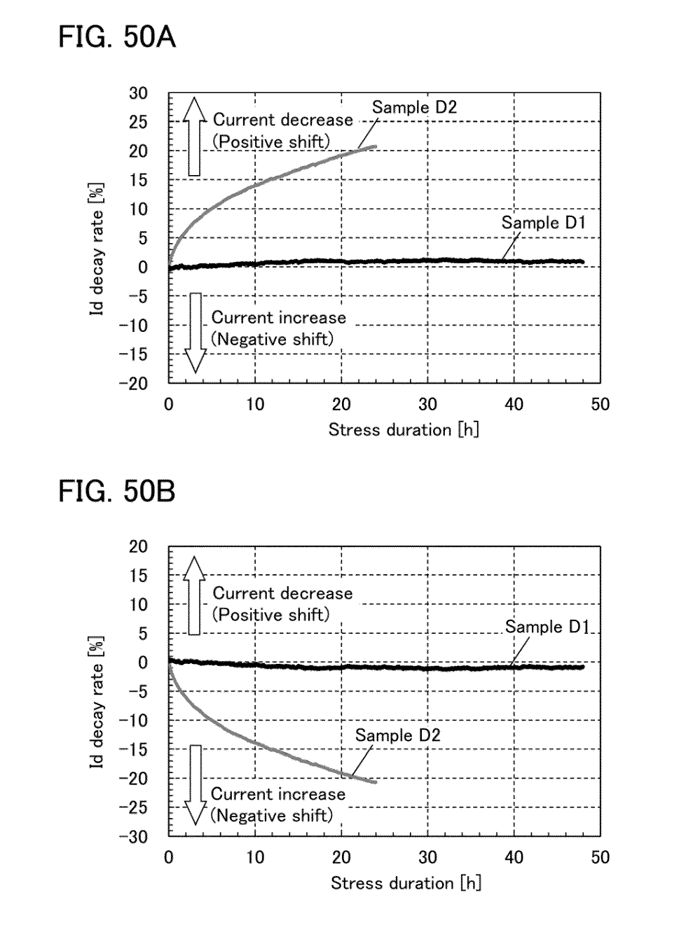

The results of the constant-current stress test performed on Sample D1 and Sample D2 are shown in FIGS. 48A and 48B, FIGS. 49A and 49B, and FIGS. 50A and 50B. FIG. 48A shows the I_{d}-V_{g} characteristics of Sample D1. FIG. 48B shows the I_{d}-V_{g} characteristics of Sample D2. FIG. 49A shows the I_{d}-17d characteristics of Sample D1. FIG. 49B shows the I_{d}-V_{g} characteristics of Sample D2. FIGS. 50A and 50B show the decay rates of drain currents (I_{d}) of Sample D1 and Sample D2 with respect to stress time. Note that the decay rate shown in FIG. 50A is obtained through subtraction of the drain current after the test from the drain current before the test, and the decay rate shown in FIG. 50B is obtained through subtraction of a drain current before the test from a drain current after the test.

As shown in FIGS. 48A and 48B, FIGS. 49A and 49B, and FIGS. 50A and 50B, the change in drain current of Sample D1 is smaller than that of Sample D2. This also shows that a semiconductor device including the transistor of one embodiment of the present invention has high reliability.

The structure described in this example can be combined as appropriate with any of the structures described in the embodiments or the other examples.

### Example 5

In this example, a display device including a transistor corresponding to Sample C2 in Example 2 was manufactured. Table 1 shows specifications of the display device manufactured in this example.

TABLE 1

| | Specifications |
|---|---|
| Screen Diagonal | 13.3 inches |
| Driving Method | Active Matrix |
| Resolution | 7680 × RGB × 4320 (8k4k) |
| Pixel Density | 664 ppi |
| Pixel Pitch | 12.75 μm × RGB × 38.25 μm |
| Aperture ratio | 44.30% |
| Pixel Arrangement | RGB Stripe COF |
| Source Driver | COF |
| Scan Driver | Integrated |

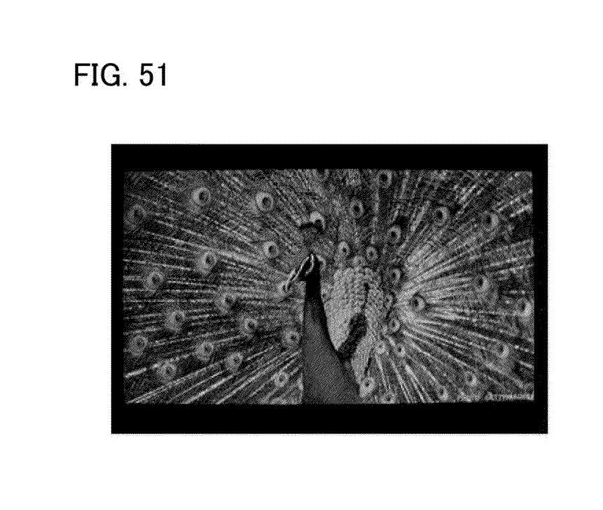

FIG. 51 shows a display example of the display device having the specifications shown in Table 1. As shown in FIG. 51, it was confirmed that the display device had favorable display quality.

The structure described in this example can be combined as appropriate with any of the structures described in the embodiments and the other examples.

This application is based on Japanese Patent Application serial no. 2014-242170 filed with Japan Patent Office on Nov. 28, 2014, Japanese Patent Application serial no. 2014-255804 filed with Japan Patent Office on Dec. 18, 2014, Japanese Patent Application serial no. 2015-046110 filed with Japan Patent Office on Mar. 9, 2015, and Japanese Patent Application serial no. 2015-061604 filed with Japan Patent Office on Mar. 24, 2015, the entire contents of which are hereby incorporated by reference.

What is claimed is:

1. A semiconductor device comprising:
a transistor,
wherein the transistor includes a first electrode, a first insulating film over the first electrode, an oxide semiconductor film over the first insulating film, a second insulating film over the oxide semiconductor film, and a second electrode over the second insulating film,
wherein the oxide semiconductor film includes a first oxide semiconductor film and a second oxide semiconductor film,
wherein a difference between energy at a conduction band minimum of the first oxide semiconductor film and energy at a conduction band minimum of the second oxide semiconductor film is greater than or equal to 0.2 eV, and
wherein, for the transistor, in a given range of drain voltage, a rate of change in drain current per unit channel width relative to a drain voltage of 1 V is less than or equal to 2%.

2. A semiconductor device comprising:
a transistor,
wherein the transistor includes a first electrode, a first insulating film over the first electrode, an oxide semiconductor film over the first insulating film, a second insulating film over the oxide semiconductor film, and a second electrode over the second insulating film,
wherein the oxide semiconductor film includes a first oxide semiconductor film and a second oxide semiconductor film,
wherein a difference between energy at a conduction band minimum of the first oxide semiconductor film and energy at a conduction band minimum of the second oxide semiconductor film is greater than or equal to 0.2 eV, and
wherein, for the transistor, in a given range of drain voltage, an amount of change in drain current per unit channel width relative to a drain voltage of 1 V is less than or equal to 1×10⁻⁹ A/μm.

3. A semiconductor device comprising:
a transistor,
wherein the transistor includes a first electrode, a first insulating film over the first electrode, an oxide semiconductor film over the first insulating film, a second insulating film over the oxide semiconductor film, and a second electrode over the second insulating film,
wherein the oxide semiconductor film includes a first oxide semiconductor film and a second oxide semiconductor film,
wherein the first oxide semiconductor film includes In, Zn, and M,
wherein M is Ti, Ga, Y, Zr, Sn, La, Ce, Nd, or Hf,
wherein the first oxide semiconductor film includes a region where an amount of the In is larger than or equal to an amount of the M,
wherein at least one element of the first oxide semiconductor film is the same as at least one element of the second oxide semiconductor film,
wherein a difference between energy at a conduction band minimum of the first oxide semiconductor film and energy at a conduction band minimum of the second oxide semiconductor film is greater than or equal to 0.2 eV, and
wherein, for the transistor, in a given range of drain voltage, a rate of change in drain current per unit channel width relative to a drain voltage of 1 V is less than or equal to 2%.

4. A semiconductor device comprising:
a transistor,
wherein the transistor includes a first electrode, a first insulating film over the first electrode, an oxide semiconductor film over the first insulating film, a second insulating film over the oxide semiconductor film, and a second electrode over the second insulating film,
wherein the oxide semiconductor film includes a first oxide semiconductor film and a second oxide semiconductor film,
wherein the first oxide semiconductor film includes In, Zn, and M,
wherein M is Ti, Ga, Y, Zr, Sn, La, Ce, Nd, or Hf,
wherein the first oxide semiconductor film includes a region where an amount of the In is larger than or equal to an amount of the M,
wherein at least one element in the first oxide semiconductor film is the same as at least one element in the second oxide semiconductor film,
wherein a difference between energy at a conduction band minimum of the first oxide semiconductor film and energy at a conduction band minimum of the second oxide semiconductor film is greater than or equal to 0.2 eV, and
wherein, for the transistor, in a given range of drain voltage, an amount of change in drain current per unit channel width relative to a drain voltage of 1 V is less than or equal to 1×10⁻⁹ A/μm.

5. The semiconductor device according to claim 1,
wherein the second oxide semiconductor film includes In, Zn, and M,
wherein M is Ti, Ga, Y, Zr, Sn, La, Ce, Nd, or Hf, and
wherein, in a region of the second oxide semiconductor film, an amount of the M is larger than or equal to an amount of the In.

6. The semiconductor device according to claim 2,
wherein the second oxide semiconductor film includes In, Zn, and M,
wherein M is Ti, Ga, Y, Zr, Sn, La, Ce, Nd, or Hf, and
wherein, in a region of the second oxide semiconductor film, an amount of the M is larger than or equal to an amount of the In.

7. The semiconductor device according to claim 3,
wherein the second oxide semiconductor film includes In, Zn, and M,
wherein M is Ti, Ga, Y, Zr, Sn, La, Ce, Nd, or Hf, and
wherein, in a region of the second oxide semiconductor film, an amount of the M is larger than or equal to an amount of the In.

8. The semiconductor device according to claim 4,
wherein the second oxide semiconductor film includes In, Zn, and M,
wherein M is Ti, Ga, Y, Zr, Sn, La, Ce, Nd, or Hf, and
wherein, in a region of the second oxide semiconductor film, an amount of the M is larger than or equal to an amount of the In.

9. The semiconductor device according to claim 5,
wherein a region where an amount of the In in the first oxide semiconductor film is larger than or equal to an amount of the In in the second oxide semiconductor film is included.

10. The semiconductor device according to claim 6,
wherein a region where an amount of the In in the first oxide semiconductor film is larger than or equal to an amount of the In in the second oxide semiconductor film is included.

11. The semiconductor device according to claim 7,
wherein a region where an amount of the In in the first oxide semiconductor film is larger than or equal to an amount of the In in the second oxide semiconductor film is included.

12. The semiconductor device according to claim 8,
wherein a region where an amount of the In in the first oxide semiconductor film is larger than or equal to an amount of the In in the second oxide semiconductor film is included.

13. The semiconductor device according to claim 5,
wherein a region where an amount of the M in the second oxide semiconductor film is larger than an amount of the M in the first oxide semiconductor film is included.

14. The semiconductor device according to claim 6,
wherein a region where an amount of the M in the second oxide semiconductor film is larger than an amount of the M in the first oxide semiconductor film is included.

15. The semiconductor device according to claim 7,
wherein a region where an amount of the M in the second oxide semiconductor film is larger than an amount of the M in the first oxide semiconductor film is included.

16. The semiconductor device according to claim 8,
wherein a region where an amount of the M in the second oxide semiconductor film is larger than an amount of the M in the first oxide semiconductor film is included.

17. The semiconductor device according to claim 1,
wherein oxygen molecules of more than or equal to 8.0×10¹⁴/cm² are detected from the second insulating film by thermal desorption spectroscopy.

18. The semiconductor device according to claim 2,
wherein oxygen molecules of more than or equal to 8.0×10¹⁴/cm² are detected from the second insulating film by thermal desorption spectroscopy.

19. The semiconductor device according to claim 3,
wherein oxygen molecules of more than or equal to 8.0×10¹⁴/cm² are detected from the second insulating film by thermal desorption spectroscopy.

20. The semiconductor device according to claim 4,
wherein oxygen molecules of more than or equal to 8.0×10¹⁴/cm² are detected from the second insulating film by thermal desorption spectroscopy.

21. A display device comprising:
the semiconductor device according to claim 1; and
a display element.

22. A display device comprising:
the semiconductor device according to claim 2; and
a display element.

23. A display device comprising:
the semiconductor device according to claim 3; and
a display element.

24. A display device comprising:
the semiconductor device according to claim 4; and
a display element.
